(19) United States
(12) Patent Application Publication
(10) Pub. No.: US 2026/0033236 A1
(43) Pub. Date: Jan. 29, 2026

(54) ORGANIC LIGHT EMITTING DIODE INCLUDING NOVEL ANTHRACENE COMPOUND

(71) Applicant: SFC CO., LTD., Cheongju-si (KR)

(72) Inventors: Se-Jin LEE, Cheongju-si (KR); Si-In Kim, cheongju-si (KR); Seok-Bae Park, Cheongju-si (KR); Hee-Dae Kim, Cheongju-si (KR); Yeong-Tae Choi, Cheongju-si (KR); Seung-Soo Lee, Cheongju-si (KR); Ji-Yung Kim, Cheongju-si (KR); Kyeong-Hyeon Kim, Cheongju-si (KR); Kyungtae Kim, Cheongju-si (KR); Myeong-Jun Kim, Cheongju-si (KR); Tae Gyun Lee, Cheongju-si (KR); Joon-Ho Kim, Cheongju-si (KR)

(21) Appl. No.: 19/341,307

(22) Filed: Sep. 26, 2025

Related U.S. Application Data
(62) Division of application No. 17/576,354, filed on Jan. 14, 2022, now Pat. No. 12,457,896.

(30) Foreign Application Priority Data
Jan. 15, 2021 (KR) 10-2021-00062207

(51) Int. Cl. H10K 85/60; H10K 50/15; H10K 50/16; H10K 50/17

(52) U.S. Cl. CPC H10K 85/615; H10K 85/626; H10K 85/6574; H10K 85/658; H10K 50/15; H10K 50/16; H10K 50/171

(57) ABSTRACT

Disclosed herein is an organic light emitting diode including a novel anthracene compound. More particularly, an organic light emitting diode including an anthracene compound represented by Chemical Formula A; and a compound represented by Chemical Formula B-1 or B-2 is provided. Chemical Formulas A, B-1, and B-2 are as defined in the description.

### CROSS-REFERENCE TO RELATED APPLICATIONS

This application is a Division of application Ser. No. 17/576,354, filed on Jan. 14, 2022, which in turn claims the priority of the Korean Patent Application No. 10-2021-0006207 filed on Jan. 15, 2021, in the Korean Intellectual Property Office, the disclosure of which is incorporated herein by reference.

### BACKGROUND OF THE INVENTION

### 1. Field of the Invention

The present disclosure relates to an organic light emitting diode including a novel anthracene compound and, more specifically, to an organic light emitting diode that employs specific host and dopant materials, thereby exhibiting diode characteristics including high efficiency and high longevity.

### 2. Description of the Related Art

Organic light-emitting diodes (OLEDs), which are self-emitting devices, enjoy advantages including a wide viewing angle, high contrast, fast response time, high luminance, a low driving voltage, a high response speed, and polychromatic properties.

A typical organic light emitting diode includes an anode and a cathode, which face each other, with an organic emission layer for light emission disposed therebetween.

In detail, the organic light-emitting diode may have a structure in which a hole transport layer, a light-emitting layer, an electron transport layer, and a cathode are sequentially formed on an anode. Here, the hole transport layer, the light-emitting layer, and the electron transport layer are each an organic thin film composed of an organic compound.

Having such a structure, the organic light-emitting diode operates according to the following principle. When a voltage is applied between the anode and the cathode, a hole injected from the anode moves toward the light-emitting layer through the hole transport layer while an electron injected from the cathode moves toward the light-emitting layer through the electron transport layer. In the light-emitting layer zone, the carriers such as a hole and an electron recombine to produce an exciton. The exciton returns to the ground state from the excited state, emitting light.

Materials used as organic layers in organic light-emitting diodes may be divided according to functions into luminescent materials and charge transport materials, for example, a hole injection material, a hole transport material, an electron transport material, and an electron injection material. The light-emitting mechanism forms the basis of classification of luminescent materials as fluorescent and phosphorescent materials, which use excitons in singlet and triplet states, respectively.

When a single material is employed as the luminescent material, intermolecular actions cause the maximum luminescence wavelength to shift toward a longer wavelength, resulting in a reduction in color purity and luminous efficiency due to light attenuation. In this regard, a host-dopant system may be used as a luminescent material so as to increase the color purity and the luminous efficiency through energy transfer. This is based on the principle whereby, when a dopant which is smaller in energy band gap than a host forming a light-emitting layer is added in a small amount to the light-emitting layer, excitons are generated from the light-emitting layer and transported to the dopant, emitting light at high efficiency. Here, light with desired wavelengths can be obtained depending on the kind of the dopant because the wavelength of the host moves to the wavelength range of the dopant.

Meanwhile, studies have been made to introduce a deuterium-substituted compound as a material in the light emitting layer in order to improve the longevity and stability of the organic light emitting diode.

Compounds substituted with deuterium are known to exhibit differences in thermodynamic behavior from those bonded with hydrogen because the atomic mass of deuterium is twice as great as that of hydrogen, which results in lower zero point energy and lower vibration energy level.

In addition, physicochemical properties involving deuterium, such as chemical bond lengths, etc., appear to be different from those involving hydrogen. In particular, the van der Waals radius of deuterium is smaller than that of hydrogen because of the smaller stretching amplitude of the C-D bond compared to the C—H bond. Generally, the C-D bond is shorter and stronger than the C—H bond. Upon deuterium substitution, the ground state energy is lowered and a short bond length is formed between the carbon atom and the deuterium atom. Accordingly, the molecular hardcore volume becomes smaller, thereby reducing the electron polarizability can be reduced, and the thin film volume can be increased by weakening the intermolecular interaction.

As discussed above, deuterium substitution provides the effect of reducing the crystallinity of the thin film, that is, it makes the thin film amorphous. Generally, a compound having deuterium substitution may be advantageously used to increase the lifespan and driving characteristics of an OLED and further improve the thermal resistance.

With respect to related arts for organic light emitting compounds containing deuterium, reference may be made to Korean Patent Number 10-1111406, which discloses a low-voltage driving and long lifespan diode employing a deuterium-substituted, carbazole-containing compound or a mixture of deuterium-substituted compounds and to Korean Patent Number 10-1068224, which discloses the use of an anthracene derivative bearing a deuterium-substituted phenyl group as a host.

In spite of various efforts, including the techniques of the cited documents, made to fabricate organic light emitting diodes exhibiting longevity characteristics, there is a still continuing need for development of an organic light-emitting diode that has improved long lifespan characteristics.

### RELATED ART DOCUMENT

### Patent Literature

(Patent literature 0001) Korean Patent Number 10-1111406 (Apr. 12, 2012)
(Patent literature 0002) Korean Patent Number 10-1068224 (Sep. 28, 2011)

### SUMMARY OF THE INVENTION

In order to solve problems encountered in the conventional techniques, an aspect of the present disclosure is to provide an organic light emitting diode (OLED) which employs an anthracene compound having a special structural characteristic as a host and a boron compound having a special structure as a dopant therein, whereby more enhanced long lifespan characteristics can be imparted to the organic light emitting diode.

The present disclosure provides an organic light-emitting diode comprising: a first electrode; a second electrode facing the first electrode; and an organic layer between the first electrode and the second electrode, wherein the organic layer includes a light emission layer containing a host and a dopant, the host comprising at least one of anthracene compounds represented by Chemical Formula A and the dopant comprising at least one of compounds represented by Chemical Formula B-1 or Chemical Formula B-2:

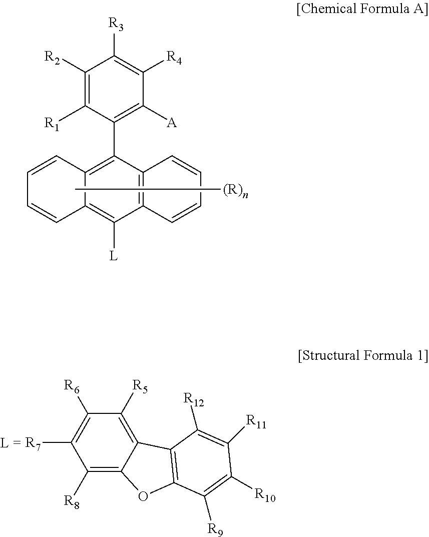

wherein,
A is any one selected from among a substituted or unsubstituted aryl of 6 to 50 carbon atoms, a substituted or unsubstituted heteroaryl of 2 to 50 carbon atoms, and a substituted or unsubstituted aliphatic/aromatic composite ring of 3 to 50 carbon atoms,
R₁ is a hydrogen atom or a deuterium atom,
R, and R₂ to R₁₂, which may be same or different, are each independently any one selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 30 carbon atoms, a substituted or unsubstituted cycloalkyl of 3 to 30 carbon atoms, a substituted or unsubstituted cycloalkenyl of 3 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 50 carbon atoms, a substituted or unsubstituted akylthioxy of 1 to 30 carbon atoms, a substituted or unsubstituted arylthioxy of 6 to 50 carbon atoms, a substituted or unsubstituted amine of 0 to 30 carbon atoms, a substituted or unsubstituted silyl of 0 to 30 carbon atoms, a substituted or unsubstituted aliphatic/aromatic composite ring of 3 to 50 carbon atoms, a cyano, a nitro, and a halogen, wherein a linkage may be made between adjacent two of the substituents R and R₂ to R₁₂ to form an additional mono- or polycyclic aliphatic or aromatic ring,
n is an integer of 1 to 8, wherein when n is 2 or greater, the R's are same or different,
one of R₅ to R₁₂ in Structural Formula 1 is a single bond to a carbon member of the anthracene moiety of Chemical Formula A, and
at least one substituent in Chemical Formula A is substituted by or bears a deuterium atom; and

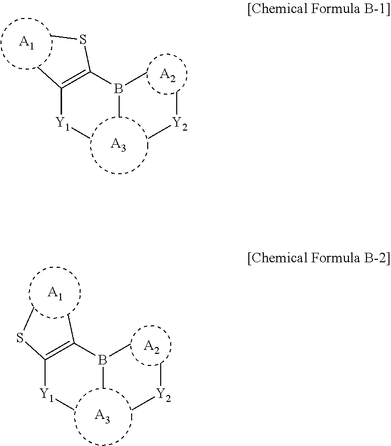

wherein,
A₁ to A₃, which may be same or different, are each independently any one selected from among a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, and a substituted or unsubstituted aliphatic/aromatic composite ring of 3 to 30 carbon atoms, wherein a linkage may be formed between adjacent two of substituents on the rings A₁ to A₃ to form an additional mono- or polycyclic aliphatic or aromatic ring,
Y₁ and Y₂, which may be same or different, are each independently any one selected from among NR₂₁, CR₂₂R₂₃, O, S. Se, and SiR₂₄R₂₅,
R₂₁ to R₂₅, which may be same or different, are each independently any one selected from among a hydrogen atom, a deuterium atom, substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arylthioxy of 6 to 30 carbon atoms, a substituted or unsubstituted amine of 0 to 30 carbon atoms, a substituted or unsubstituted silyl of 0 to 30 carbon atoms, a substituted or unsubstituted aliphatic/aromatic composite ring of 3 to 30 carbon atoms, a nitro, a cyano, and a halogen,
R₂₁ to R₂₅ may each be connected to at least one selected from among the rings A₁ to A₃ to form an additional mono- or polycyclic aliphatic or aromatic ring, and
a bond may be made between R₂₂ and R₂₃ and between R₂₄ and R₂₅ to form additional respective mono- or polycyclic aliphatic or aromatic rings,
wherein the term “substituted” in the expression “substituted or unsubstituted” used for compounds of Chemical Formulas A, B-1, and B-2 means having at least one substituent selected from the group consisting of a deuterium atom, a cyano, a halogen, a hydroxy, a nitro, an alkyl of 1 to 24 carbon atoms, an halogenated alkyl of 1 to 24 carbon atoms, a cycloalkyl of 3 to 30 carbon atoms, an alkenyl of 2 to 24 carbon atoms, an alkynyl of 2 to 24 carbon atoms, a heteroalkyl of 1 to 24 carbon atoms, an aryl of 6 to 30 carbon atoms, an arylalkyl of 7 to 30 carbon atoms, an alkylaryl of 7 to 30 carbon atoms, a heteroaryl of 2 to 30 carbon atoms, a heteroarylalkyl of 2 to 30 carbon atoms, an amine of 0 to 24 carbon atoms, a silyl of 0 to 24 carbon atoms, an aryloxy of 6 to 30 carbon atoms, and an aliphatic/aromatic composite ring of 3 to 30 carbon atoms.

When employing the novel anthracene compound according to the present disclosure as a host material therein, an organic light emitting diode exhibits longevity characteristics and more improved efficiency, compared to conventional organic light emitting diodes.

### BRIEF DESCRIPTION OF THE DRAWINGS

The above and other aspects, features and advantages of the present disclosure will be more apparent from the following detailed description taken in conjunction with the accompanying drawing, in which:

FIG. 1 is a schematic diagram depicting the structure of an organic light-emitting diode according to some embodiments of the present disclosure.

### DETAILED DESCRIPTION OF THE EXEMPLARY EMBODIMENTS

Below, a detailed description will be given of the present disclosure with reference to the accompanying drawing so as for a person skilled in the art to implement the present disclosure.

In the drawing of the present disclosure, sizes or scales of components may be enlarged or reduced than their actual sizes or scales for better illustration, and known components are not depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In drawings, for convenience of description, sizes of components may be exaggerated for clarity. For example, since sizes and thicknesses of components in drawings are arbitrarily shown for convenience of description, the sizes and thicknesses are not limited thereto. Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between”, may be used herein for ease of description to refer to the relative positioning.

Throughout the specification, when a portion may “include” a certain constituent element, unless explicitly described to the contrary, it may not be construed to exclude another constituent element but may be construed to further include other constituent elements. Further, throughout the specification, the word “on” means positioning on or below the object portion, but does not essentially mean positioning on the lower side of the object portion based on a gravity direction.

The present disclosure provides an organic light emitting diode (OLED) which employs a deuterated anthracene compound having a special structural characteristic and as a host and a boron compound having a special structure as a dopant therein, whereby more enhanced long lifespan characteristics can be imparted to the organic light emitting diode.

More specifically, the present disclosure provides an organic light-emitting diode comprising: a first electrode; a second electrode facing the first electrode; and an organic layer between the first electrode and the second electrode, wherein the organic layer includes a light emission layer containing a host and a dopant, the host comprising at least one of anthracene compounds represented by Chemical Formula A and the dopant comprising at least one of compounds represented by Chemical Formula B-1 or Chemical Formula B-2:

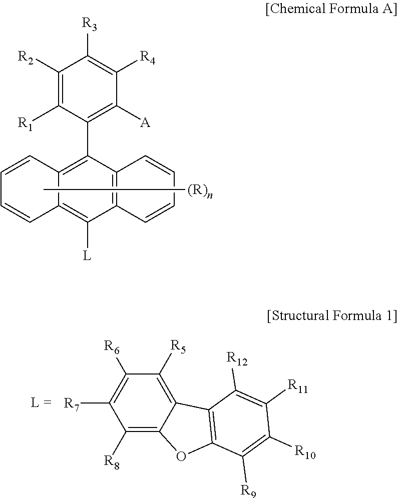

wherein,
A is any one selected from among a substituted or unsubstituted aryl of 6 to 50 carbon atoms, a substituted or unsubstituted heteroaryl of 2 to 50 carbon atoms, and a substituted or unsubstituted aliphatic/aromatic composite ring of 3 to 50 carbon atoms,
R₁ is a hydrogen atom or a deuterium atom,
R, and R₂ to R₁₂, which may be same or different, are each independently any one selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 30 carbon atoms, a substituted or unsubstituted cycloalkyl of 3 to 30 carbon atoms, a substituted or unsubstituted cycloalkenyl of 3 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 50 carbon atoms, a substituted or unsubstituted akylthioxy of 1 to 30 carbon atoms, a substituted or unsubstituted arylthioxy of 6 to 50 carbon atoms, a substituted or unsubstituted amine of 0 to 30 carbon atoms, a substituted or unsubstituted silyl of 0 to 30 carbon atoms, a substituted or unsubstituted aliphatic/aromatic composite ring of 3 to 50 carbon atoms, a cyano, a nitro, and a halogen, wherein a linkage may be made between adjacent two of the substituents R and R₂ to R₁₂ to form an additional mono- or polycyclic aliphatic or aromatic ring,
n is an integer of 1 to 8, wherein when n is 2 or greater, the R's are same or different,
one of R₅ to R₁₂ in Structural Formula 1 is a single bond to a carbon member of the anthracene moiety of Chemical Formula A, and
at least one substituent in Chemical Formula A is substituted by or bears a deuterium atom; and

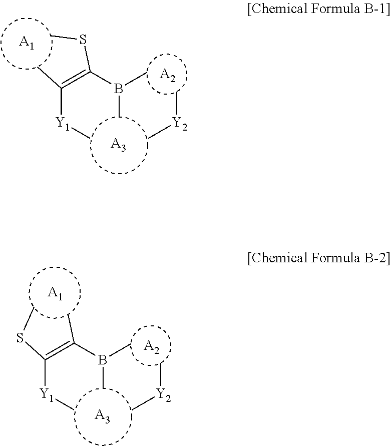

wherein,
A₁ to A₃, which may be same or different, are each independently any one selected from among a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, and a substituted or unsubstituted aliphatic/aromatic composite ring of 3 to 30 carbon atoms, wherein a linkage may be formed between adjacent two of substituents on the rings A₁ to A₃ to form an additional mono- or polycyclic aliphatic or aromatic ring,
Y₁ and Y₂, which may be same or different, are each independently any one selected from among NR₂₁, CR₂₂R₂₃, O, S, Se, and SiR₂₄R₂₅,
R₂₁ to R₂₅, which may be same or different, are each independently any one selected from among a hydrogen atom, a deuterium atom, substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arylthioxy of 6 to 30 carbon atoms, a substituted or unsubstituted amine of 0 to 30 carbon atoms, a substituted or unsubstituted silyl of 0 to 30 carbon atoms, a substituted or unsubstituted aliphatic/aromatic composite ring of 3 to 30 carbon atoms, a nitro, a cyano, and a halogen,
R₂₁ to R₂₅ may each be connected to at least one selected from among the rings A₁ to A₃ to form an additional mono- or polycyclic aliphatic or aromatic ring, and
a bond may be made between R₂₂ and R₂₃ and between R₂₄ and R₂₅ to form additional respective mono- or polycyclic aliphatic or aromatic rings,
wherein the term “substituted” in the expression “substituted or unsubstituted” used for compounds of Chemical Formulas A, B-1, and B-2 means having at least one substituent selected from the group consisting of a deuterium atom, a cyano, a halogen, a hydroxy, a nitro, an alkyl of 1 to 24 carbon atoms, an halogenated alkyl of 1 to 24 carbon atoms, a cycloalkyl of 3 to 30 carbon atoms, an alkenyl of 2 to 24 carbon atoms, an alkynyl of 2 to 24 carbon atoms, a heteroalkyl of 1 to 24 carbon atoms, an aryl of 6 to 30 carbon atoms, an arylalkyl of 7 to 30 carbon atoms, an alkylaryl of 7 to 30 carbon atoms, a heteroaryl of 2 to 30 carbon atoms, a heteroarylalkyl of 2 to 30 carbon atoms, an amine of 0 to 24 carbon atoms, a silyl of 0 to 24 carbon atoms, an aryloxy of 6 to 30 carbon atoms, and an aliphatic/aromatic composite ring of 3 to 30 carbon atoms.

The expression indicating the number of carbon atoms, such as “a substituted or unsubstituted alkyl of 1 to 30 carbon atoms”, “a substituted or unsubstituted aryl of 5 to 50 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical derived from an aromatic hydrocarbon by removing one hydrogen that is bonded to the aromatic hydrocarbon. It may be a single or a fused aromatic system, and when it comes to the latter, the aromatic system may include a fused ring that is formed by adjacent substituents on the aryl radical.

Examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl, but are not limited thereto. At least one hydrogen atom of the aryl may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 carbon atoms, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 1 to 24 carbon atoms, an alkynyl of 1 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The term “heteroaryl” substituent used in the compounds of the present disclosure refers to a hetero aromatic radical of 2 to 24 carbon atoms bearing 1, 2, or 3 heteroatoms selected from among N, O, P, Si, S, Ge, Se, and Te. In the aromatic radical, two or more rings may be fused. One or more hydrogen atoms on the heteroaryl may be substituted by the same substituents as on the aryl.

In addition, the term “heteroaromatic ring”, as used herein, refers to an aromatic hydrocarbon ring bearing as aromatic ring members 1 to 3 heteroatoms selected particularly from among N, O, P, Si, S, Ge, Se, and Te.

As used herein, the term “alkyl” refers to an alkane missing one hydrogen atom and includes linear or branched structures. Examples of the alkyl substituent useful in the present disclosure include methyl, ethyl, propyl, isopropyl, isobutyl, sec-butyl, tert-butyl, pentyl, isoamyl, hexyl, and the like. At least one hydrogen atom of the alkyl may be substituted by the same substituent as in the aryl.

The term “cyclo” as used in substituents of the compounds of the present disclosure, such as cycloalkyl, etc., refers to a structure responsible for a mono- or polycyclic ring of saturated hydrocarbons. Concrete examples of cycloalkyl radicals include cyclopropyl, cyclobutyl, cyclopentyl, cyclohexyl, methylcyclopentyl, methylcyclohexyl, ethylcyclopentyl, ethylcyclohexyl, adamantyl, dicyclopentadienyl, decahydronaphthyl, norbornyl, bornyl, isobornyl, and so on. One or more hydrogen atoms on the cycloalkyl may be substituted by the same substituents as on the aryl.

The term “alkoxy” as used in the compounds of the present disclosure refers to an alkyl or cycloalkyl singularly bonded to oxygen. Concrete examples of the alkoxy include methoxy, ethoxy, propoxy, isobutoxy, sec-butoxy, pentoxy, iso-amyloxy, hexyloxy, cyclobutyloxy, cyclopentyloxy, adamantyloxy, dicyclopentyloxy, bornyloxy, isobornyloxy, and the like. One or more hydrogen atoms on the alkoxy may be substituted by the same substituents as on the aryl.

Concrete examples of the arylalkyl used in the compounds of the present disclosure include phenylmethyl (benzyl), phenylethyl, phenylpropyl, naphthylmethyl, naphthylethyl, and the like. One or more hydrogen atoms on the arylalkyl may be substituted by the same substituents as on the aryl.

As used herein, the term “alkenyl” refers to an unsaturated hydrocarbon group that contains a carbon-carbon double bond between two carbon atoms and the term “alkynyl” refers to an unsaturated hydrocarbon group that contains a carbon-carbon triple bond between two carbon atoms.

As used herein, the term “alkylene” refers to an organic aliphatic radical regarded as derived from a linear or branched saturated hydrocarbon alkane by removal of two hydrogen atoms from different carbon atoms. Concrete examples of the alkylene include methylene, ethylene, propylene, isopropylene, isobutylene, sec-butylene, tert-butylene, pentylene, iso-amylene, hexylene, and so on. One or more hydrogen atoms on the alkylene may be substituted by the same substituents as on the aryl.

The term “aliphatic/aromatic composite ring” or “aliphatic/aromatic composite ring radical” used in the compounds of the present disclosure refers to a cyclic moiety which has two or more rings condensed to each other, with non-aromaticity appearing on the whole molecule thereof. In addition, a polycyclic aliphatic/aromatic composite ring may bear a heteroatom selected from among N, O, P, and S in addition to C.

Furthermore, the term “amine”, as used herein, is indented to encompass —NH₂, alkylamine, arylamine, alkylarylamine, arylheteroarylamine, heteroarylamine, etc. Here, arylamine refers to an amine resulting from substitution of aryl for one or two hydrogen atoms of —NH₂; alkylamine refers to an amine resulting from substitution of alkyl for one or two hydrogen atoms of —NH₂; alkylarylamine refers to an amine resulting from substitution of alkyl and aryl for the two hydrogen atoms of —NH₂, respectively; arylheteroarylamine refers to an amine resulting from substitution of aryl and heteroaryl for the two hydrogen atoms of —NH₂; and heteroarylamine refers to an amine resulting from substitution of heteroaryl for one or two hydrogen atoms of —NH₂. Examples of the arylamine include a substituted or unsubstituted monoarylamine and a substituted or unsubstituted diarylamine, and the same application may be made to alkylamine and heteroarylamine.

Here, the aryl in each of arylamine, heteroarylamine, and arylheteroarylamine may be monocyclic aryl or polycyclic aryl. The heteroaryl in each of arylamine, heteroarylamine, and arylheteroarylamine may be monocyclic heteroaryl or polycyclic heteroaryl.

The term “silyl” used in the compounds of the present disclosure is intended to encompass —SiH₃, alkylsilyl, arylsilyl, arylsilyl, alkylarylsilyl, arylheteroarylsilyl, heteroarylsilyl, and the like. Here, arylsilyl refers to a silyl resulting from substitution of aryl for one, two, or three hydrogen atoms of —SiH₃; alkylsilyl refers to a silyl resulting from substitution of alkyl for one, two, or three hydrogen atoms of —SiH₃; alkylarylsilyl refers to a silyl resulting from substitution of alkyl for one or two hydrogen atoms of —SiH₃ and aryl for one or two hydrogen atoms of —SiH₃; arylheteroarylsilyl refers to a silyl resulting from substitution of aryl for one or two hydrogen atoms of —SiH₃ and heteroaryl for one or two hydrogen atoms of —SiH₃; heteroarylsilyl refers to a silyl resulting from substitution of heteroaryl for one, two, or three hydrogen atoms of —SiH₃. Examples of the arylsilyl include a substituted or unsubstituted monoarylsilyl, a substituted or unsubstituted diarylsilyl, and a substituted or unsubstituted triarylsilyl, and the same application may be made to alkylsilyl and heteroarylsilyl.

Here, the aryl in each of arylsilyl, heteroarylsilyl, and arylheteroarylsilyl may be monocyclic aryl or polycyclic aryl. The heateroaryl in each of arylsilyl, heteroarylsilyl, and arylheteroarylsilyl may be monocyclic heteroaryl and polycyclic heteroaryl.

Concrete examples of the silyl radicals used in the compounds of the present disclosure include trimethylsilyl, triethylsilyl, triphenylsilyl, trimethoxysilyl, dimethoxyphenylsilyl, diphenylmethylsilyl, diphenylvinlysilyl, methylcyclobutylsilyl, dimethyl furylsilyl, and the like. One or more hydrogen atoms on the silyl may be substituted by the same substituents as on the aryl.

As more particular examples accounting for the term “substituted” in the expression “substituted or unsubstituted” used for compounds of Chemical Formulas A, B-1, and B-2, the compounds may be substituted by at least one substituent selected from the group consisting of a deuterium atom, a cyano, a halogen, a hydroxy, a nitro, an alkyl of 1 to 12 carbon atoms, a halogenated alkyl of 1 to 12 carbon atoms, a cycloalkyl of 3 to 12 carbon atoms, an alkenyl of 2 to 12 carbon atoms, an alkynyl of 2 to 12 carbon atoms, a heteroalkyl of 1 to 12 carbon atoms, an aryl of 6 to 18 carbon atoms, an arylalkyl of 7 to 20 carbon atoms, an alkylaryl of 7 to 20 carbon atoms, a heteroaryl of 2 to 18 carbon atoms, a heteroarylalkyl of 2 to 18 carbon atoms, an alkoxy of 1 to 12 carbon atoms, an alkylamino of 1 to 12 carbon atoms, an amine of 0 to 18 carbon atoms, a silyl of 0 to 18 carbon atoms, an aryloxy of 6 to 18 carbon atoms, an aliphatic/aromatic composite ring of 3 to 18 carbon atoms.

The anthracene compound, represented by Chemical Formula A, which is used as a host in the organic light-emitting diode according to the present disclosure, is structurally characterized by the anthracene ring moiety possessing the phenyl substituted with A and R₁ to R₄ as a substituent on the carbon atom at position 10 thereof, wherein R₁ is a hydrogen atom or a deuterium atom and A is any one selected from among a substituted or unsubstituted aryl of 6 to 50 carbon atoms, a substituted or unsubstituted heteroaryl of 2 to 50 carbon atoms, and a substituted or unsubstituted aliphatic/aromatic composite ring of 3 to 50 carbon atoms; and technically characterized by the dibenzofuran ring moiety substituted with R₅ to R₁₂, represented by Structural Formula 1, which is located on the carbon atom at position 9 of the anthracene moiety, wherein one of R₅ to R₁₂ is a single bond through which the anthracene ring moiety is linked to the dibenzofuran ring moiety, with at least one substituent in Chemical Formula A is substituted by or bears a deuterium atom.

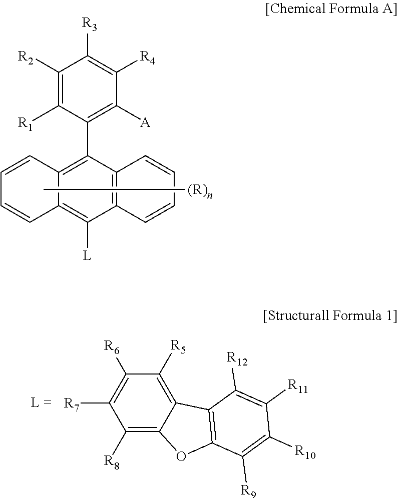

In a particular embodiment of the present disclosure, the A substituent in Chemical Formula A may be a deuterium-substituted or unsubstituted an aryl of 6 to 30 carbon atoms.

In another particular embodiment of the present disclosure, the A substituent may be any one selected from among a deuterium-substituted or unsubstituted phenyl, a deuterium-substituted or unsubstituted biphenyl, a deuterium-substituted or unsubstituted terphenyl, a deuterium-substituted or unsubstituted naphthyl, a deuterium-substituted or unsubstituted phenanthryl.

According to another particular embodiment, at least one of the R's in Chemical Formula A may be a deuterium atom, preferably two or more of R's may be deuterium atoms, more preferably four or more of R's may be deuterium atoms, and even more preferably all of R's may be deuterium atoms.

In a particular embodiment, at least one of R₂ to R₄ in Chemical Formula A may be selected from a hydrogen atom, a deuterium atom, and a substituted or unsubstituted an aryl of 6 to 30 carbon atoms. In a more particular embodiment, R₂ to R₄, which are same or different, may each be independently selected from among a deuterium atom and a substituted or unsubstituted an aryl of 6 to 30 carbon atoms.

In another particular embodiment, at least one of the substituents R₅ to R₁₂, which are not single bond in Chemical Formula A, may be a deuterium-substituted or unsubstituted aryl of 6 to 30 carbon atoms.

In a particular embodiment, the anthracene compound represented by Chemical Formula A has preferably a degree of deuteration of 20% or higher, more preferably a degree of deuteration of 30% or higher, more preferably a degree of deuteration of 35% or higher, more preferably a degree of deuteration of 40% or higher, more preferably a degree of deuteration of 45% or higher, more preferably a degree of deuteration of 50% or higher, more preferably a degree of deuteration of 55% or higher, more preferably a degree of deuteration of 60% or higher, more preferably a degree of deuteration of 65% or higher, more preferably a degree of deuteration of 70% or higher, more preferably a degree of deuteration of 75% or higher, and more preferably a degree of deuteration of 80% or higher.

With respect to the degree of deuteration used herein, the term “deuterated derivative” of compound X means a compound that is structurally identical to compound X, but has at least one deuterium (D) atom in substitution with a hydrogen atom (H) bonded to a carbon atom, a nitrogen atom, or an oxygen atom in compound X.

In this regard, the term “yy % deuterated” or “yy % deuteration” refers to yy % for the ratio of deuterium atoms to a sum of hydrogen and deuterium atoms bonded directly to carbon, nitrogen, or oxygen atoms within compound X.

Thus, when two of six hydrogen atoms in benzene, the resulting benzene compound C6H4D2 is 33% deuterated (2/(4+2)×100=33%).

Likewise, when the anthracene compound of the present disclosure is deuterated, the degree of deuteration thereof is expressed as a percentage of deuterium atoms bonded directly to carbon atoms within the anthracene compound relative to a sum of hydrogen and deuterium atoms bonded directly to carbon atoms within the anthracene compound.

For example, the anthracene compound represented by Compound 1, below, has a total of five deuterium atoms bonded to the phenyl group linked to the anthracene moiety and
a total of 19 hydrogen atoms including four hydrogen atoms bonded to the phenyl group linked to the anthracene moiety, eight hydrogen atoms bonded to the anthracene moiety, and seven hydrogen atoms bonded to the 6-membered aromatic rings of the dibenzofuran, so that its degree of deuteration can be calculated as 100×5/(5+19)=20.8%:

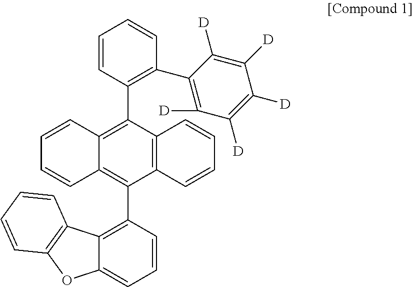 [SMILES: [2H]c1c([2H])c([2H])c(-c2ccccc2-c2c3ccccc3c(-c3cccc4oc5ccccc5c34)c3ccccc23)c([2H])c1[2H]]

For a specific substituent, a degree of deuteration may differ from one compound molecule to another and thus is expressed as an average value.

An example is given by a partially deuterium-substituted anthracene radical. When a deuterium atom is intended to be substituted on all carbon atoms in an anthracene, the resulting anthracene compound may be deuterated fully or partially according to reaction conditions. That is, there may be a mixture including fully deuterated anthracene molecules and partially deuterated anthracene molecules. It is very difficult to separate the fully deuterated anthracene molecules and the partially deuterated anthracene molecules from each other. In this case, the degree of deuteration can be calculated according to the entire structural formula with reference to an average degree of deuteration.

According to the present disclosure, the use of the anthracene compound represented by Chemical Formula A as a host material for a light emission layer in an organic light-emitting diode can further improve the lifespan of the organic light-emitting diode.

In greater detail, the anthracene compound represented by Chemical Formula A may be any one selected from the group consisting of <Compound 1> to <Compound 60>, but is not limited thereto:

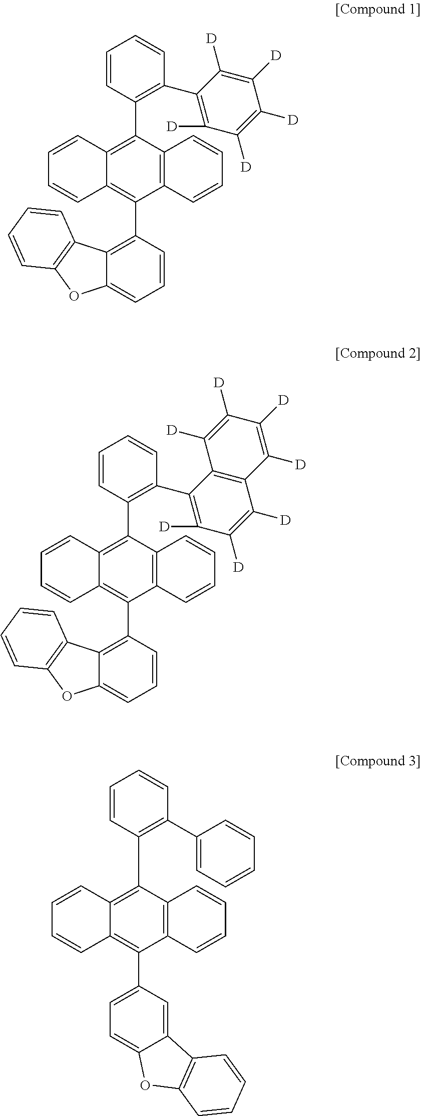 [SMILES: [2H]c1c([2H])c([2H])c(-c2ccccc2-c2c3ccccc3c(-c3cccc4oc5ccccc5c34)c3ccccc23)c([2H])c1[2H] ; [2H]c1c([2H])c([2H])c2c(-c3ccccc3-c3c4ccccc4c(-c4cccc5oc6ccccc6c45)c4ccccc34)c([2H])c([2H])c([2H])c2c1[2H] ; c1ccc(-c2ccccc2-c2c3ccccc3c(-c3ccc4oc5ccccc5c4c3)c3ccccc23)cc1]

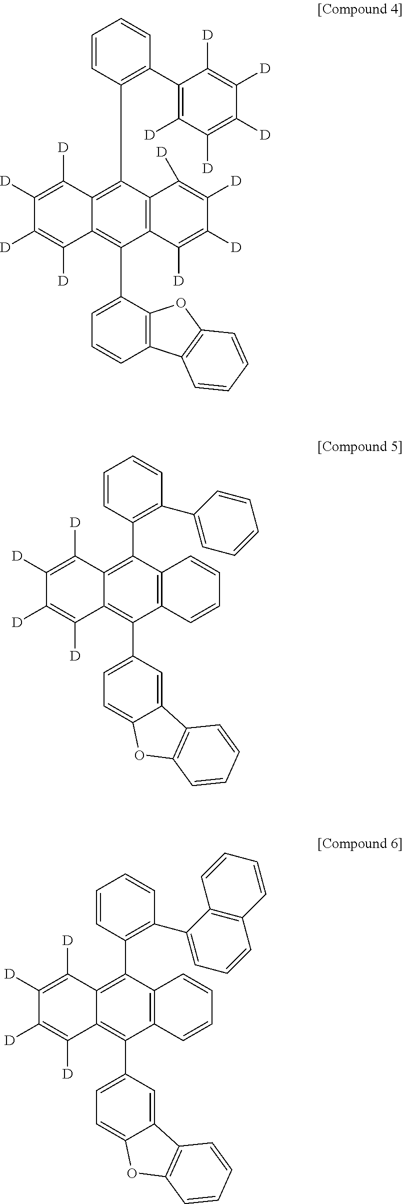 [SMILES: [2H]c1c([2H])c([2H])c(-c2ccccc2-c2c3c([2H])c([2H])c([2H])c([2H])c3c(-c3cccc4c3oc3ccccc34)c3c([2H])c([2H])c([2H])c([2H])c23)c([2H])c1[2H] ; [2H]c1c([2H])c([2H])c2c(-c3ccccc3-c3ccccc3)c3ccccc3c(-c3ccc4oc5ccccc5c4c3)c2c1[2H] ; [2H]c1c([2H])c([2H])c2c(-c3ccccc3-c3cccc4ccccc34)c3ccccc3c(-c3ccc4oc5ccccc5c4c3)c2c1[2H]]

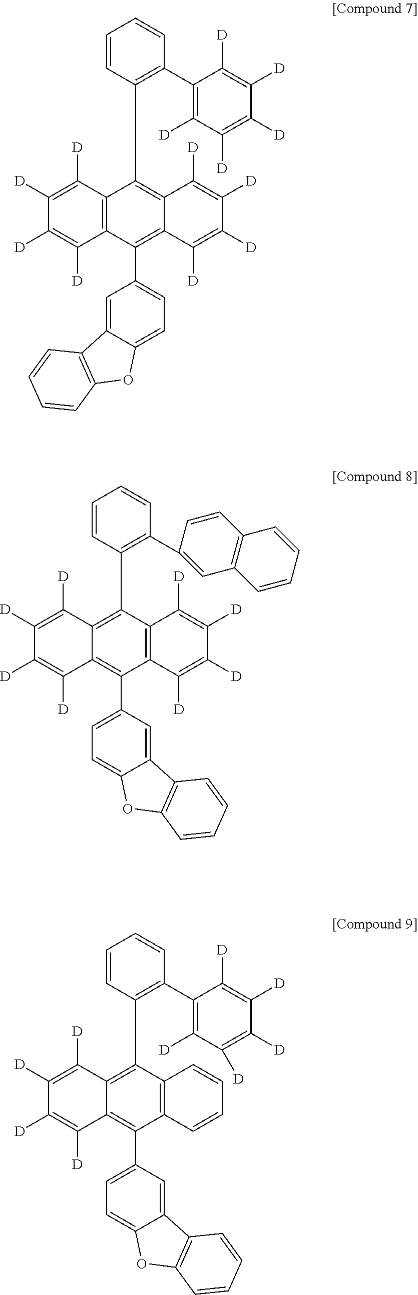 [SMILES: [2H]c1c([2H])c([2H])c(-c2ccccc2-c2c3c([2H])c([2H])c([2H])c([2H])c3c(-c3ccc4oc5ccccc5c4c3)c3c([2H])c([2H])c([2H])c([2H])c23)c([2H])c1[2H] ; [2H]c1c([2H])c([2H])c2c(-c3ccccc3-c3ccc4ccccc4c3)c3c([2H])c([2H])c([2H])c([2H])c3c(-c3ccc4oc5ccccc5c4c3)c2c1[2H] ; [2H]c1c([2H])c([2H])c(-c2ccccc2-c2c3ccccc3c(-c3ccc4oc5ccccc5c4c3)c3c([2H])c([2H])c([2H])c([2H])c23)c([2H])c1[2H]]

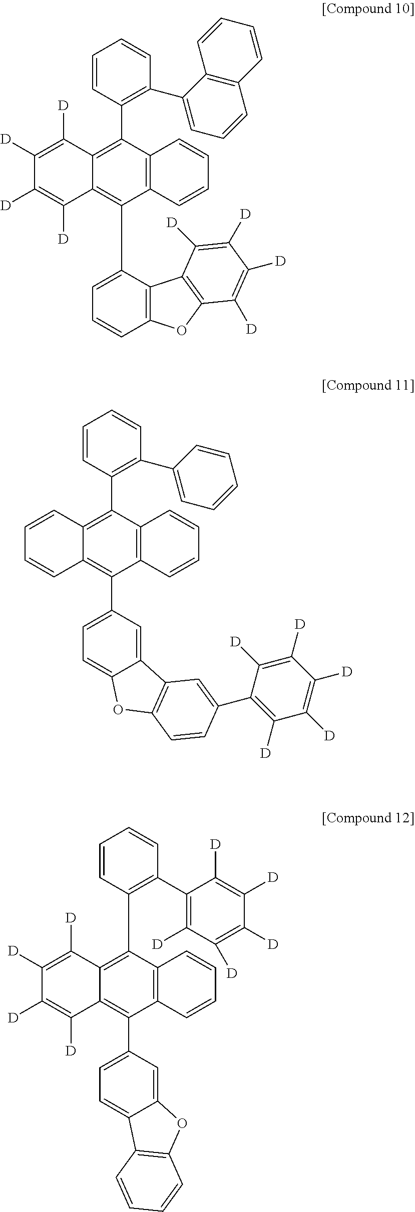 [SMILES: [2H]c1c([2H])c([2H])c2c(oc3cccc(-c4c5ccccc5c(-c5ccccc5-c5cccc6ccccc56)c5c([2H])c([2H])c([2H])c([2H])c45)c32)c1[2H] ; [2H]c1c([2H])c([2H])c(-c2ccc3oc4ccc(-c5c6ccccc6c(-c6ccccc6-c6ccccc6)c6ccccc56)cc4c3c2)c([2H])c1[2H] ; [2H]c1c([2H])c([2H])c(-c2ccccc2-c2c3ccccc3c(-c3ccc4c(c3)oc3ccccc34)c3c([2H])c([2H])c([2H])c([2H])c23)c([2H])c1[2H]]

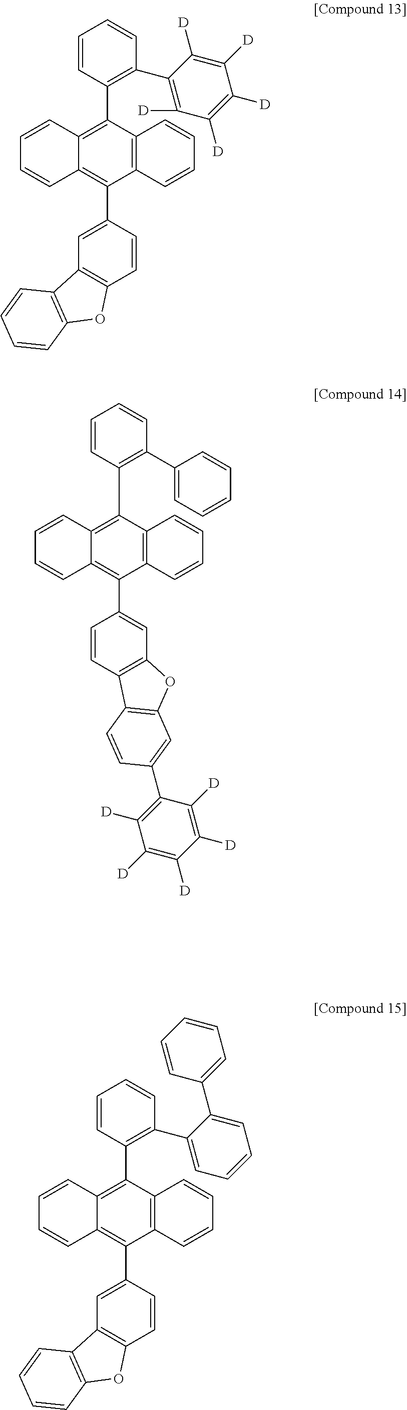 [SMILES: [2H]c1c([2H])c([2H])c(-c2ccccc2-c2c3ccccc3c(-c3ccc4oc5ccccc5c4c3)c3ccccc23)c([2H])c1[2H] ; [2H]c1c([2H])c([2H])c(-c2ccc3c(c2)oc2cc(-c4c5ccccc5c(-c5ccccc5-c5ccccc5)c5ccccc45)ccc23)c([2H])c1[2H] ; c1ccc(-c2ccccc2-c2ccccc2-c2c3ccccc3c(-c3ccc4oc5ccccc5c4c3)c3ccccc23)cc1]

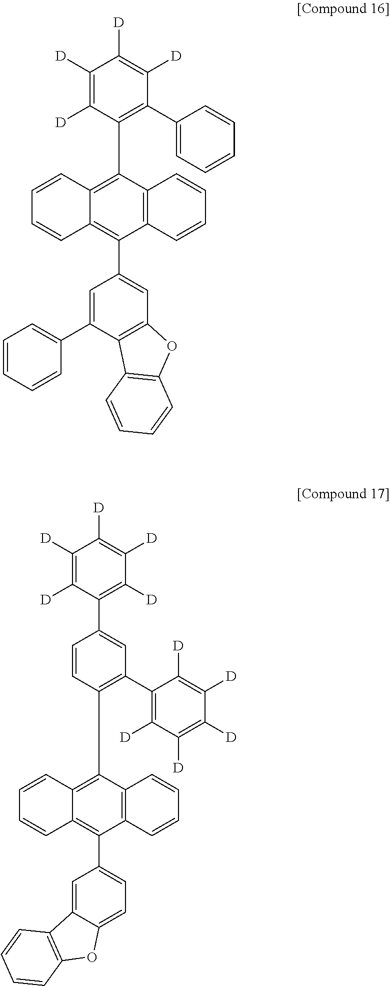 [SMILES: [2H]c1c([2H])c([2H])c(-c2c3ccccc3c(-c3cc(-c4ccccc4)c4c(c3)oc3ccccc34)c3ccccc23)c(-c2ccccc2)c1[2H] ; [2H]c1c([2H])c([2H])c(-c2ccc(-c3c4ccccc4c(-c4ccc5oc6ccccc6c5c4)c4ccccc34)c(-c3c([2H])c([2H])c([2H])c([2H])c3[2H])c2)c([2H])c1[2H]]

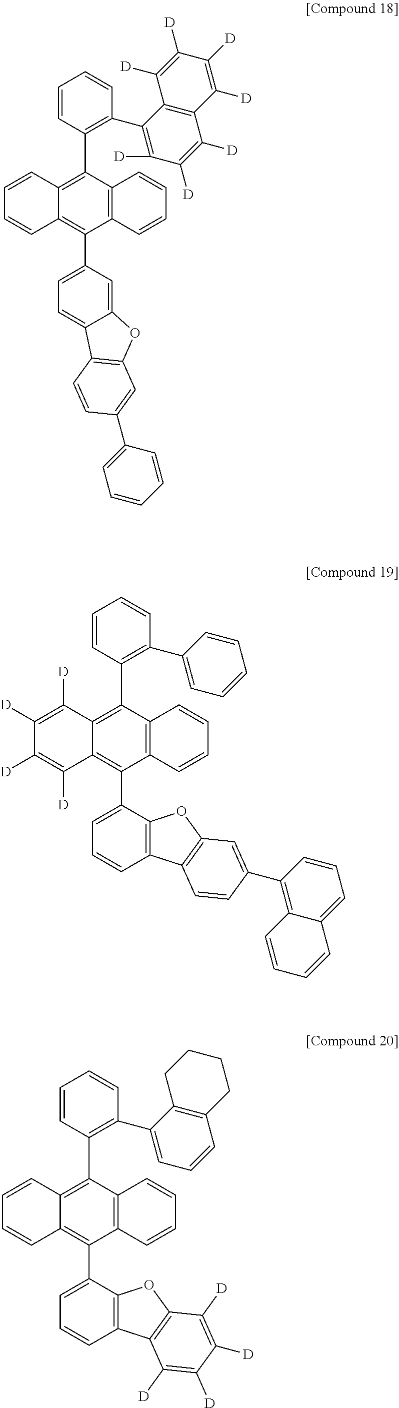 [SMILES: [2H]c1c([2H])c([2H])c2c(-c3ccccc3-c3c4ccccc4c(-c4ccc5c(c4)oc4cc(-c6ccccc6)ccc45)c4ccccc34)c([2H])c([2H])c([2H])c2c1[2H] ; [2H]c1c([2H])c([2H])c2c(-c3cccc4c3oc3cc(-c5cccc6ccccc56)ccc34)c3ccccc3c(-c3ccccc3-c3ccccc3)c2c1[2H] ; [2H]c1c([2H])c([2H])c2c(oc3c(-c4c5ccccc5c(-c5ccccc5-c5cccc6c5CCCC6)c5ccccc45)cccc32)c1[2H]]

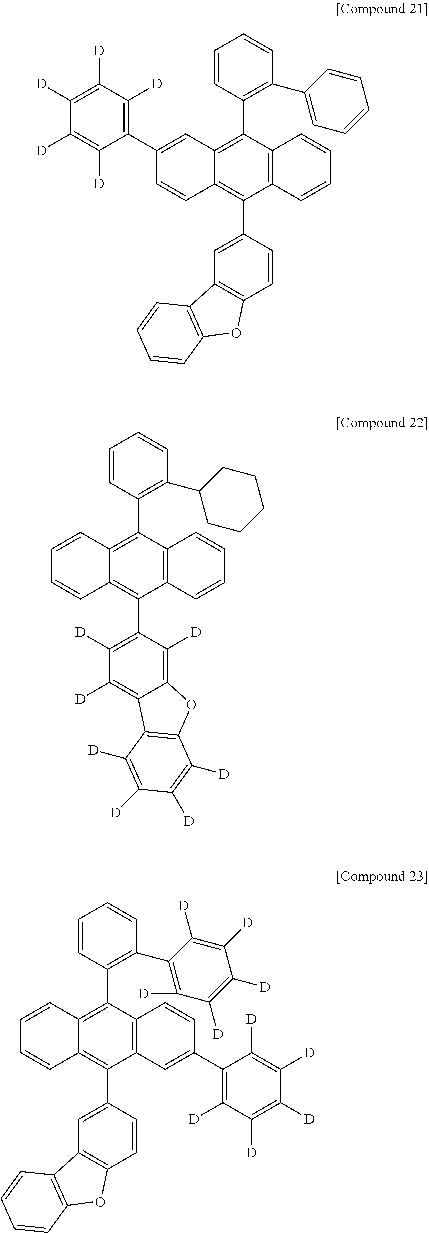 [SMILES: [2H]c1c([2H])c([2H])c(-c2ccc3c(-c4ccc5oc6ccccc6c5c4)c4ccccc4c(-c4ccccc4-c4ccccc4)c3c2)c([2H])c1[2H] ; [2H]c1c([2H])c([2H])c2c(oc3c([2H])c(-c4c5ccccc5c(-c5ccccc5C5CCCCC5)c5ccccc45)c([2H])c([2H])c32)c1[2H] ; [2H]c1c([2H])c([2H])c(-c2ccc3c(-c4ccccc4-c4c([2H])c([2H])c([2H])c([2H])c4[2H])c4ccccc4c(-c4ccc5oc6ccccc6c5c4)c3c2)c([2H])c1[2H]]

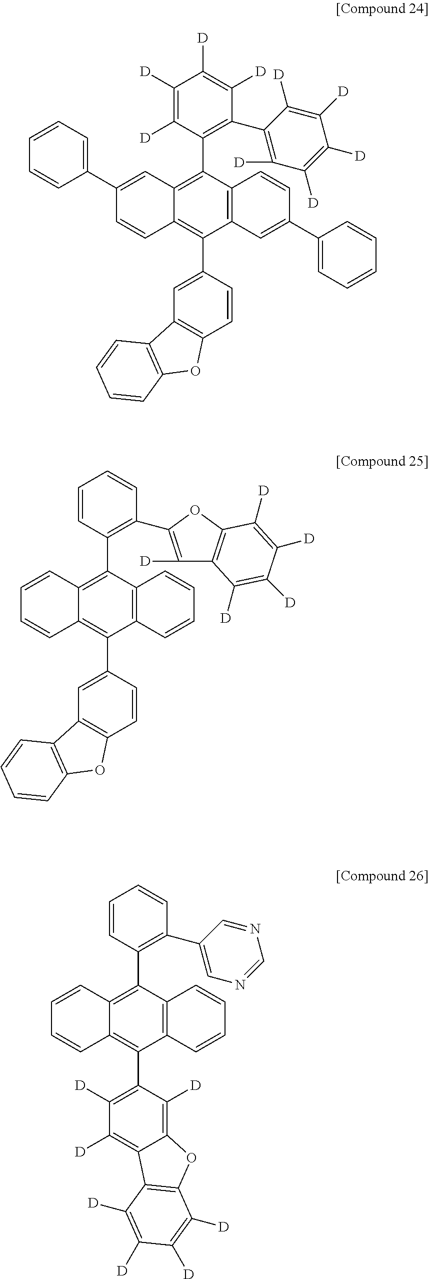 [SMILES: [2H]c1c([2H])c([2H])c(-c2c([2H])c([2H])c([2H])c([2H])c2-c2c3ccc(-c4ccccc4)cc3c(-c3ccc4oc5ccccc5c4c3)c3ccc(-c4ccccc4)cc23)c([2H])c1[2H] ; [2H]c1c([2H])c([2H])c2c([2H])c(-c3ccccc3-c3c4ccccc4c(-c4ccc5oc6ccccc6c5c4)c4ccccc34)oc2c1[2H] ; [2H]c1c([2H])c([2H])c2c(oc3c([2H])c(-c4c5ccccc5c(-c5ccccc5-c5cncnc5)c5ccccc45)c([2H])c([2H])c32)c1[2H]]

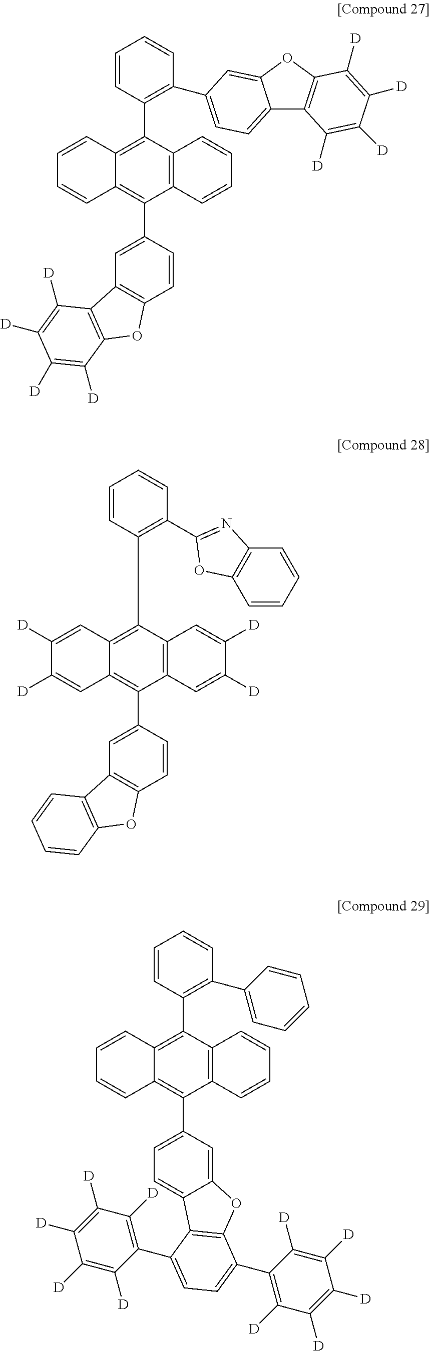 [SMILES: [2H]c1c([2H])c([2H])c2c(oc3cc(-c4ccccc4-c4c5ccccc5c(-c5ccc6oc7c([2H])c([2H])c([2H])c([2H])c7c6c5)c5ccccc45)ccc32)c1[2H] ; [2H]c1cc2c(-c3ccc4oc5ccccc5c4c3)c3cc([2H])c([2H])cc3c(-c3ccccc3-c3nc4ccccc4o3)c2cc1[2H] ; [2H]c1c([2H])c([2H])c(-c2ccc(-c3c([2H])c([2H])c([2H])c([2H])c3[2H])c3c2oc2cc(-c4c5ccccc5c(-c5ccccc5-c5ccccc5)c5ccccc45)ccc23)c([2H])c1[2H]]

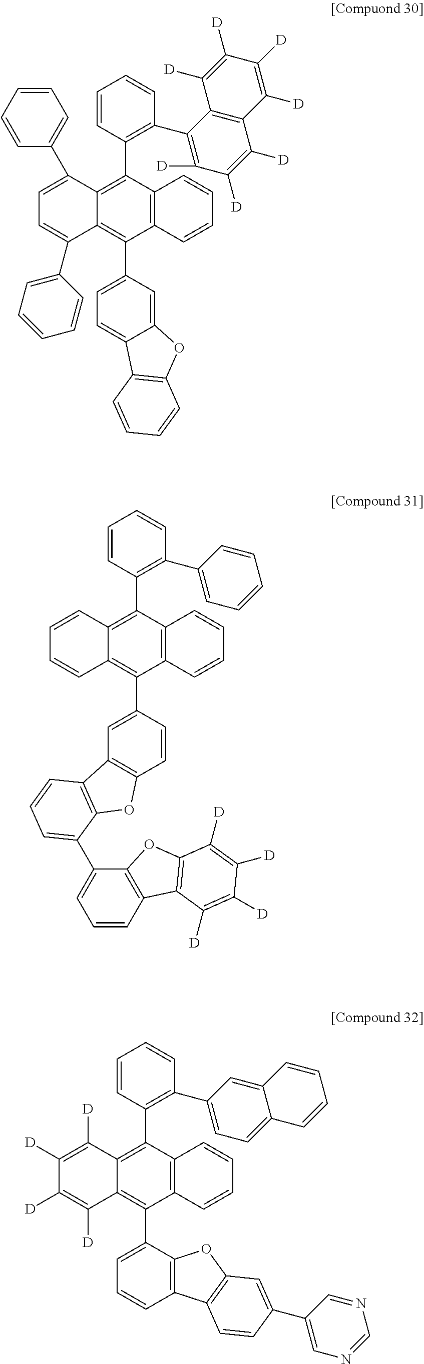 [SMILES: [2H]c1c([2H])c([2H])c2c(-c3ccccc3-c3c4ccccc4c(-c4ccc5c(c4)oc4ccccc45)c4c(-c5ccccc5)ccc(-c5ccccc5)c34)c([2H])c([2H])c([2H])c2c1[2H] ; [2H]c1c([2H])c([2H])c2c(oc3c(-c4cccc5c4oc4ccc(-c6c7ccccc7c(-c7ccccc7-c7ccccc7)c7ccccc67)cc45)cccc32)c1[2H] ; [2H]c1c([2H])c([2H])c2c(-c3cccc4c3oc3cc(-c5cncnc5)ccc34)c3ccccc3c(-c3ccccc3-c3ccc4ccccc4c3)c2c1[2H]]

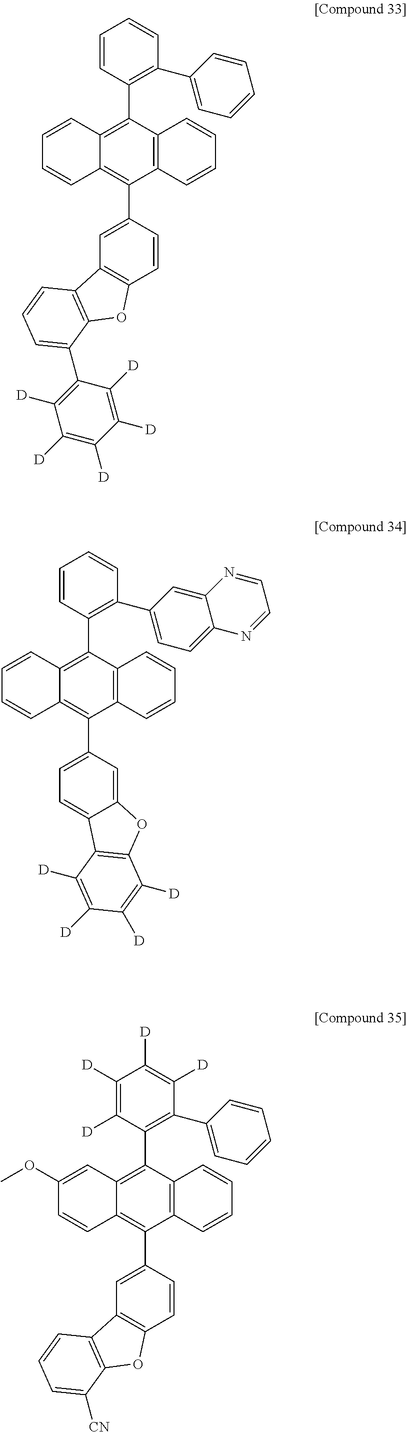 [SMILES: [2H]c1c([2H])c([2H])c(-c2cccc3c2oc2ccc(-c4c5ccccc5c(-c5ccccc5-c5ccccc5)c5ccccc45)cc23)c([2H])c1[2H] ; [2H]c1c([2H])c([2H])c2c(oc3cc(-c4c5ccccc5c(-c5ccccc5-c5ccc6nccnc6c5)c5ccccc45)ccc32)c1[2H] ; [2H]c1c([2H])c([2H])c(-c2c3ccccc3c(-c3ccc4oc5c(C#N)cccc5c4c3)c3ccc(OC)cc23)c(-c2ccccc2)c1[2H]]

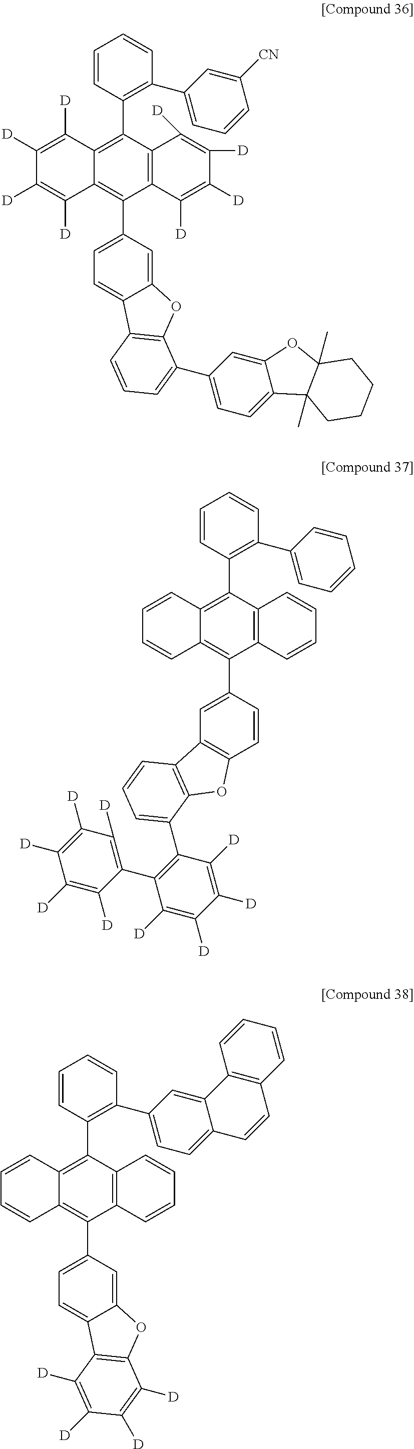 [SMILES: [2H]c1c([2H])c([2H])c2c(-c3ccccc3-c3cccc(C#N)c3)c3c([2H])c([2H])c([2H])c([2H])c3c(-c3ccc4c(c3)oc3c(-c5ccc6c(c5)OC5(C)CCCCC65C)cccc34)c2c1[2H] ; [2H]c1c([2H])c([2H])c(-c2c([2H])c([2H])c([2H])c([2H])c2-c2cccc3c2oc2ccc(-c4c5ccccc5c(-c5ccccc5-c5ccccc5)c5ccccc45)cc23)c([2H])c1[2H] ; [2H]c1c([2H])c([2H])c2c(oc3cc(-c4c5ccccc5c(-c5ccccc5-c5ccc6ccc7ccccc7c6c5)c5ccccc45)ccc32)c1[2H]]

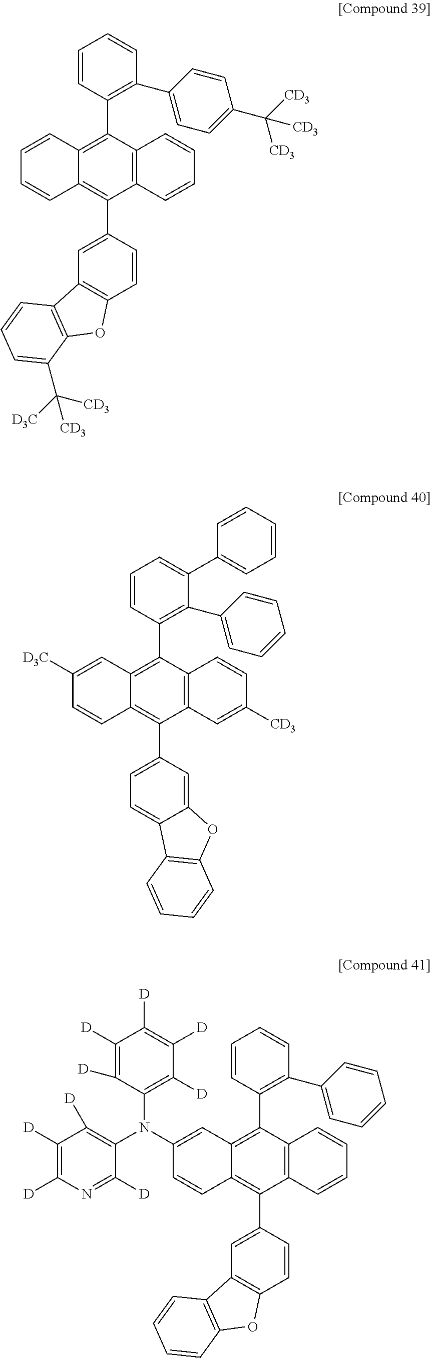 [SMILES: [2H]C([2H])([2H])C(c1ccc(-c2ccccc2-c2c3ccccc3c(-c3ccc4oc5c(C(C([2H])([2H])[2H])(C([2H])([2H])[2H])C([2H])([2H])[2H])cccc5c4c3)c3ccccc23)cc1)(C([2H])([2H])[2H])C([2H])([2H])[2H] ; [2H]C([2H])([2H])c1ccc2c(-c3cccc(-c4ccccc4)c3-c3ccccc3)c3cc(C([2H])([2H])[2H])ccc3c(-c3ccc4c(c3)oc3ccccc34)c2c1 ; [2H]c1nc([2H])c(N(c2ccc3c(-c4ccc5oc6ccccc6c5c4)c4ccccc4c(-c4ccccc4-c4ccccc4)c3c2)c2c([2H])c([2H])c([2H])c([2H])c2[2H])c([2H])c1[2H]]

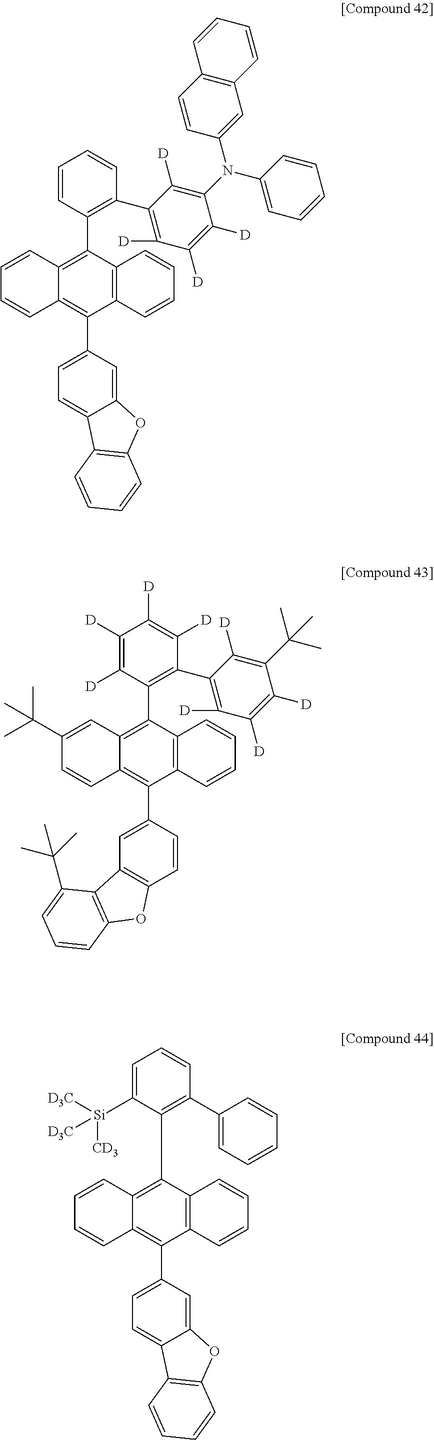 [SMILES: [2H]c1c([2H])c(-c2ccccc2-c2c3ccccc3c(-c3ccc4c(c3)oc3ccccc34)c3ccccc23)c([2H])c(N(c2ccccc2)c2ccc3ccccc3c2)c1[2H] ; [2H]c1c([2H])c([2H])c(-c2c3ccccc3c(-c3ccc4oc5cccc(C(C)(C)C)c5c4c3)c3ccc(C(C)(C)C)cc23)c(-c2c([2H])c([2H])c([2H])c(C(C)(C)C)c2[2H])c1[2H] ; [2H]C([2H])([2H])[Si](c1cccc(-c2ccccc2)c1-c1c2ccccc2c(-c2ccc3c(c2)oc2ccccc23)c2ccccc12)(C([2H])([2H])[2H])C([2H])([2H])[2H]]

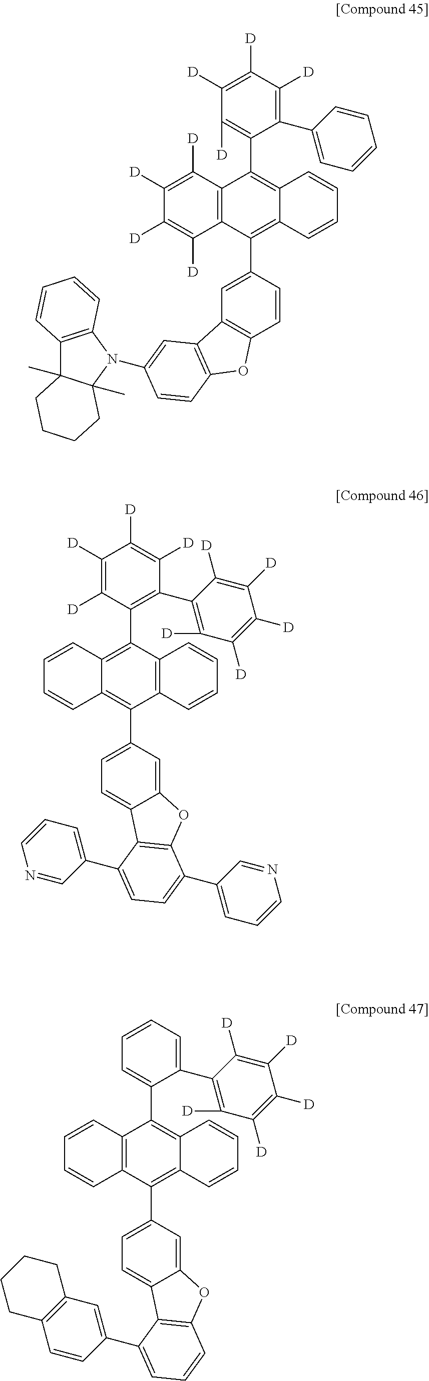 [SMILES: [2H]c1c([2H])c([2H])c(-c2c3ccccc3c(-c3ccc4oc5ccc(N6c7ccccc7C7(C)CCCCC67C)cc5c4c3)c3c([2H])c([2H])c([2H])c([2H])c23)c(-c2ccccc2)c1[2H] ; [2H]c1c([2H])c([2H])c(-c2c([2H])c([2H])c([2H])c([2H])c2-c2c3ccccc3c(-c3ccc4c(c3)oc3c(-c5cccnc5)ccc(-c5cccnc5)c34)c3ccccc23)c([2H])c1[2H] ; [2H]c1c([2H])c([2H])c(-c2ccccc2-c2c3ccccc3c(-c3ccc4c(c3)oc3cccc(-c5ccc6c(c5)CCCC6)c34)c3ccccc23)c([2H])c1[2H]]

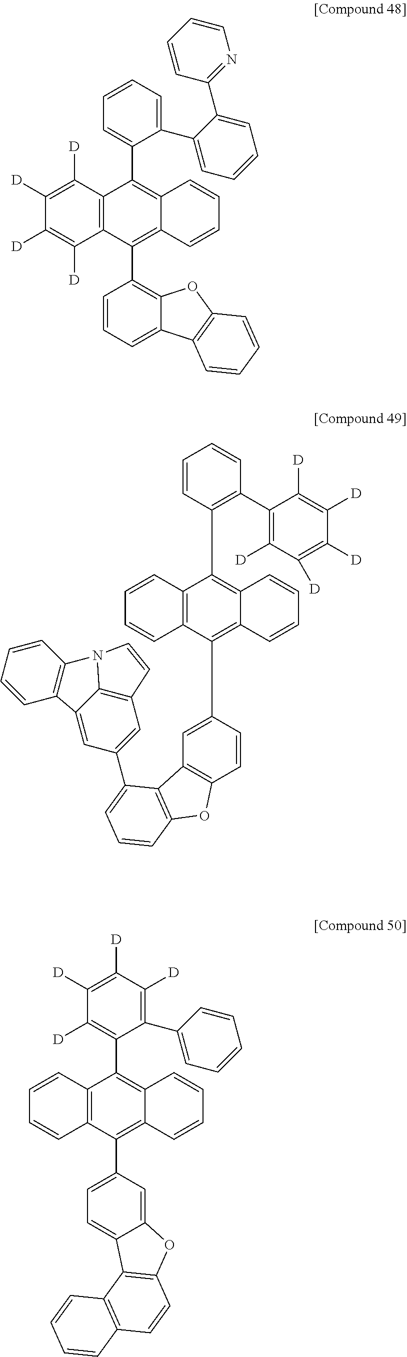 [SMILES: [2H]c1c([2H])c([2H])c2c(-c3cccc4c3oc3ccccc34)c3ccccc3c(-c3ccccc3-c3ccccc3-c3ccccn3)c2c1[2H] ; [2H]c1c([2H])c([2H])c(-c2ccccc2-c2c3ccccc3c(-c3ccc4oc5cccc(-c6cc7ccn8c9ccccc9c(c6)c78)c5c4c3)c3ccccc23)c([2H])c1[2H] ; [2H]c1c([2H])c([2H])c(-c2c3ccccc3c(-c3ccc4c(c3)oc3ccc5ccccc5c34)c3ccccc23)c(-c2ccccc2)c1[2H]]

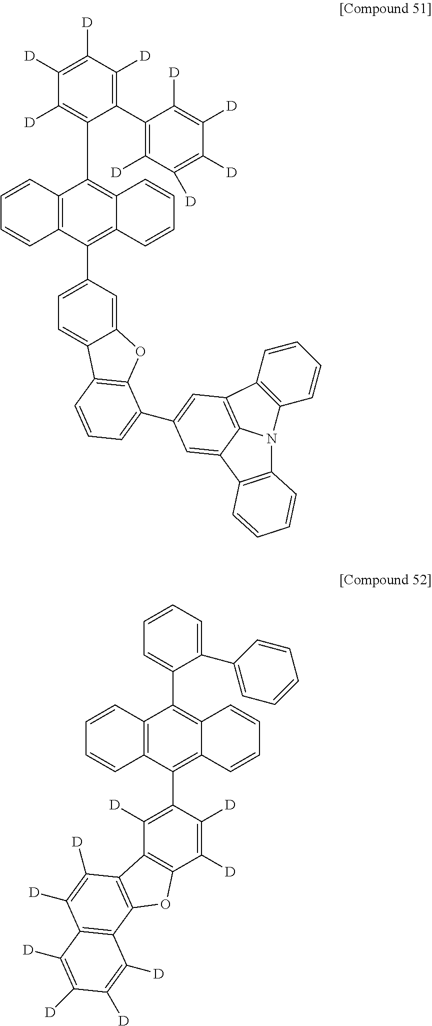 [SMILES: [2H]c1c([2H])c([2H])c(-c2c([2H])c([2H])c([2H])c([2H])c2-c2c3ccccc3c(-c3ccc4c(c3)oc3c(-c5cc6c7ccccc7n7c8ccccc8c(c5)c67)cccc34)c3ccccc23)c([2H])c1[2H] ; [2H]c1c(-c2c3ccccc3c(-c3ccccc3-c3ccccc3)c3ccccc23)c([2H])c2c(oc3c4c([2H])c([2H])c([2H])c([2H])c4c([2H])c([2H])c32)c1[2H]]

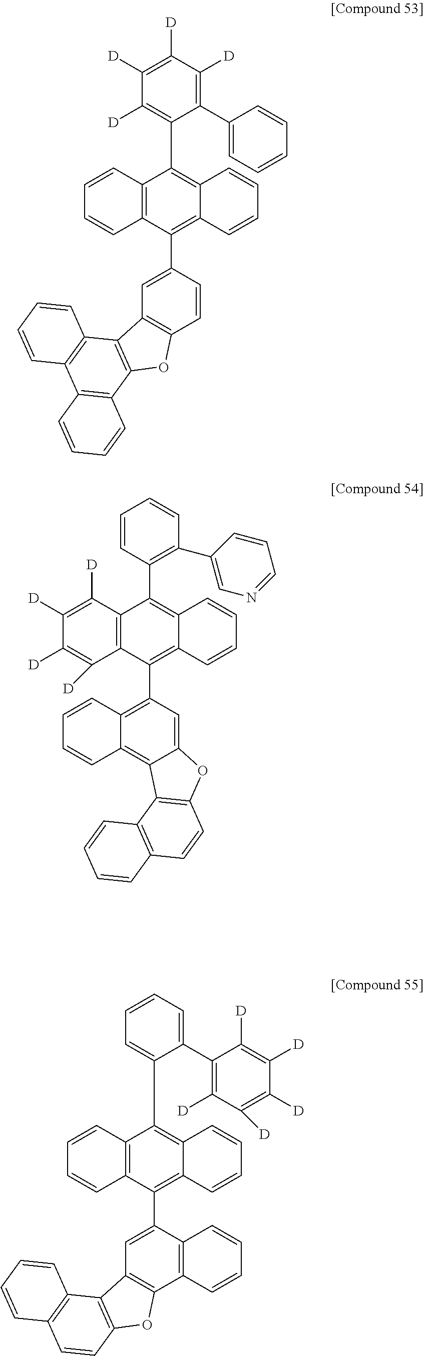 [SMILES: [2H]c1c([2H])c([2H])c(-c2c3ccccc3c(-c3ccc4oc5c6ccccc6c6ccccc6c5c4c3)c3ccccc23)c(-c2ccccc2)c1[2H] ; [2H]c1c([2H])c([2H])c2c(-c3cc4oc5ccc6ccccc6c5c4c4ccccc34)c3ccccc3c(-c3ccccc3-c3cccnc3)c2c1[2H] ; [2H]c1c([2H])c([2H])c(-c2ccccc2-c2c3ccccc3c(-c3cc4c(oc5ccc6ccccc6c54)c4ccccc34)c3ccccc23)c([2H])c1[2H]]

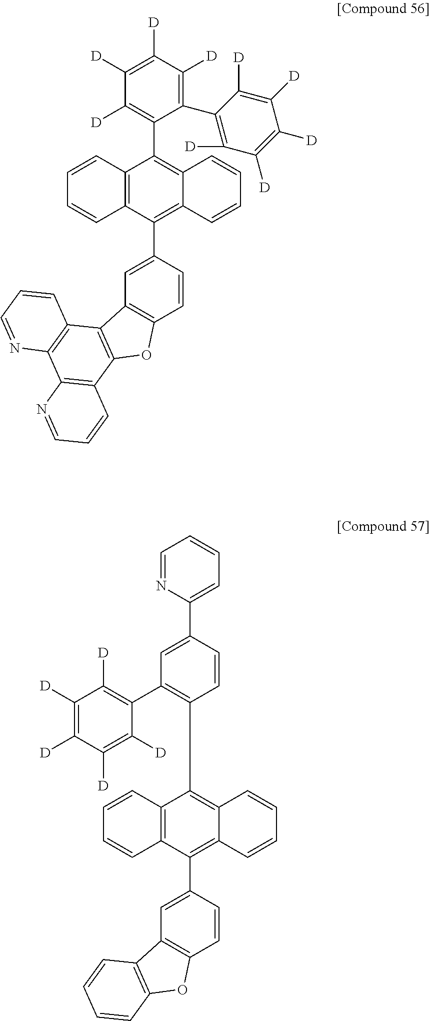 [SMILES: [2H]c1c([2H])c([2H])c(-c2c([2H])c([2H])c([2H])c([2H])c2-c2c3ccccc3c(-c3ccc4oc5c6cccnc6c6ncccc6c5c4c3)c3ccccc23)c([2H])c1[2H] ; [2H]c1c([2H])c([2H])c(-c2cc(-c3ccccn3)ccc2-c2c3ccccc3c(-c3ccc4oc5ccccc5c4c3)c3ccccc23)c([2H])c1[2H]]

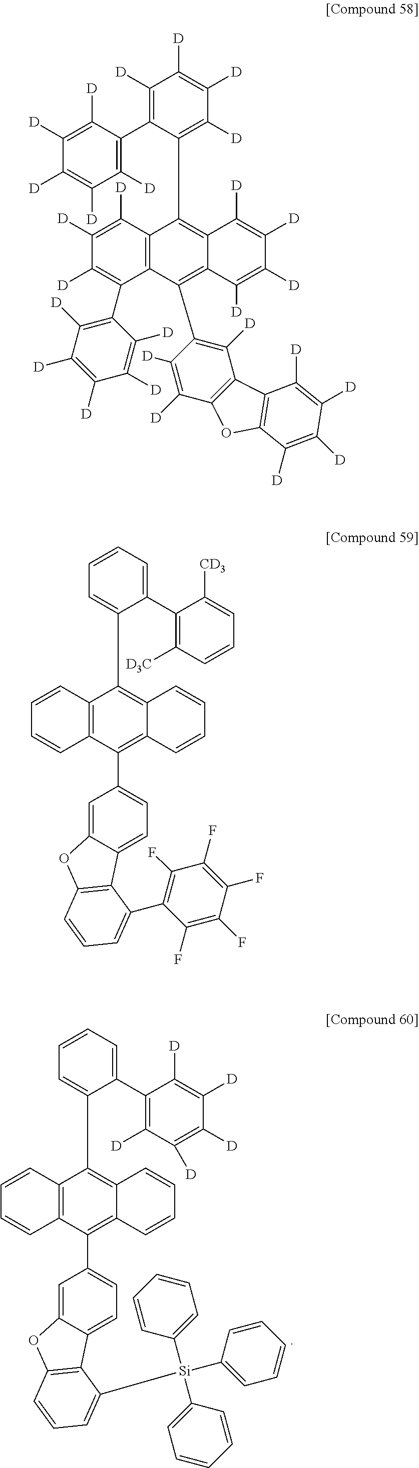 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c([2H])c([2H])c5c4c3[2H])c3c(-c4c([2H])c([2H])c([2H])c([2H])c4[2H])c([2H])c([2H])c([2H])c23)c([2H])c1[2H] ; [2H]C([2H])([2H])c1cccc(C([2H])([2H])[2H])c1-c1ccccc1-c1c2ccccc2c(-c2ccc3c(c2)oc2cccc(-c4c(F)c(F)c(F)c(F)c4F)c23)c2ccccc12 ; [2H]c1c([2H])c([2H])c(-c2ccccc2-c2c3ccccc3c(-c3ccc4c(c3)oc3cccc([Si](c5ccccc5)(c5ccccc5)c5ccccc5)c34)c3ccccc23)c([2H])c1[2H]]

In addition, the boron compound, represented by Chemical Formula B-1 or B-2, which is used as a dopant material in the organic light-emitting diode according to the present disclosure, is characterized by the structure in which:
ring moieties A₂ and A₃ are each independently selected from among a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, and a substituted or unsubstituted aliphatic/aromatic composite ring of 3 to 30 carbon atoms and are bonded directly to a boron atom (B) and indirectly to each other via linker Y₂; the ring moiety A₃ is bonded to linker Y₁; linker Y₁ is bonded to the vinyl group linked to a sulfur atom (S) and the boron atom (B); and the sulfur (S) is bonded to the ring moiety A₁ to form a 5-membered ring bearing the sulfur (S).

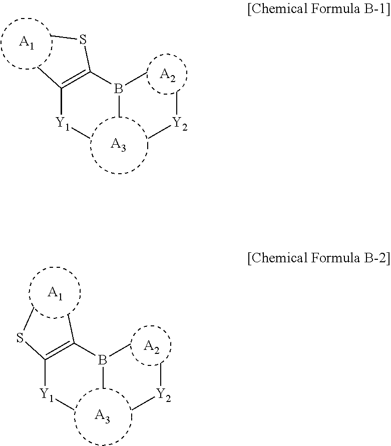

In a particular embodiment, A₁ to A₃ in the compound represented by Chemical Formula B-1 or B-2, which are same or different, may each be independently a substituted or unsubstituted aromatic hydrocarbon ring of 6 to 30 carbon atoms and may each be any one selected from among a benzene ring, a naphthalene ring, an anthracene ring, a phenanthrene ring, an indene ring, a fluorene ring, a pyrene ring, a perylene ring, a chrysene ring, a naphthacene ring, a fluoranthene ring, an acenaphthylene ring, and a pentacene ring.

In this regard, the aromatic hydrocarbon rings of A₁ and A₂ in Chemical Formula B-1 may each be any one selected from among [Structural Formula 10] to [Structural Formula 21], below, and the aromatic hydrocarbon rings of A₁ and A₂ in Chemical Formula B-2, which are same or different, may each be independently any one selected from among [Structural Formula 10] to [Structural Formula 21]m, below:

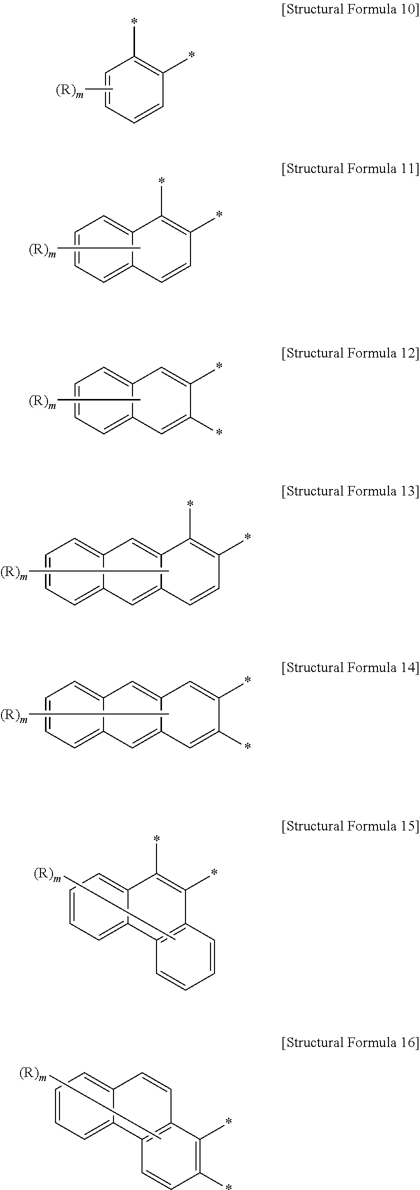

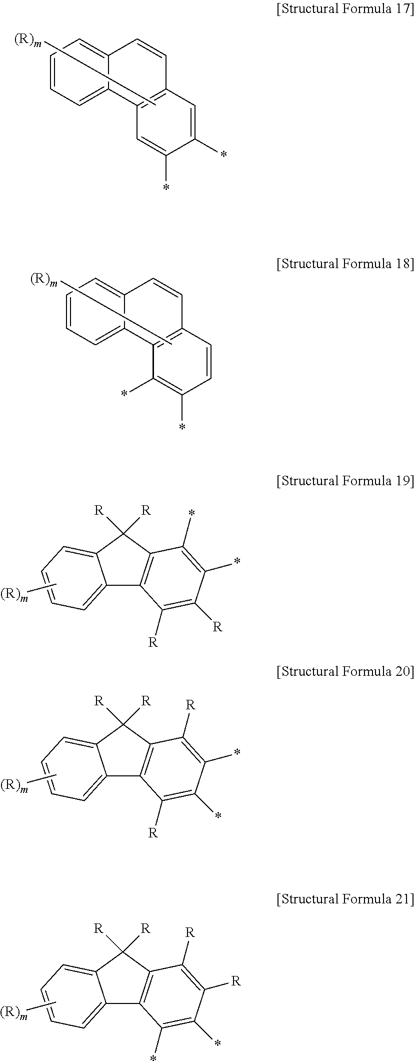

wherein, “-*” denotes: a bonding site at which the carbon ring member of A₁ is bonded to the sulfur atom or a carbon member of the 5-membered ring bearing the sulfur atom; or
a bonding site at which the carbon ring member of A₂ is bonded to the boron atom (B) or linker Y₂
R's, which are same or different, may each be independently any one selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arythioxy of 5 to 30 carbon atoms, a substituted or unsubstituted amine of 0 to 30 carbon atoms, a substituted or unsubstituted silyl of 0 to 30 carbon atoms, a cyano, and a halogen; and
m is an integer of 1 to 8 wherein when m is 2 or greater or when two or more R's exist, the individual R's may be the same or different.

In addition, when the A₁ to A₃ ring moieties, which are same or different, may each be independently a substituted or unsubstituted aromatic hydrocarbon ring of 6 to 50 carbon atoms, the aromatic hydrocarbon ring of A₃ in Chemical Formulas B-1 and B-2 may be a ring represented by the following Structural Formula B:

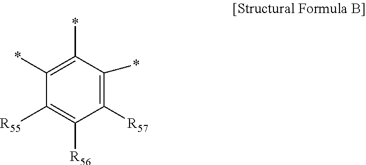

wherein “-*” denotes bonding sites at which the corresponding carbons in the aromatic ring of A₃ bond to linker Y₁, the boron atom (B), and linker Y₂; and
R₅₅ to R₅₇, which are same or different, may each be independently any one selected from among a hydrogen atom, a deuterium atom, substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arylthioxy of 5 to 30 carbon atoms, a substituted or unsubstituted amine of 0 to 30 carbon atoms, a substituted or unsubstituted silyl of 0 to 30 carbon atoms, a cyano, and a halogen, and
any adjacent two of R₅₅ to R₅₇ may be linked to each other to form an additional mono- or polycyclic aliphatic or aromatic ring.

In a particular embodiment, at least one of Y₁ and Y₂ in the compounds represented by Chemical Formulas B-1 and B-2 may be NR₂₁ and preferably, Y₁ and Y₂ in the compounds represented by Chemical Formulas B-1 and B-2 are same or different and may each be independently NR₂₁ wherein R₂₁ is as defined above.

In addition, when the linker Y₁ and Y₂ in Chemical Formulas B-1 and B-2 are each N—R₂₁, R₂₁ may be preferably a substituted or unsubstituted aryl of 6 to 50 carbon atoms or a substituted or unsubstituted heteroaryl of 2 to 50 carbon atoms, and more preferably a substituted or unsubstituted an aryl of 6 to 30 carbon atoms.

In an embodiment, at least one of the linkers Y₁ and Y₂ in Chemical Formulas B-1 and B-2, which are same or different, may be represented by the following Structural Formula A:

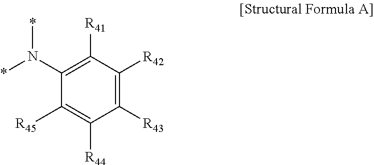

wherein,
“-*” indicates bonding sites which are linked to a carbon atom in the vinyl group of the 5-membered ring bearing the sulfur atom(S), and to an aromatic carbon atom in the A₂ or A₃ ring moiety, respectively,
R₄₁ to R₄₅, which are same or different, may each be independently any one selected from among a hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arylthioxy of 5 to 30 carbon atoms, a substituted or unsubstituted amine of 0 to 30 carbon atoms, a substituted or unsubstituted silyl of 0 to 30 carbon atoms, a nitro, a cyano, and a halogen, R₄₁ and R₄₅ bonding to A₂ or A₃ rings to form an additional mono- or polycyclic aliphatic or aromatic ring.

In Chemical Formulas B-1 and B-2 of the present disclosure, the aromatic hydrocarbon ring of 6 to 50 carbon atoms or the heteroaromatic ring of 2 to 50 carbon atoms of at least one of the ring moieties A₁ to A₃ may be bonded to an aryl amino radical represented by the following Structural Formula F:

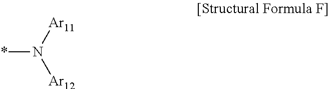

wherein,
“-*” denotes a bonding site participating in forming a bond to a carbon aromatic ring member of any one of A₁ to A₃, and
Ar₁₁ and Ar₁₂, which are same or different, may each be independently a substituted or unsubstituted aryl of 6 to 12 carbon atoms or a substituted or unsubstituted heteroaryl of 3 to 18 carbon atoms, and may be linked to each other to form a ring.

In an embodiment, the boron compound represented by Chemical Formulas B-1 and B-2 may be any one selected from the following [Chemical Formula 1] to [Chemical Formula 84]:

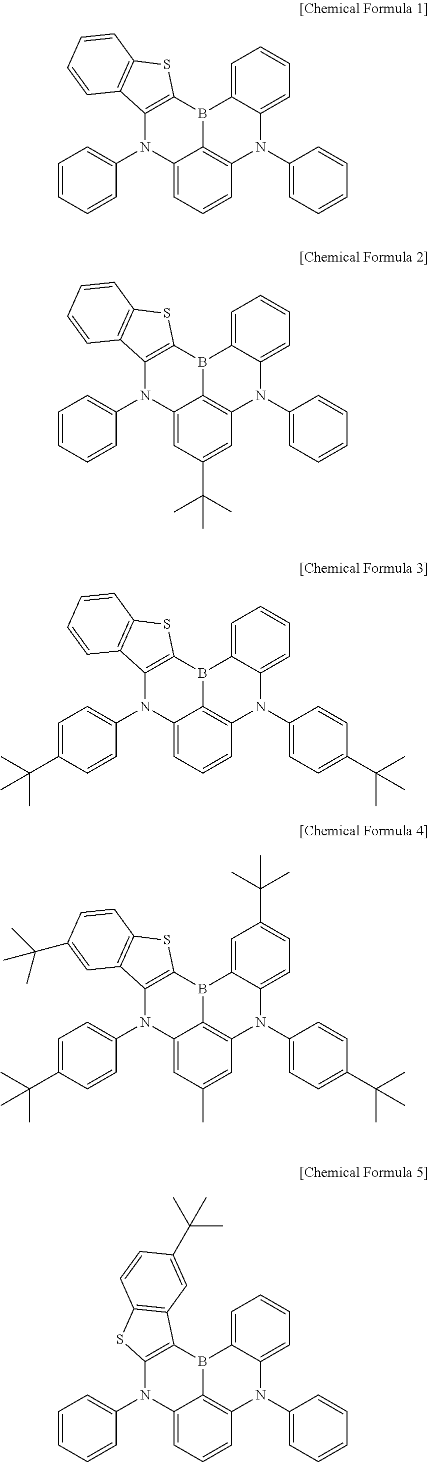

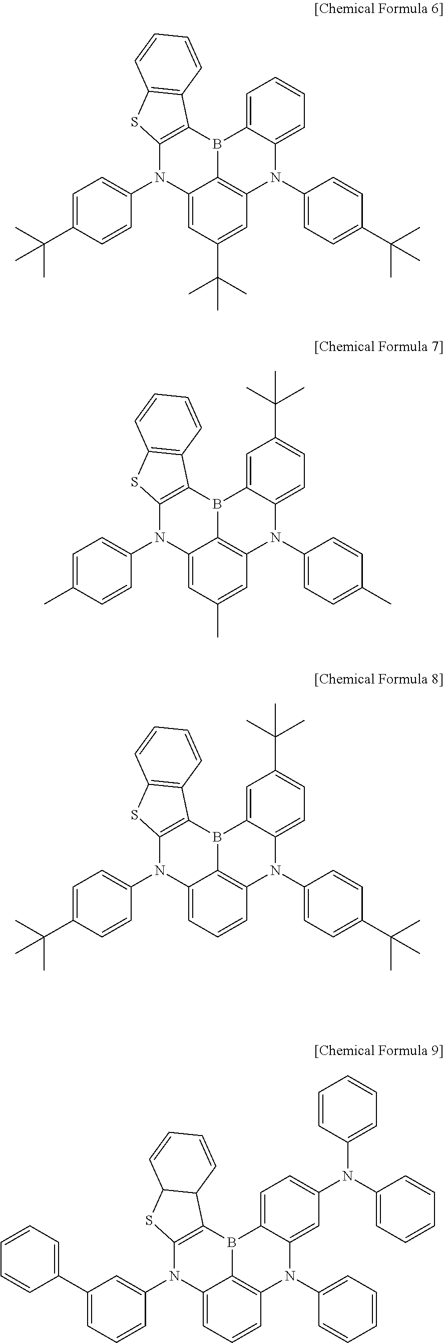

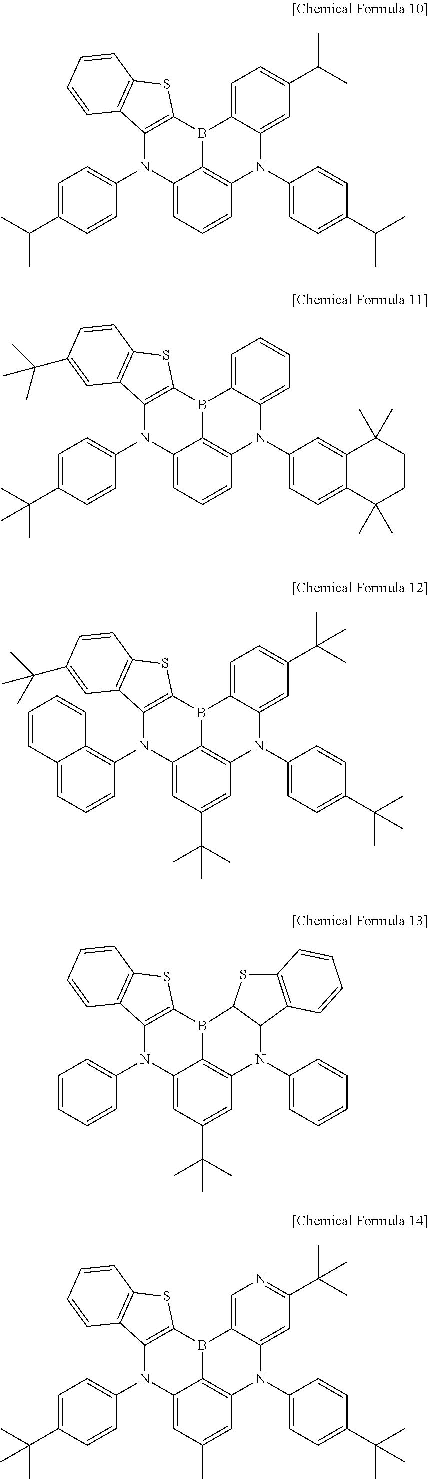

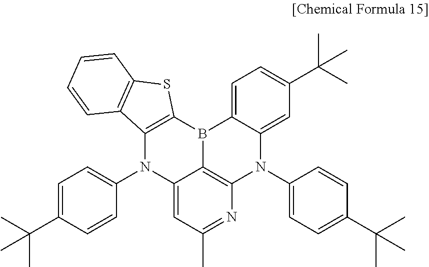 [SMILES: Cc1cc2c3c(n1)N(c1ccc(C(C)(C)C)cc1)c1cc(C(C)(C)C)ccc1B3c1sc3ccccc3c1N2c1ccc(C(C)(C)C)cc1]

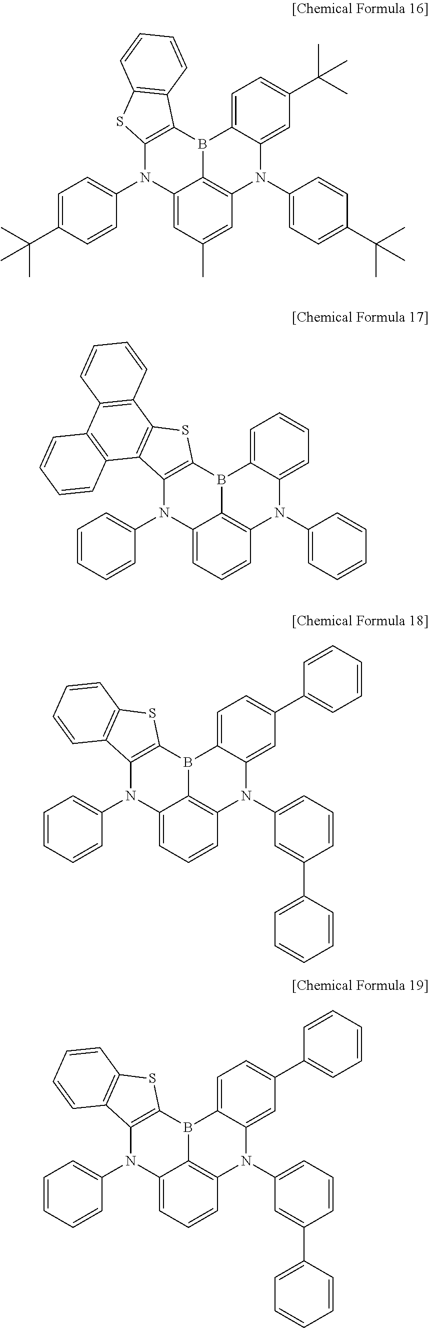 [SMILES: Cc1cc2c3c(c1)N(c1ccc(C(C)(C)C)cc1)c1sc4ccccc4c1B3c1ccc(C(C)(C)C)cc1N2c1ccc(C(C)(C)C)cc1 ; c1ccc(N2c3ccccc3B3c4sc5c6ccccc6c6ccccc6c5c4N(c4ccccc4)c4cccc2c43)cc1 ; c1ccc(-c2cccc(N3c4cc(-c5ccccc5)ccc4B4c5sc6ccccc6c5N(c5ccccc5)c5cccc3c54)c2)cc1 ; c1ccc(-c2cccc(N3c4cc(-c5ccccc5)ccc4B4c5sc6ccccc6c5N(c5ccccc5)c5cccc3c54)c2)cc1]

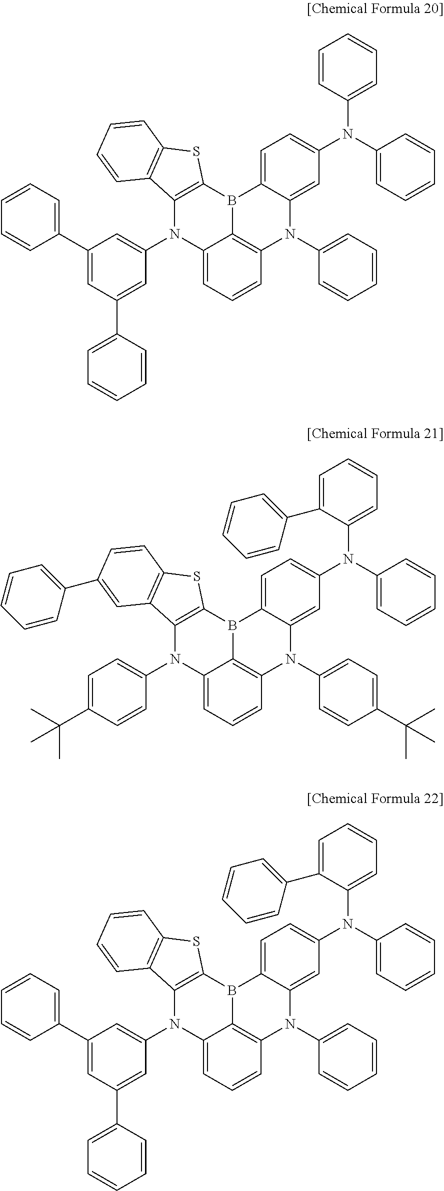 [SMILES: c1ccc(-c2cc(-c3ccccc3)cc(N3c4cccc5c4B(c4ccc(N(c6ccccc6)c6ccccc6)cc4N5c4ccccc4)c4sc5ccccc5c43)c2)cc1 ; CC(C)(C)c1ccc(N2c3cc(N(c4ccccc4)c4ccccc4-c4ccccc4)ccc3B3c4sc5ccc(-c6ccccc6)cc5c4N(c4ccc(C(C)(C)C)cc4)c4cccc2c43)cc1 ; c1ccc(-c2cc(-c3ccccc3)cc(N3c4cccc5c4B(c4ccc(N(c6ccccc6)c6ccccc6-c6ccccc6)cc4N5c4ccccc4)c4sc5ccccc5c43)c2)cc1]

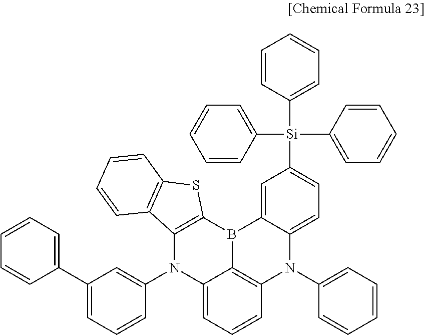 [SMILES: c1ccc(-c2cccc(N3c4cccc5c4B(c4cc([Si](c6ccccc6)(c6ccccc6)c6ccccc6)ccc4N5c4ccccc4)c4sc5ccccc5c43)c2)cc1]

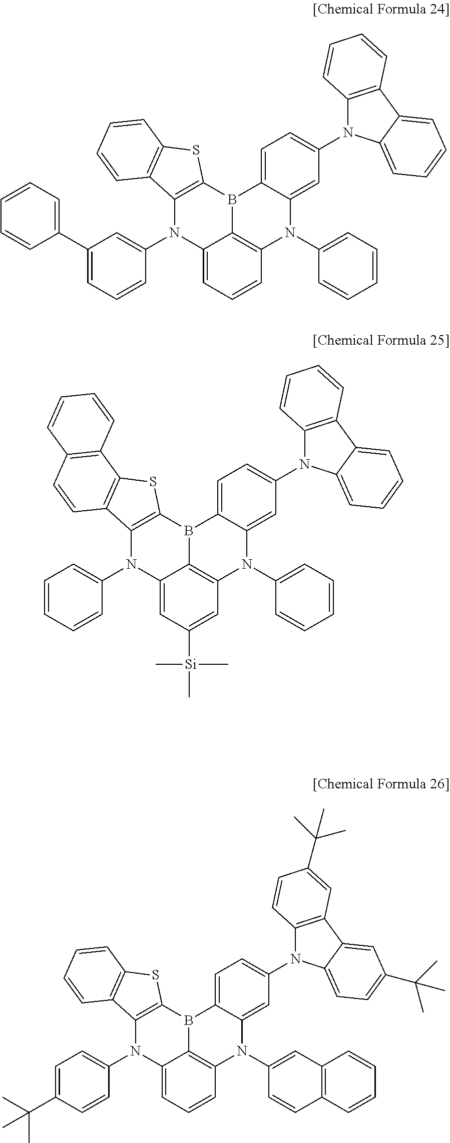 [SMILES: c1ccc(-c2cccc(N3c4cccc5c4B(c4ccc(-n6c7ccccc7c7ccccc76)cc4N5c4ccccc4)c4sc5ccccc5c43)c2)cc1 ; C[Si](C)(C)c1cc2c3c(c1)N(c1ccccc1)c1c(sc4c1ccc1ccccc14)B3c1ccc(-n3c4ccccc4c4ccccc43)cc1N2c1ccccc1 ; CC(C)(C)c1ccc(N2c3cccc4c3B(c3ccc(-n5c6ccc(C(C)(C)C)cc6c6cc(C(C)(C)C)ccc65)cc3N4c3ccc4ccccc4c3)c3sc4ccccc4c32)cc1]

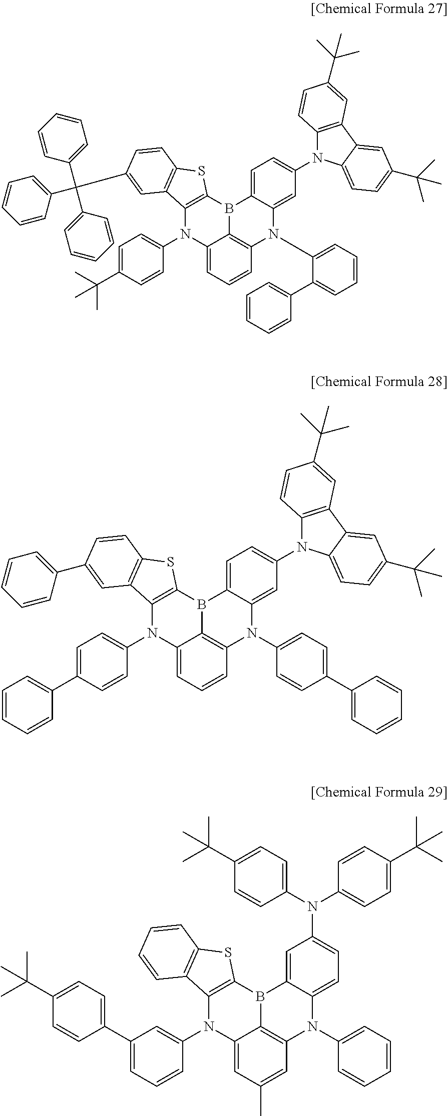

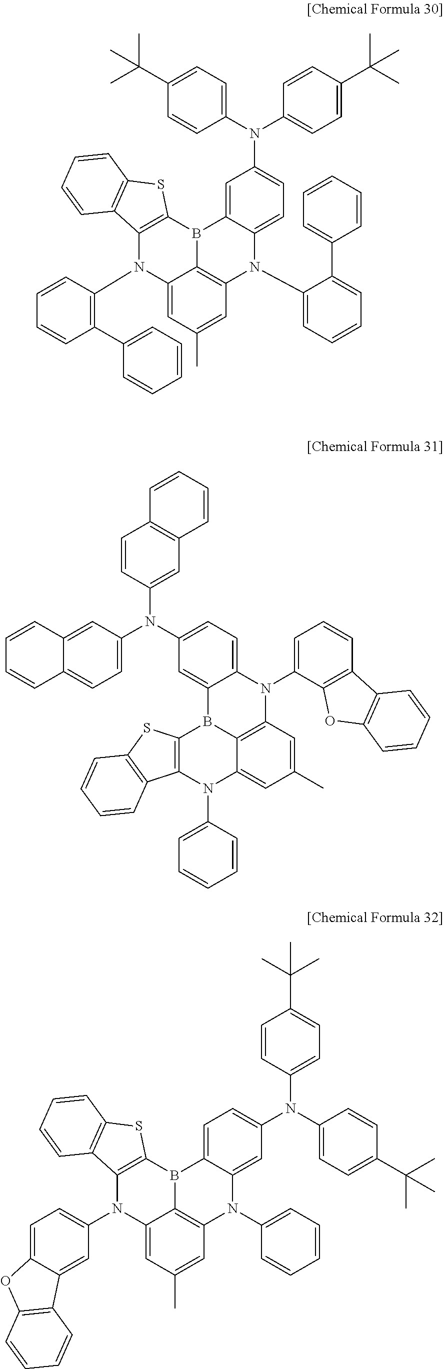 [SMILES: Cc1cc2c3c(c1)N(c1ccccc1-c1ccccc1)c1c(sc4ccccc14)B3c1cc(N(c3ccc(C(C)(C)C)cc3)c3ccc(C(C)(C)C)cc3)ccc1N2c1ccccc1-c1ccccc1 ; Cc1cc2c3c(c1)N(c1cccc4c1oc1ccccc14)c1ccc(N(c4ccc5ccccc5c4)c4ccc5ccccc5c4)cc1B3c1sc3ccccc3c1N2c1ccccc1 ; Cc1cc2c3c(c1)N(c1ccc4oc5ccccc5c4c1)c1c(sc4ccccc14)B3c1ccc(N(c3ccc(C(C)(C)C)cc3)c3ccc(C(C)(C)C)cc3)cc1N2c1ccccc1]

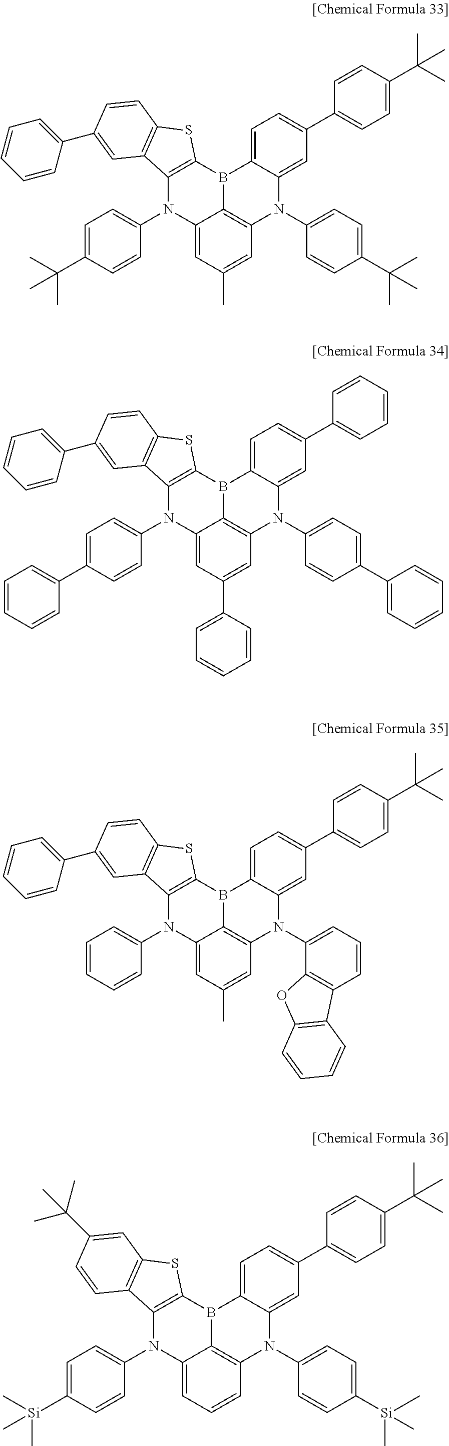

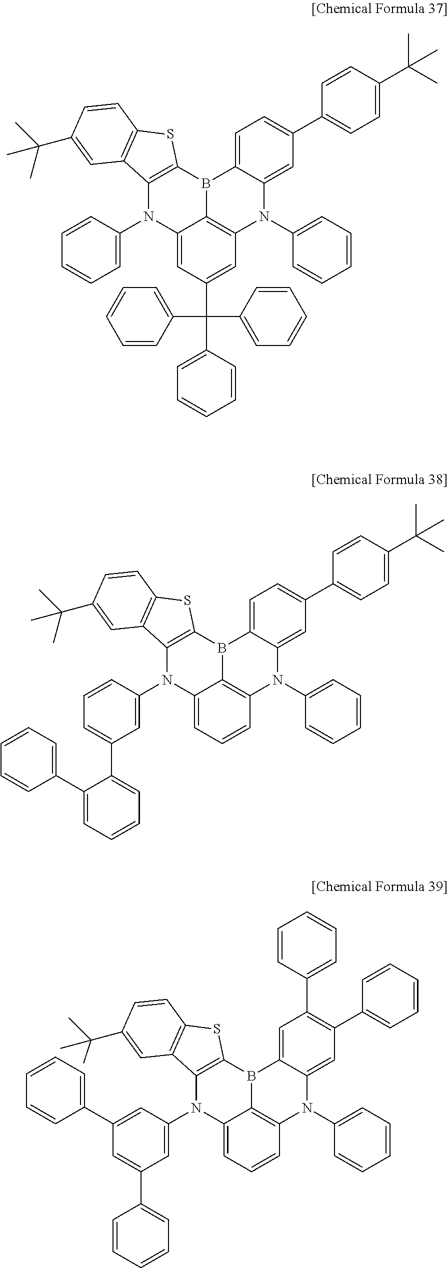 [SMILES: CC(C)(C)c1ccc(-c2ccc3c(c2)N(c2ccccc2)c2cc(C(c4ccccc4)(c4ccccc4)c4ccccc4)cc4c2B3c2sc3ccc(C(C)(C)C)cc3c2N4c2ccccc2)cc1 ; CC(C)(C)c1ccc(-c2ccc3c(c2)N(c2ccccc2)c2cccc4c2B3c2sc3ccc(C(C)(C)C)cc3c2N4c2cccc(-c3ccccc3-c3ccccc3)c2)cc1 ; CC(C)(C)c1ccc2sc3c(c2c1)N(c1cc(-c2ccccc2)cc(-c2ccccc2)c1)c1cccc2c1B3c1cc(-c3ccccc3)c(-c3ccccc3)cc1N2c1ccccc1]

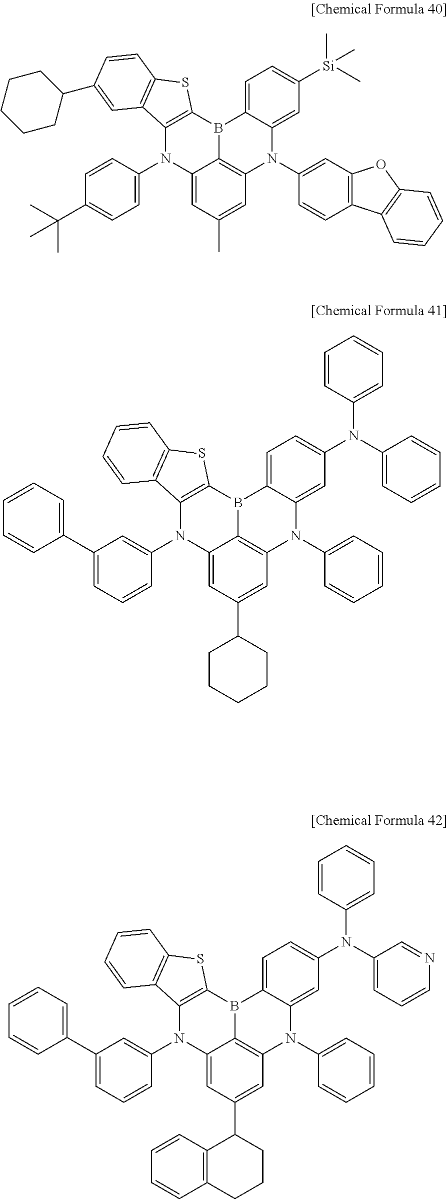 [SMILES: Cc1cc2c3c(c1)N(c1ccc(C(C)(C)C)cc1)c1c(sc4ccc(C5CCCCC5)cc14)B3c1ccc([Si](C)(C)C)cc1N2c1ccc2c(c1)oc1ccccc12 ; c1ccc(-c2cccc(N3c4cc(C5CCCCC5)cc5c4B(c4ccc(N(c6ccccc6)c6ccccc6)cc4N5c4ccccc4)c4sc5ccccc5c43)c2)cc1 ; c1ccc(-c2cccc(N3c4cc(C5CCCc6ccccc65)cc5c4B(c4ccc(N(c6ccccc6)c6cccnc6)cc4N5c4ccccc4)c4sc5ccccc5c43)c2)cc1]

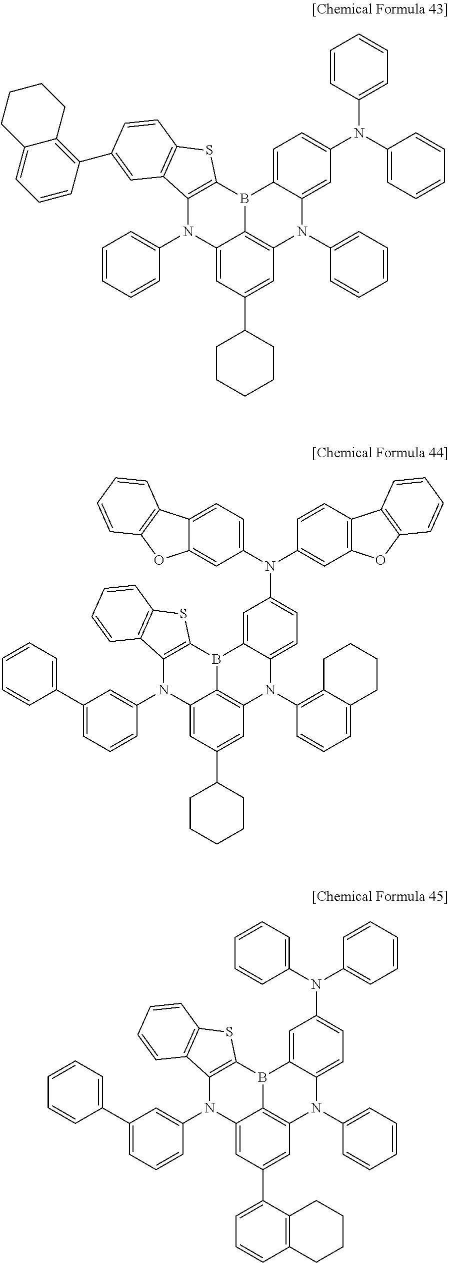 [SMILES: c1ccc(N(c2ccccc2)c2ccc3c(c2)N(c2ccccc2)c2cc(C4CCCCC4)cc4c2B3c2sc3ccc(-c5cccc6c5CCCC6)cc3c2N4c2ccccc2)cc1 ; c1ccc(-c2cccc(N3c4cc(C5CCCCC5)cc5c4B(c4cc(N(c6ccc7c(c6)oc6ccccc67)c6ccc7c(c6)oc6ccccc67)ccc4N5c4cccc5c4CCCC5)c4sc5ccccc5c43)c2)cc1 ; c1ccc(-c2cccc(N3c4cc(-c5cccc6c5CCCC6)cc5c4B(c4cc(N(c6ccccc6)c6ccccc6)ccc4N5c4ccccc4)c4sc5ccccc5c43)c2)cc1]

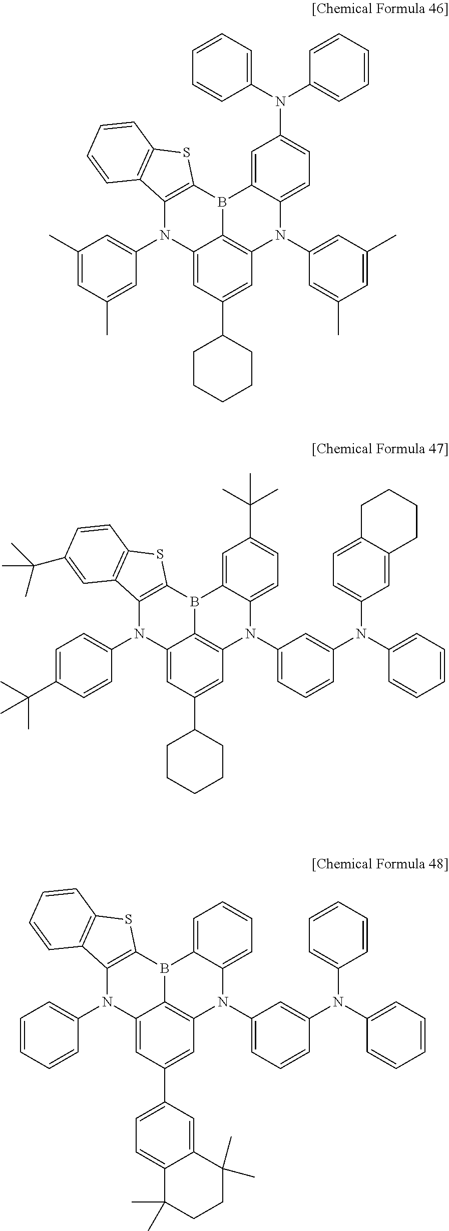

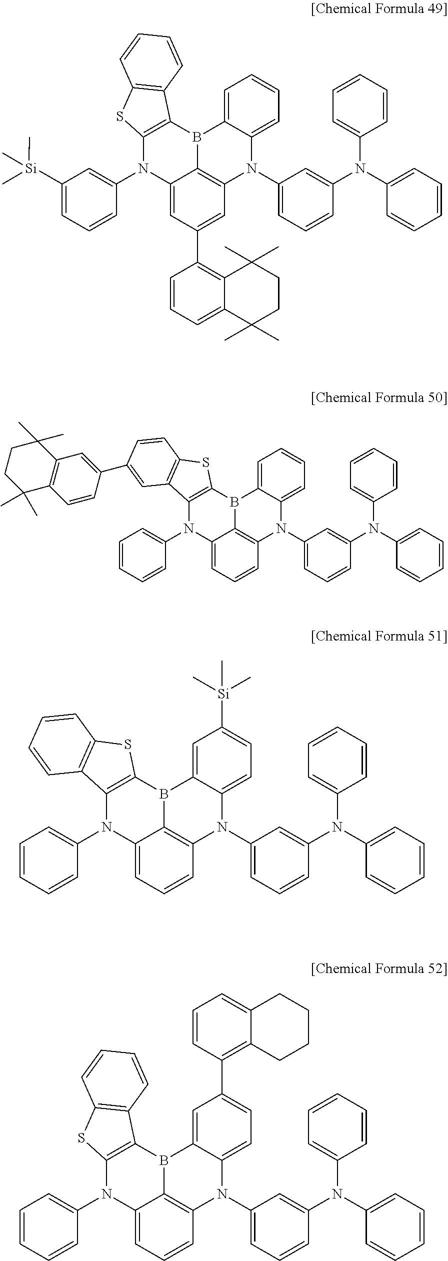 [SMILES: CC1(C)CCC(C)(C)c2c(-c3cc4c5c(c3)N(c3cccc([Si](C)(C)C)c3)c3sc6ccccc6c3B5c3ccccc3N4c3cccc(N(c4ccccc4)c4ccccc4)c3)cccc21 ; CC1(C)CCC(C)(C)c2cc(-c3ccc4sc5c(c4c3)N(c3ccccc3)c3cccc4c3B5c3ccccc3N4c3cccc(N(c4ccccc4)c4ccccc4)c3)ccc21 ; C[Si](C)(C)c1ccc2c(c1)B1c3sc4ccccc4c3N(c3ccccc3)c3cccc(c31)N2c1cccc(N(c2ccccc2)c2ccccc2)c1 ; c1ccc(N(c2ccccc2)c2cccc(N3c4ccc(-c5cccc6c5CCCC6)cc4B4c5c3cccc5N(c3ccccc3)c3sc5ccccc5c34)c2)cc1]

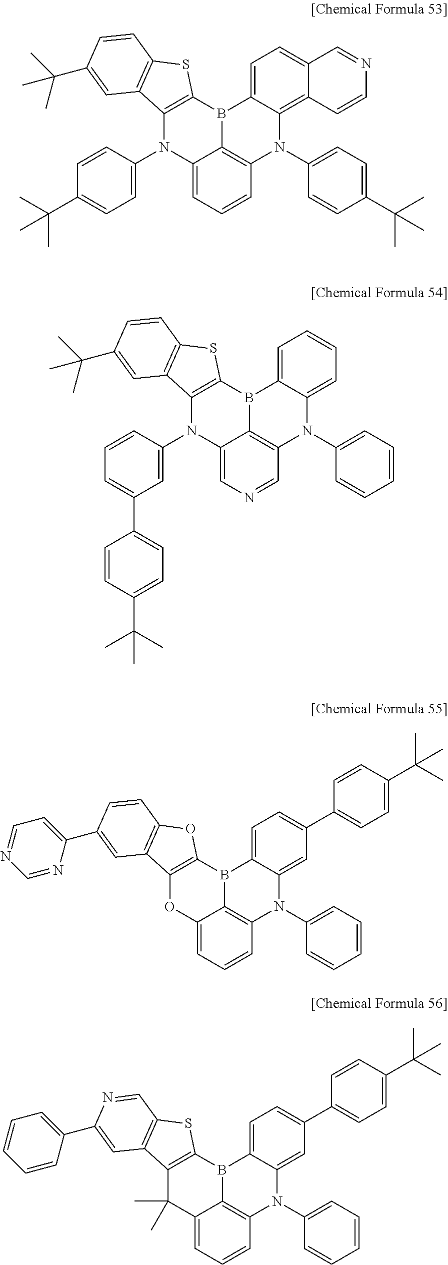

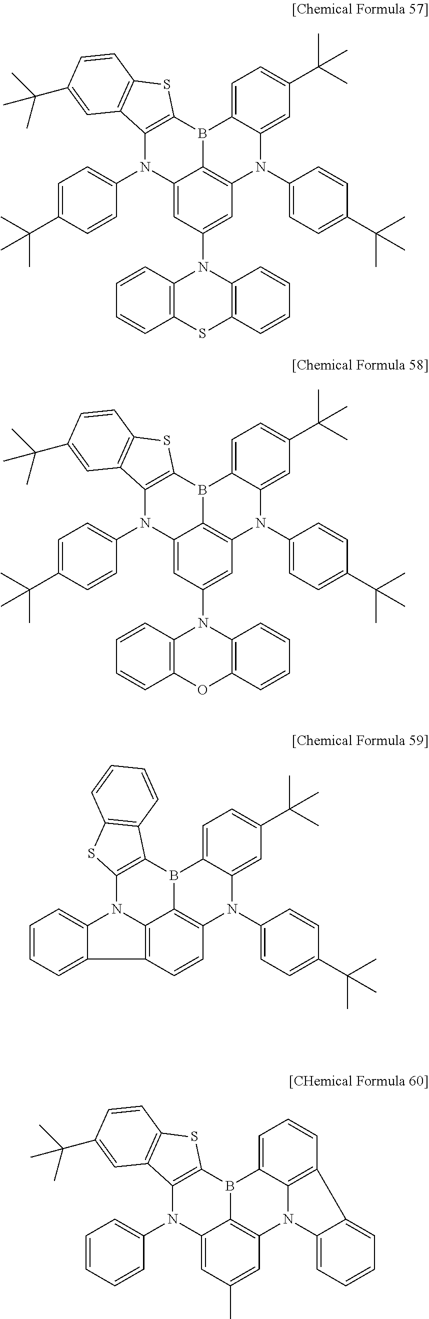

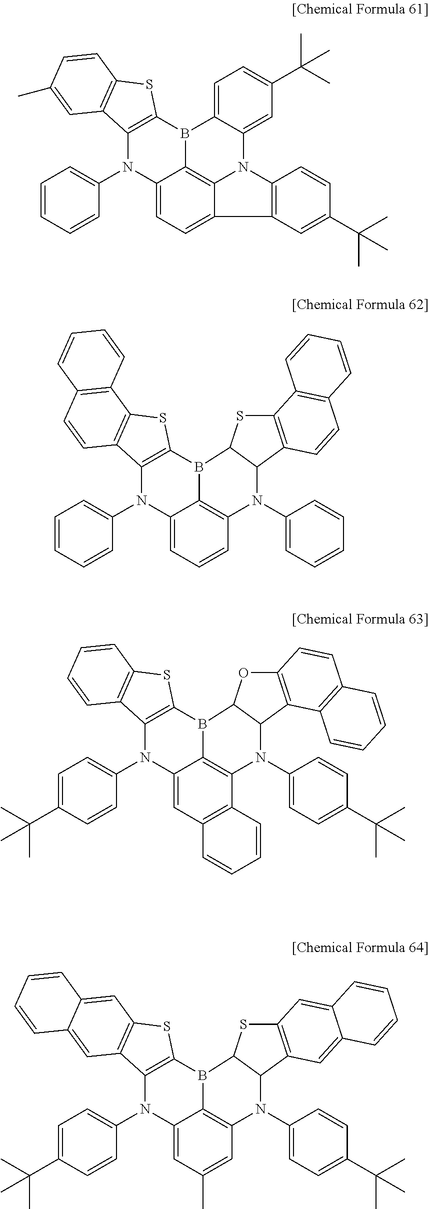

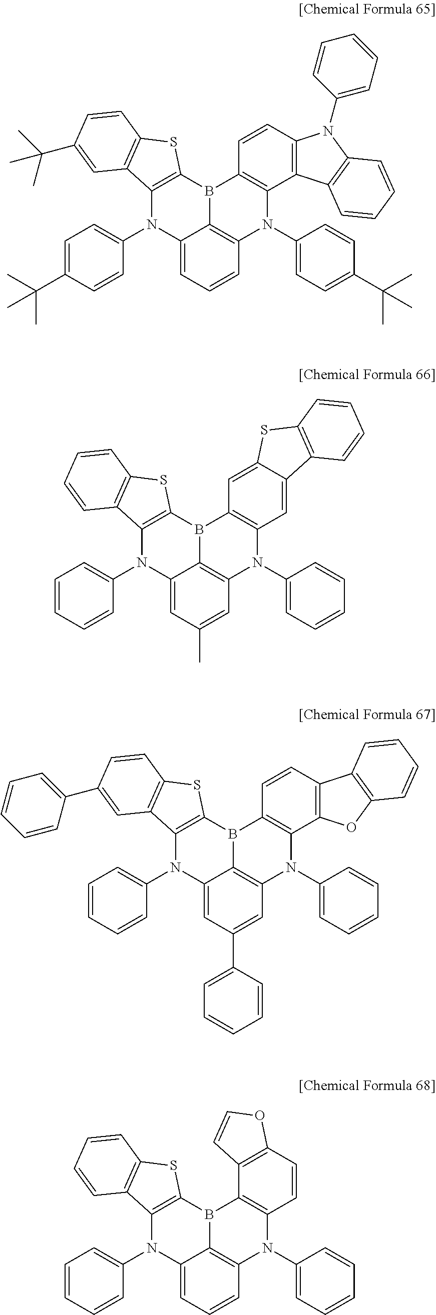 [SMILES: CC(C)(C)c1ccc(N2c3cccc4c3B(c3ccc5c(c3N4c3ccc(C(C)(C)C)cc3)c3ccccc3n5-c3ccccc3)c3sc4ccc(C(C)(C)C)cc4c32)cc1 ; Cc1cc2c3c(c1)N(c1ccccc1)c1c(sc4ccccc14)B3c1cc3sc4ccccc4c3cc1N2c1ccccc1 ; c1ccc(-c2cc3c4c(c2)N(c2ccccc2)c2c(ccc5c2oc2ccccc25)B4c2sc4ccc(-c5ccccc5)cc4c2N3c2ccccc2)cc1 ; c1ccc(N2c3cccc4c3B(c3sc5ccccc5c3N4c3ccccc3)c3c2ccc2occc32)cc1]

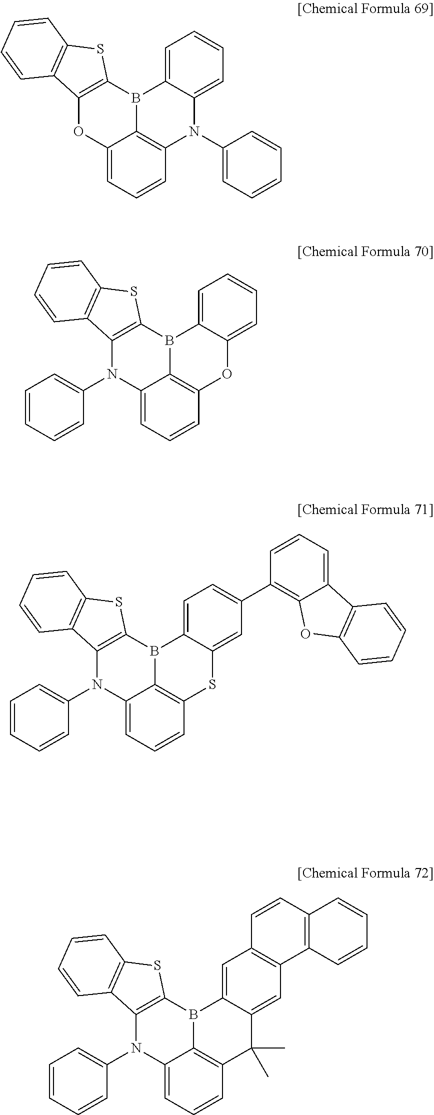 [SMILES: c1ccc(N2c3ccccc3B3c4sc5ccccc5c4Oc4cccc2c43)cc1 ; c1ccc(N2c3cccc4c3B(c3ccccc3O4)c3sc4ccccc4c32)cc1 ; c1ccc(N2c3cccc4c3B(c3ccc(-c5cccc6c5oc5ccccc56)cc3S4)c3sc4ccccc4c32)cc1 ; CC1(C)c2cc3c(ccc4ccccc43)cc2B2c3sc4ccccc4c3N(c3ccccc3)c3cccc1c32]

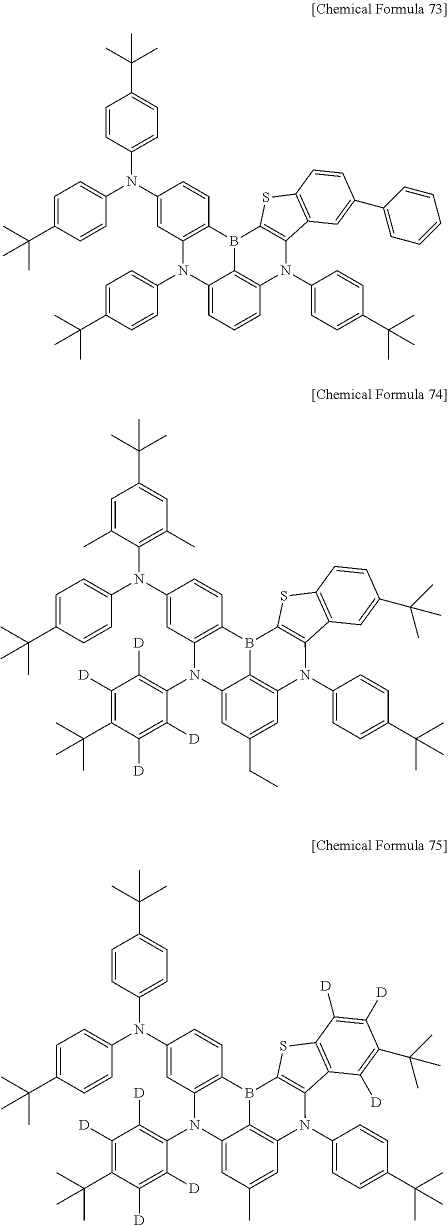

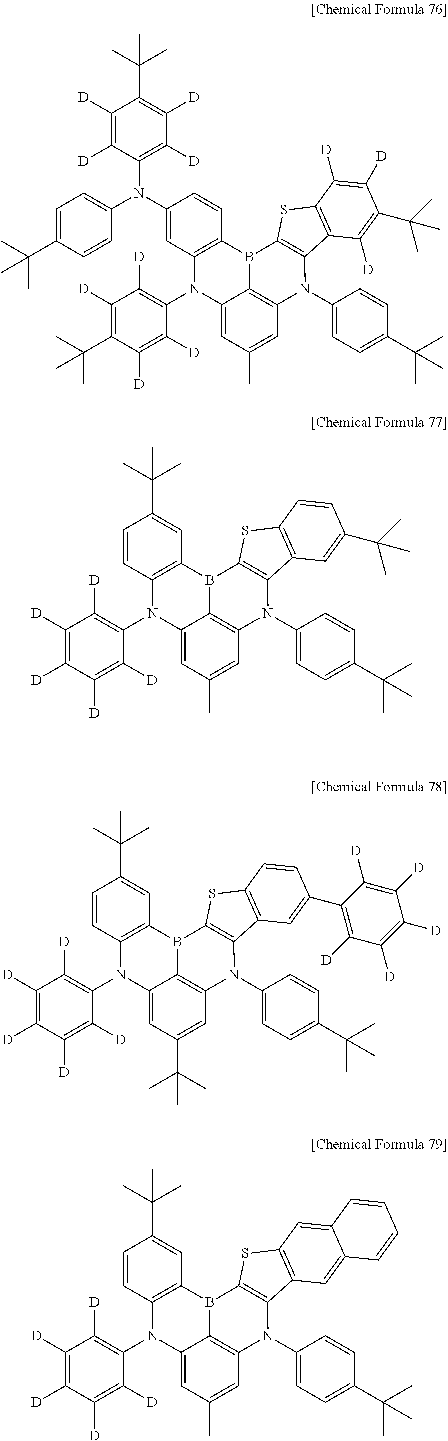

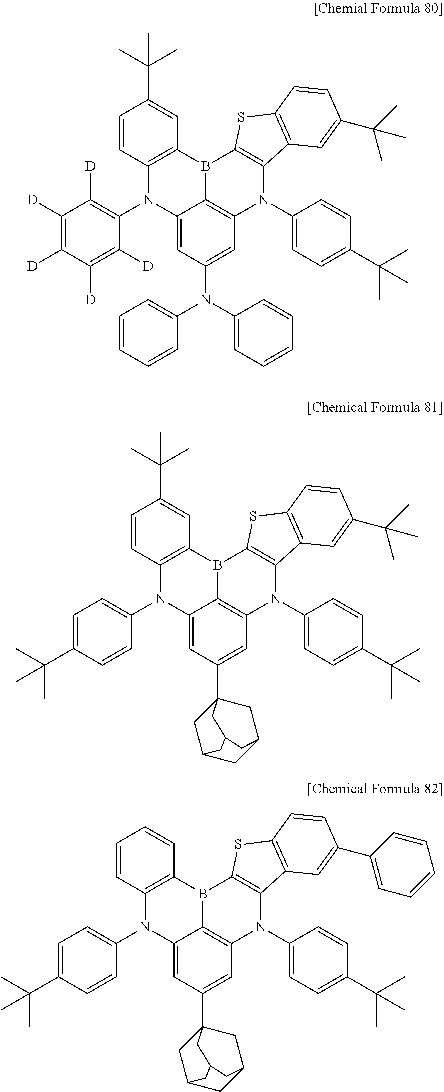

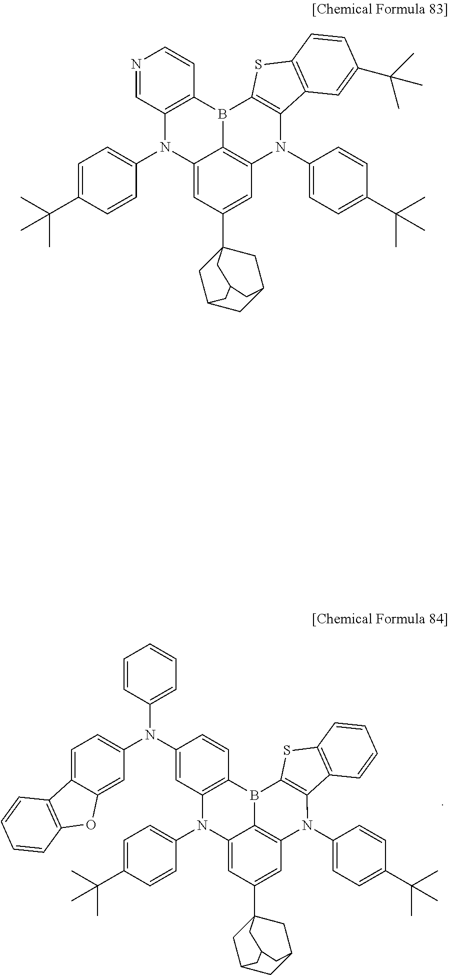 [SMILES: CC(C)(C)c1ccc(N2c3cnccc3B3c4sc5ccc(C(C)(C)C)cc5c4N(c4ccc(C(C)(C)C)cc4)c4cc(C56CC7CC(CC(C7)C5)C6)cc2c43)cc1 ; CC(C)(C)c1ccc(N2c3cc(N(c4ccccc4)c4ccc5c(c4)oc4ccccc45)ccc3B3c4sc5ccccc5c4N(c4ccc(C(C)(C)C)cc4)c4cc(C56CC7CC(CC(C7)C5)C6)cc2c43)cc1]

The organic layer within the organic light-emitting diode according to the present disclosure may include at least one of a hole injection layer, a hole transport layer, a functional layer capable of both hole injection and hole transport, an electron transport layer, and an electron injection layer, in addition to the light emission layer.

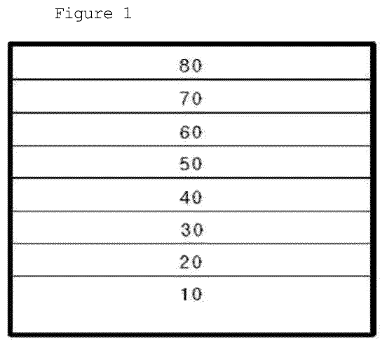

FIG. 1 is a schematic view of the structure of an organic light-emitting diode according to the present disclosure.

As shown in FIG. 1, the organic light-emitting diode according to an embodiment of the present disclosure comprises an anode 20, a hole transport layer 40, a light emission layer 50, an electron transport layer 60, and a cathode 80, and optionally a hole injection layer 30 and an electron injection layer 70. In addition, one or two intermediate layers may be further formed in the organic light-emitting diode.

Here, the anthracene compound represented by Chemical Formula A can be used as a host in the light emitting layer.

Reference is made to FIG. 1 with regard to the organic light-emitting diode of the present disclosure and the fabrication thereof. First, a substrate 10 is coated with an anodic electrode material to form an anode 20. So long as it is used in a typical organic electroluminescence device, any substrate may be used as the substrate 10. Preferable is an organic substrate or transparent plastic substrate that exhibits excellent transparency, surface smoothness, ease of handling, and waterproofness. As the anodic electrode material, indium tin oxide (ITO), indium zinc oxide (IZO), tin oxide (SnO₂), or zinc oxide (ZnO), which are transparent and superior in terms of conductivity, may be used.

A hole injection layer material is applied on the anode 20 by thermal deposition in a vacuum or by spin coating to form a hole injection layer 30. Subsequently, thermal deposition in a vacuum or by spin coating may also be conducted to form a hole transport layer 40 with a hole transport layer material on the hole injection layer 30.

No particular limitations are imparted to the hole injection layer material, as long as it is one that is typically used in the art. For example, mention may be made of 2-TNATA [4,4′,4″-tris(2-naphthylphenyl-phenylamino)-triphenylamine], NPD [N,N′-di(1-naphthyl)-N,N′-diphenylbenzidine)], TPD [N,N′-diphenyl-N,N′-bis(3-methylphenyl)-1,1′-biphenyl-4,4′-diamine], DNTPD [N,N′-diphenyl-N,N′-bis-[4-(phenyl-m-tolyl-amino)-phenyl]-biphenyl-4,4′-diamine], or HAT-CN [dipyrazino[2,3-f: 2′,3′-h]quinoxaline-2,3,6,7,10,11-hexacarbonitrile], but the present disclosure is not limited thereby.

So long as it is typically used in the art, any material may be selected for the hole transport layer without particular limitation. Examples include, but are not limited to, N, N′-bis(3-methylphenyl)-N, N′-diphenyl-[1,1-biphenyl]-4,4′-diamine (TPD), and N, N′-di(naphthalen-1-yl)-N, N′-diphenylbenzidine (a-NPD).

Then, an organic light emission layer 50 containing a host and a dopant is deposited on the hole transport layer 40 by deposition in a vacuum or by spin coating. In some embodiments of the present disclosure, the light emission layer particularly ranges in thickness from 50 to 2,000 Å. Here, an electron density control layer (not shown) may be further formed on the organic light emitting layer 50, as necessary.

The light emission layer may contain a host and a dopant. The materials for the host and dopant are as described above. The content of the dopant may range from about 0.01 to 20 parts by weight, based on 100 parts by weight of the host, but is not limited thereto.

In addition, the anthracene compound represented by Chemical Formula A may be used as a host alone or in mixture with a well-known host in the light emission layer or may be deposited separately from a well-known host in the light emission layer.

In an embodiment, the anthracene compound represented by Chemical Formula A may be used in mixture with at least one different host compound in the light emission layer or may be deposited separately from at least one host compound in the light emission layer.

When the anthracene compound is used in mixture with or separately from a well-known host, the available well-known host may be at least one of the compounds represented by Chemical Formulas B and C, below:

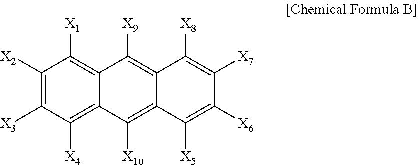

wherein,
X₁ to X₁₀, which are same or different, may each be independently at least one selected from the group consisting of a hydrogen atom, a deuterium atom, a substituted or unsubstituted alkyl of 1 to 30 carbon atoms, a substituted or unsubstituted alkenyl of 2 to 30 carbon atoms, a substituted or unsubstituted cycloalkyl of 3 to 30, a substituted or unsubstituted cycloalkenyl of 5 to 30 carbon atoms, a substituted or unsubstituted alkoxy of 1 to 30 carbon atoms, a substituted or unsubstituted aryloxy of 6 to 30 carbon atoms, a substituted or unsubstituted akylthioxy of 1 to 30 carbon atoms, a substituted or unsubstituted arylthioxy of 5 to 30 carbon atoms, a substituted or unsubstituted amine of 0 to 30 carbon atoms, a substituted or unsubstituted aryl of 5 to 50 carbon atoms, a substituted or unsubstituted heteroaryl of 3 to 50 carbon atoms bearing O, N, or S as a heteroatom, a substituted or unsubstituted silicone, a substituted or unsubstituted boron, a substituted or unsubstituted silyl of 0 to 30 carbon atoms, a carbonyl, a phosphoryl, an amino, a nitrile, a hydroxy, a nitro, a halogen, an amide, and an ester, wherein adjacent radicals may form an aliphatic, an aromatic, an aliphatic hetero, or an aromatic hetero fused ring.

More particularly, concrete examples of the host compound represented by Chemical Formula B include, but are not limited to, compounds of [Chemical Formula 101] to [Chemical Formula 296]:

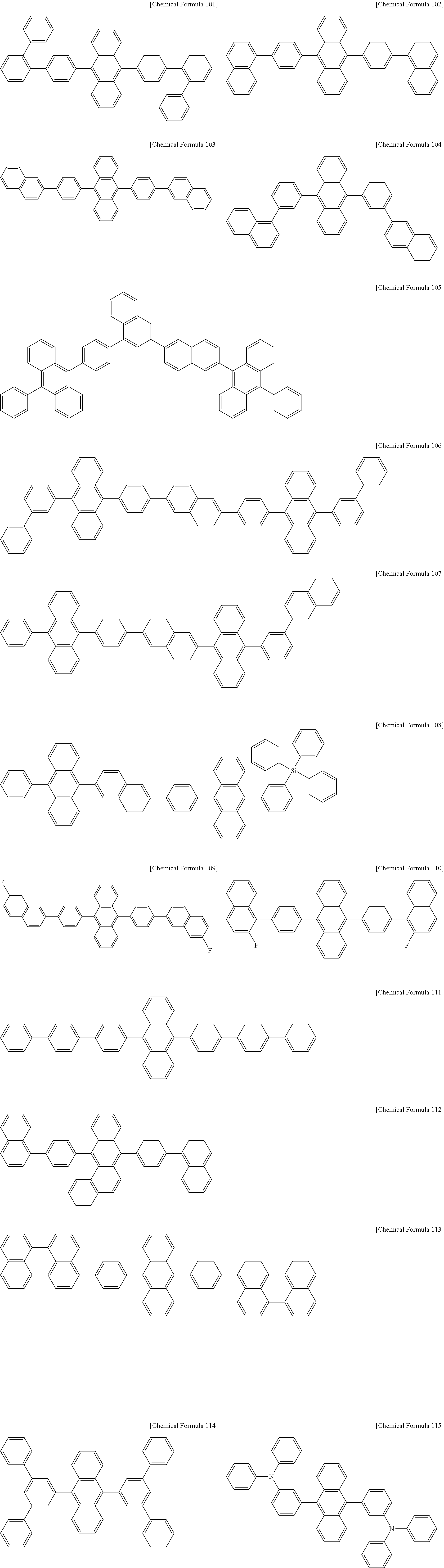

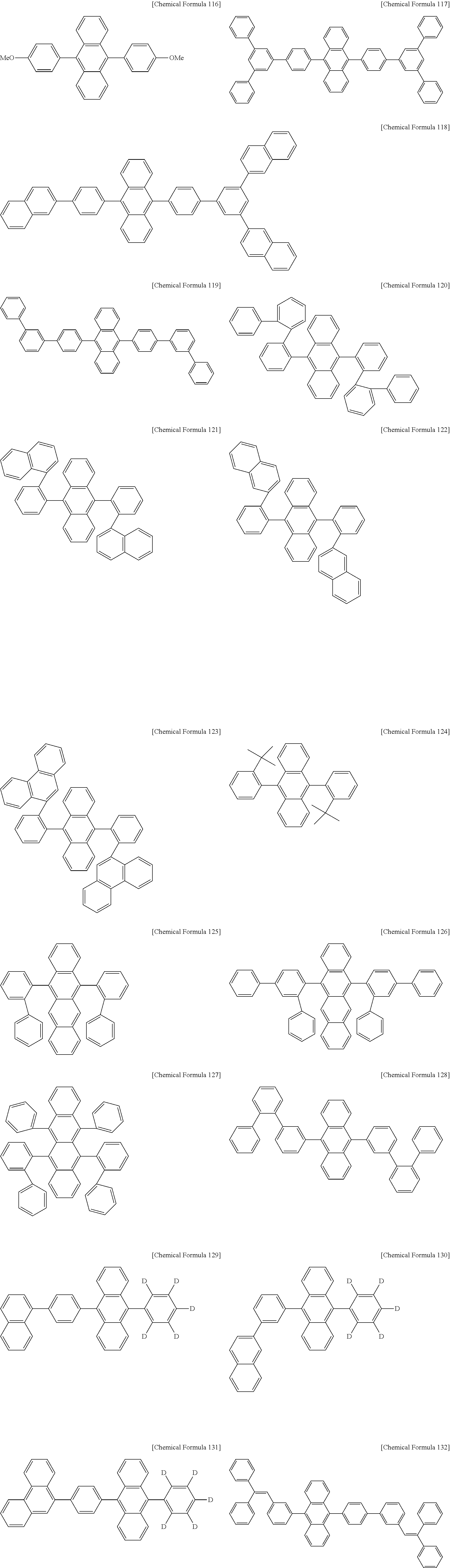

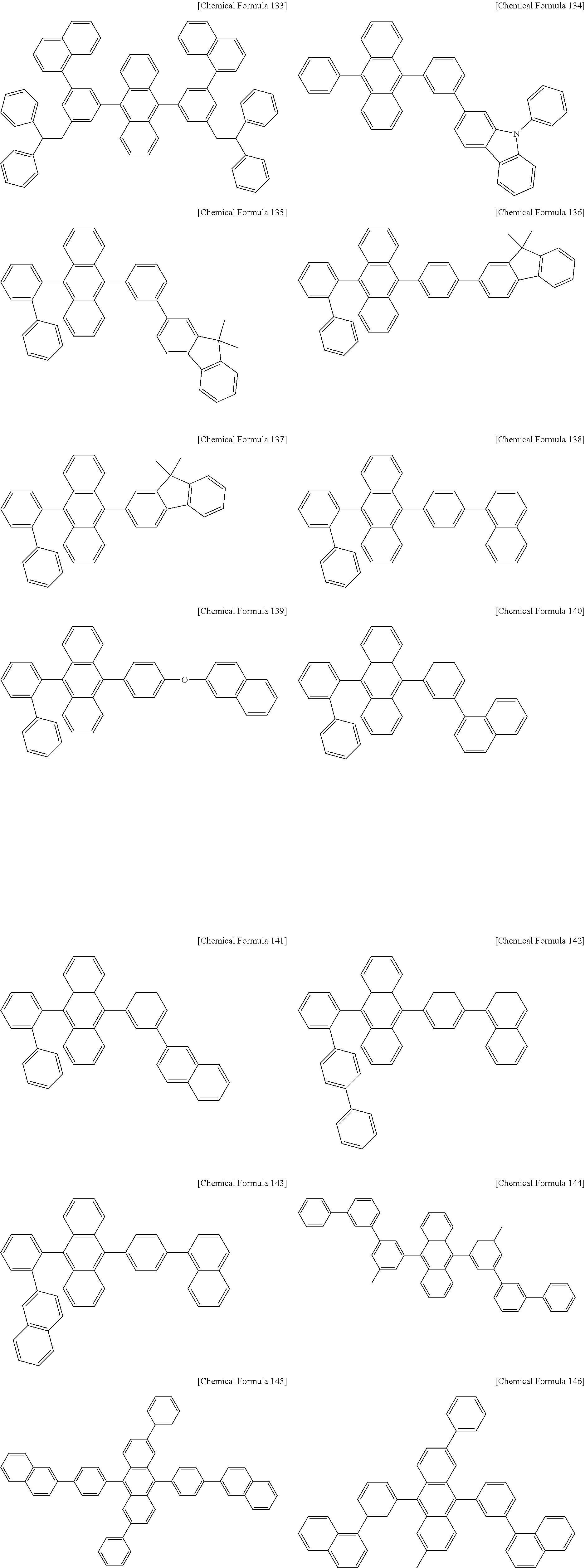

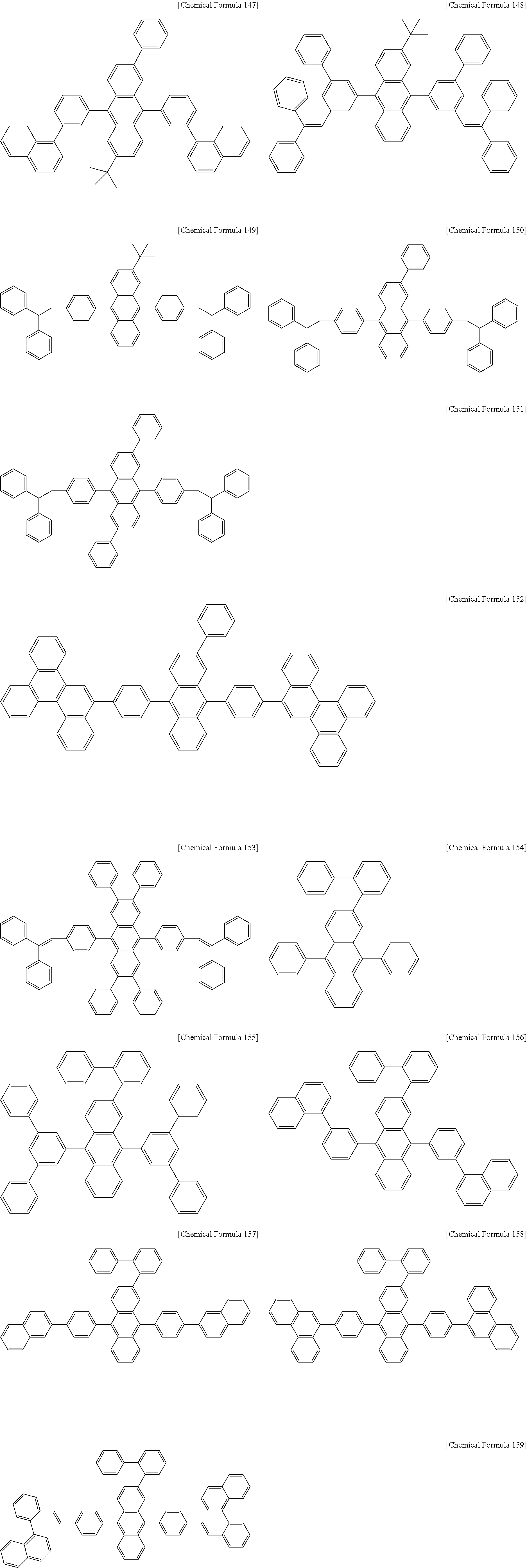

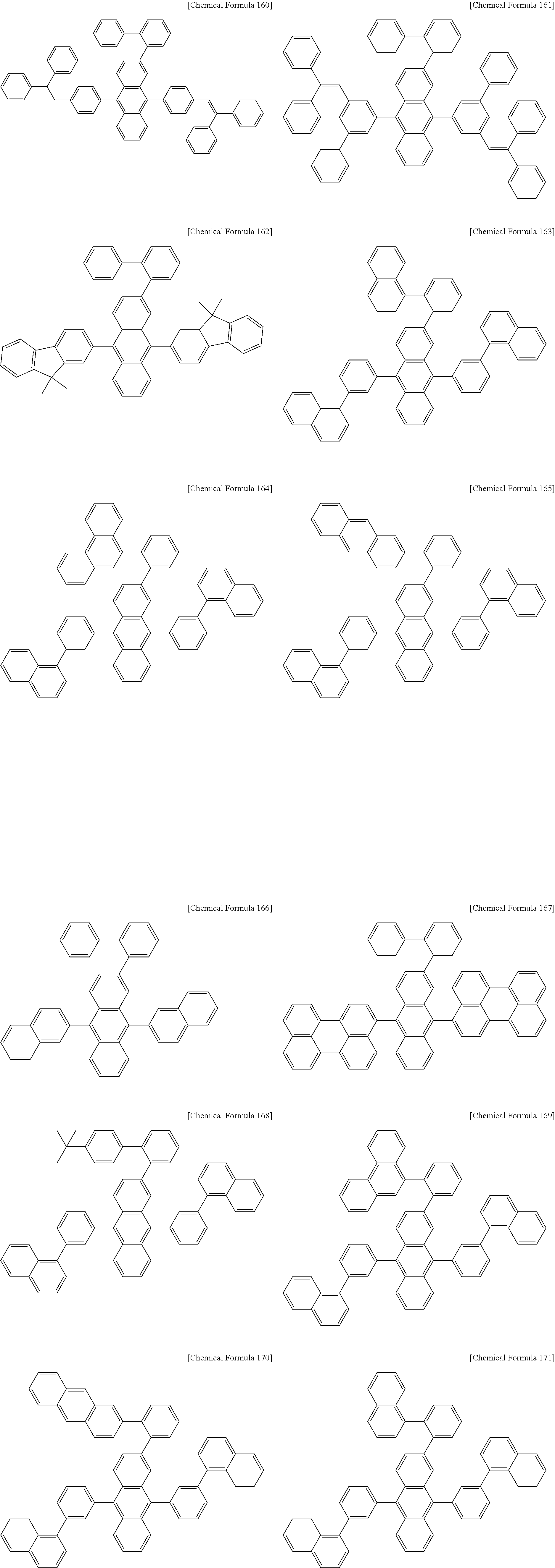

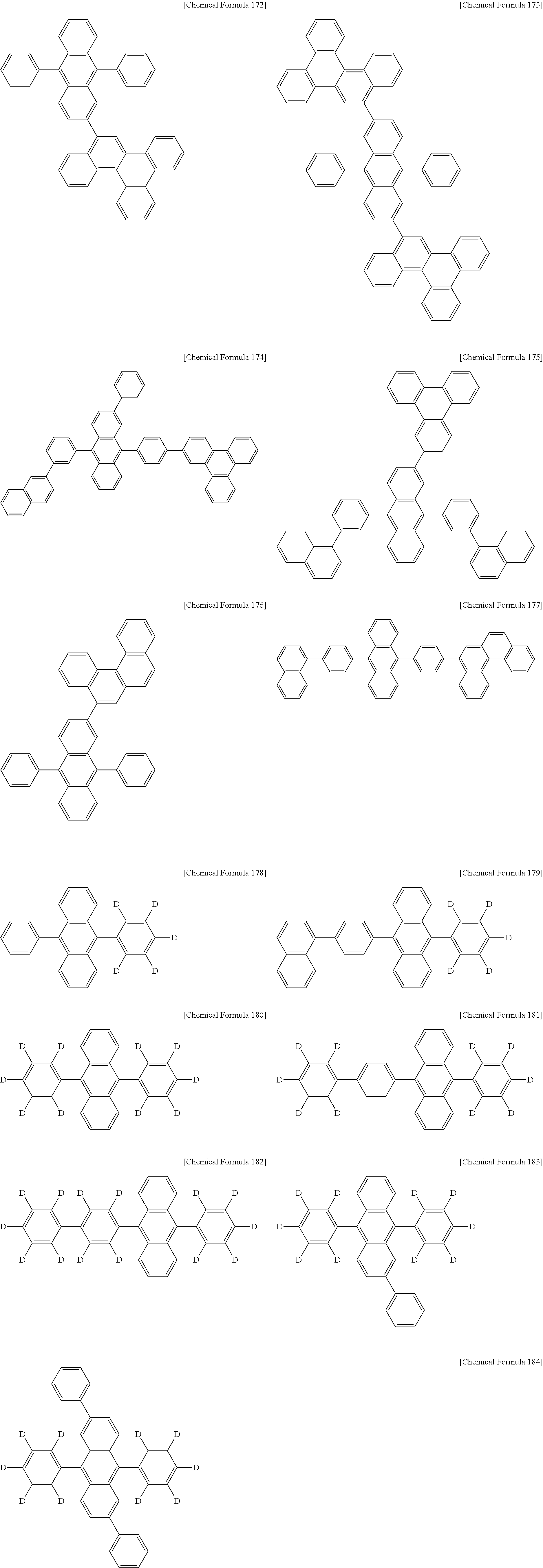

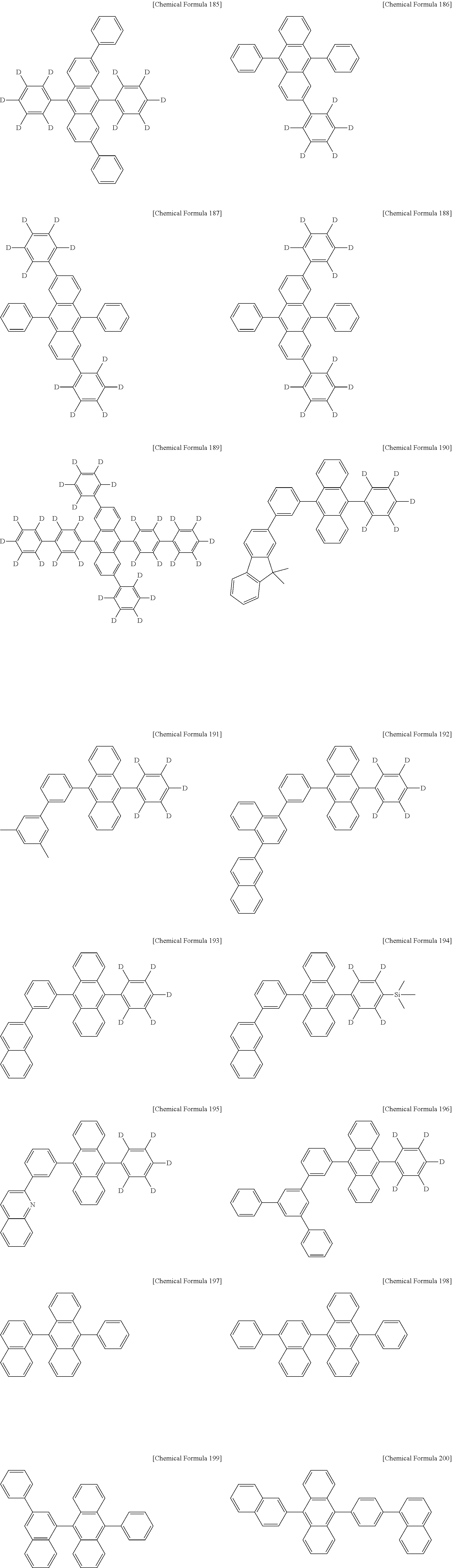

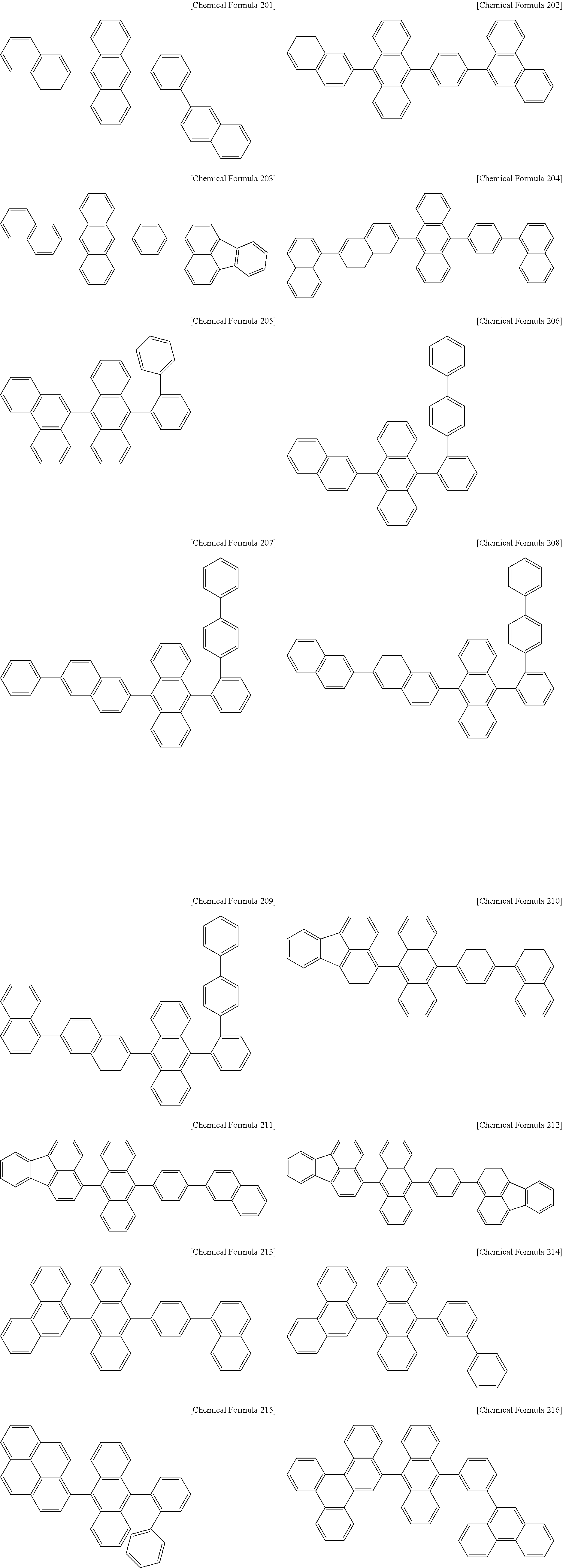

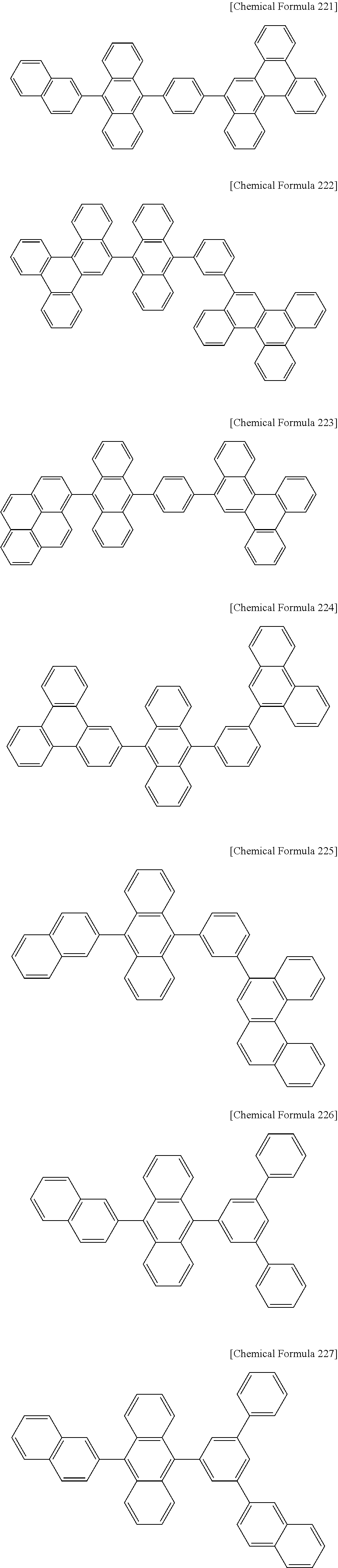

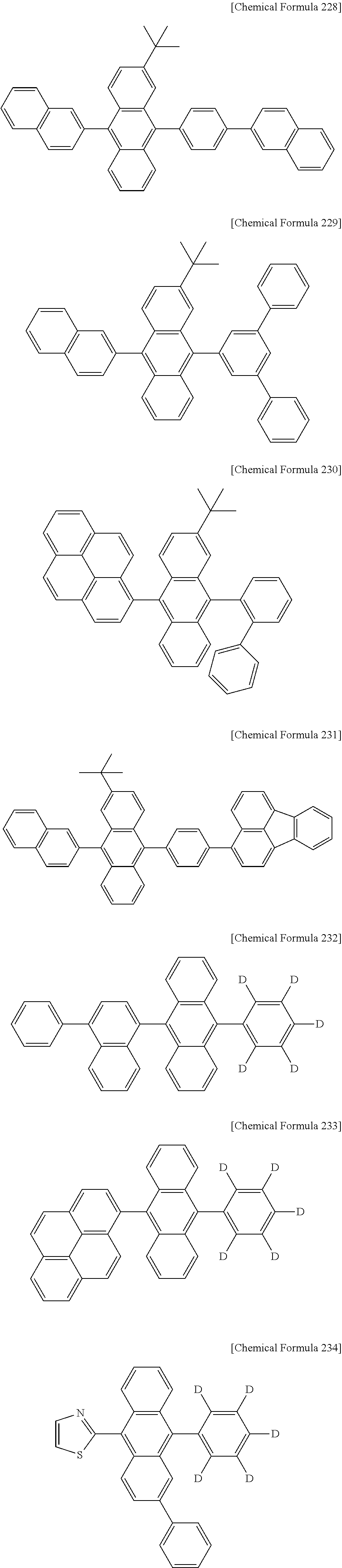

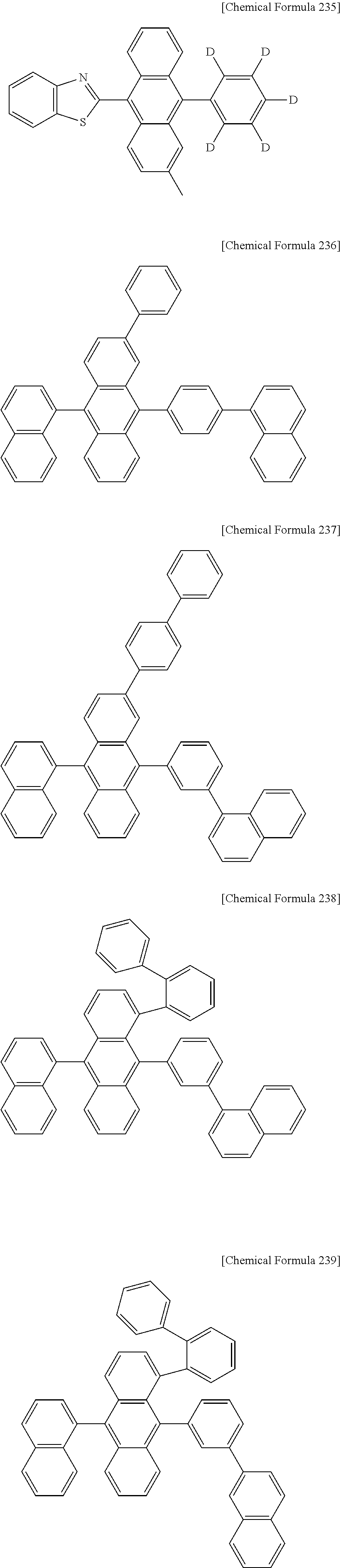

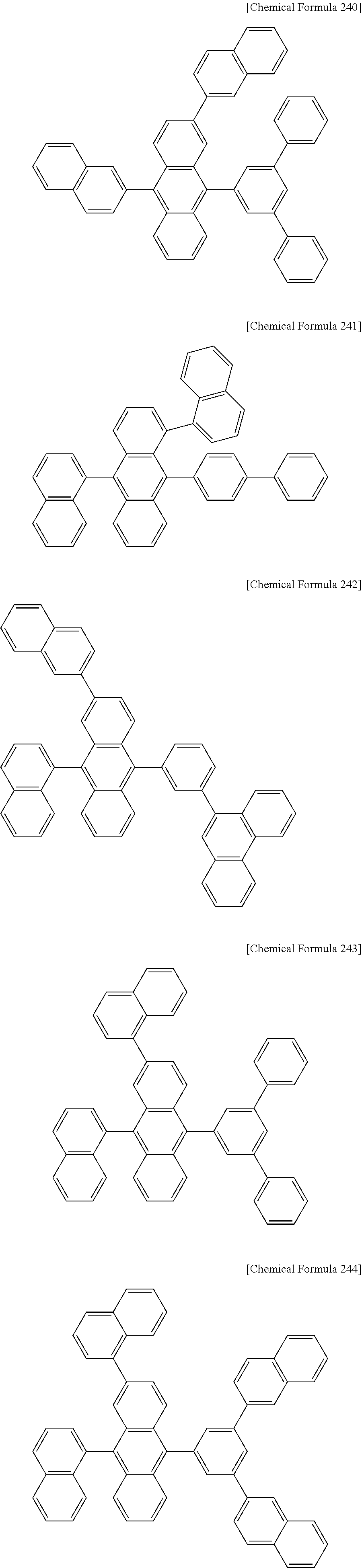

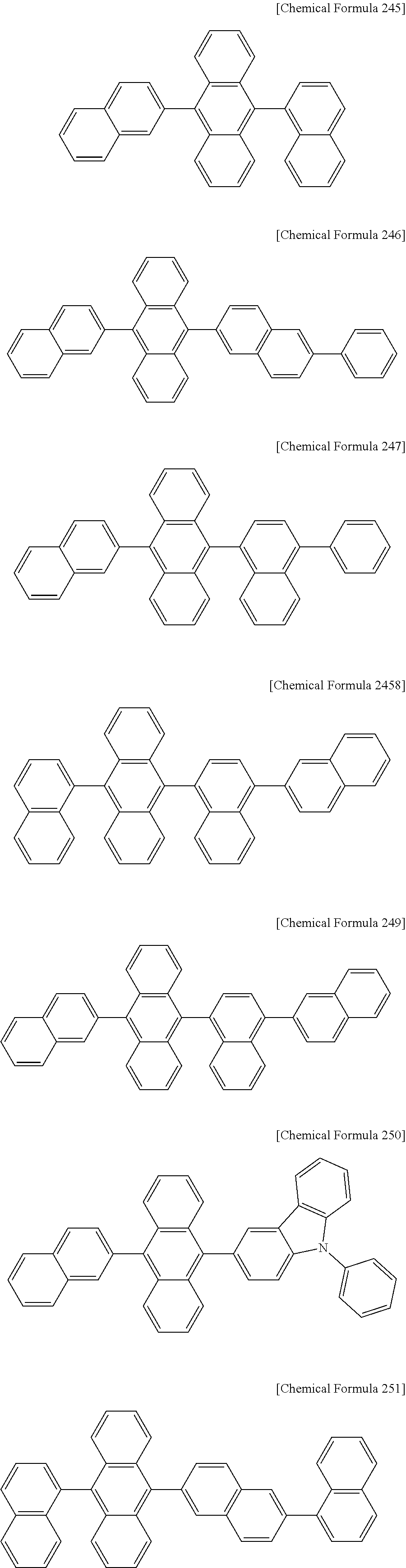

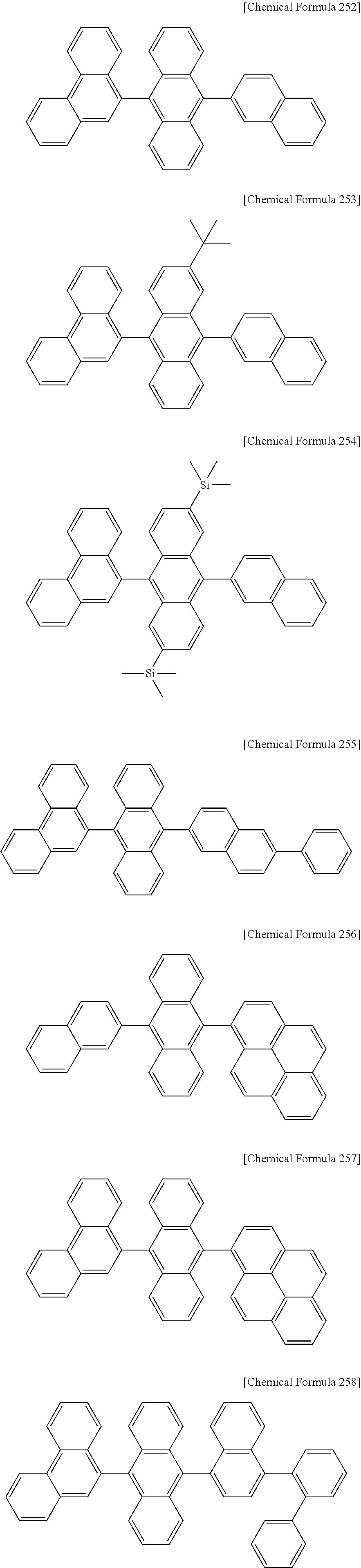

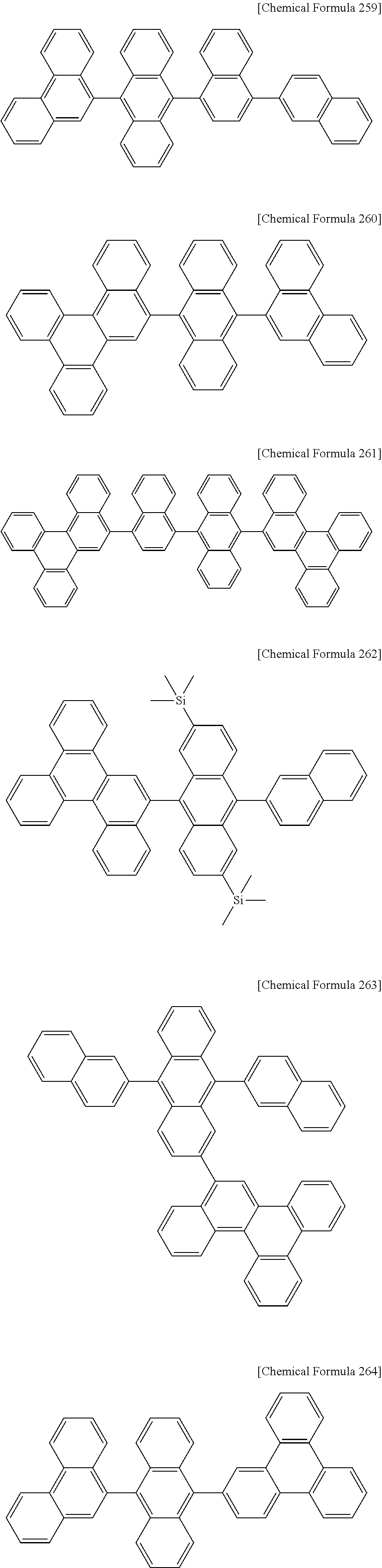

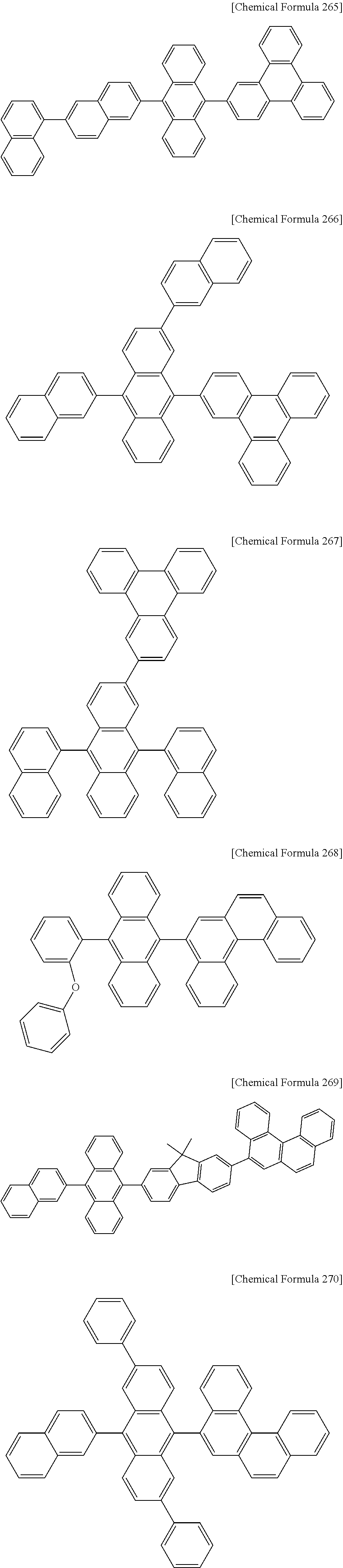

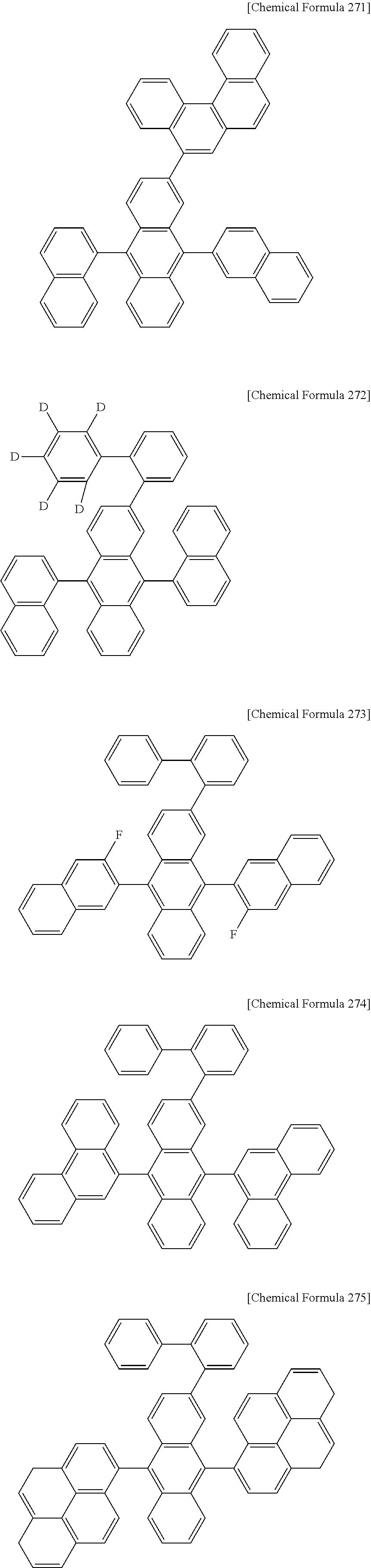

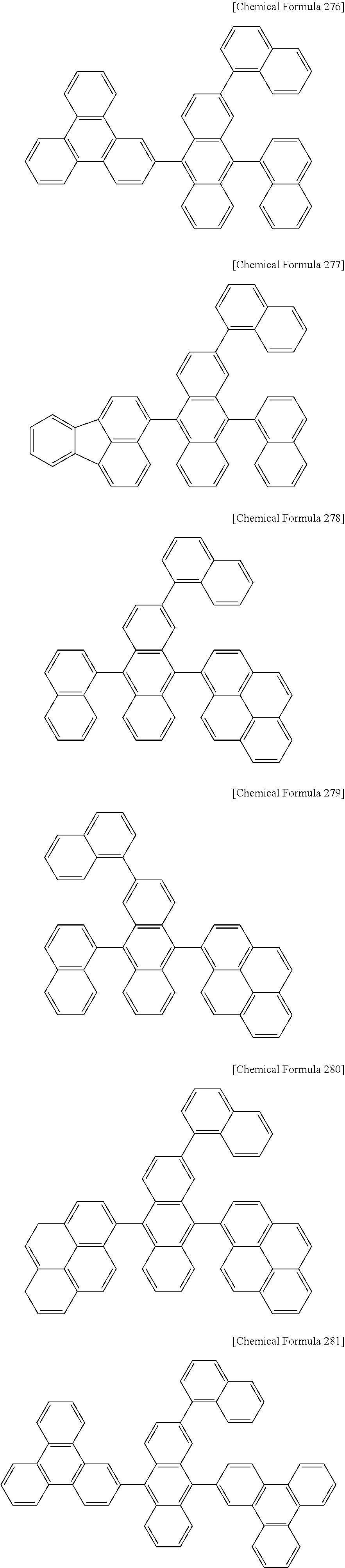

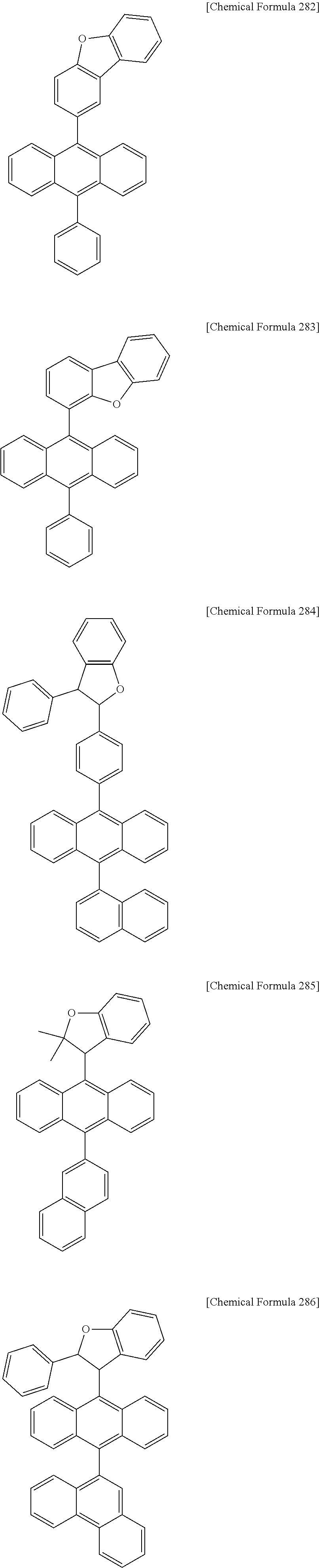

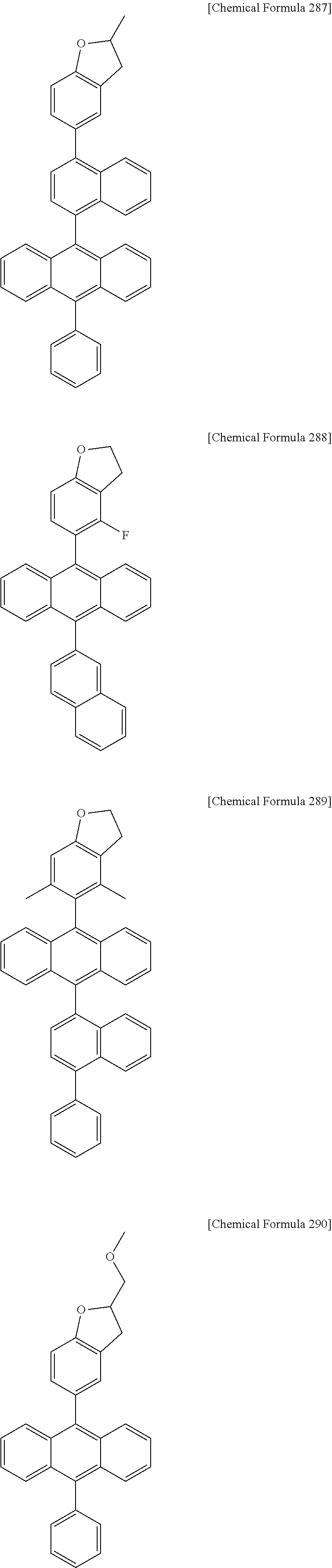

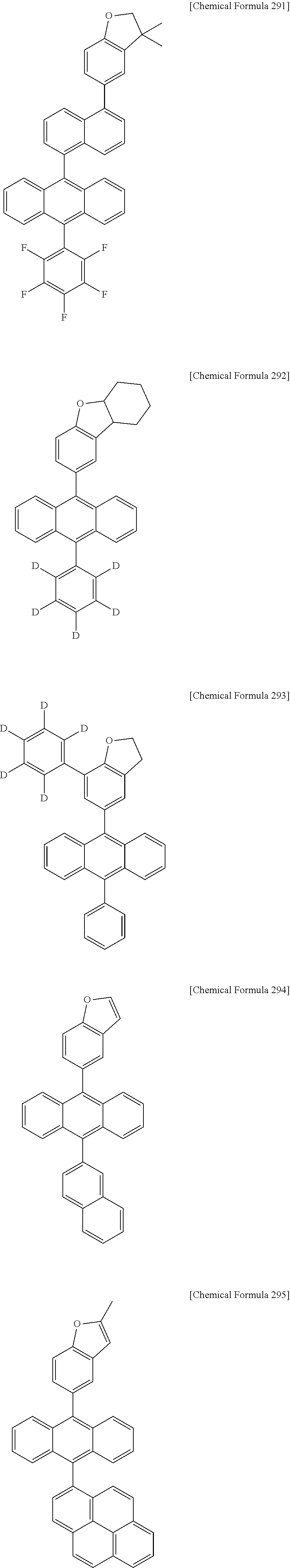

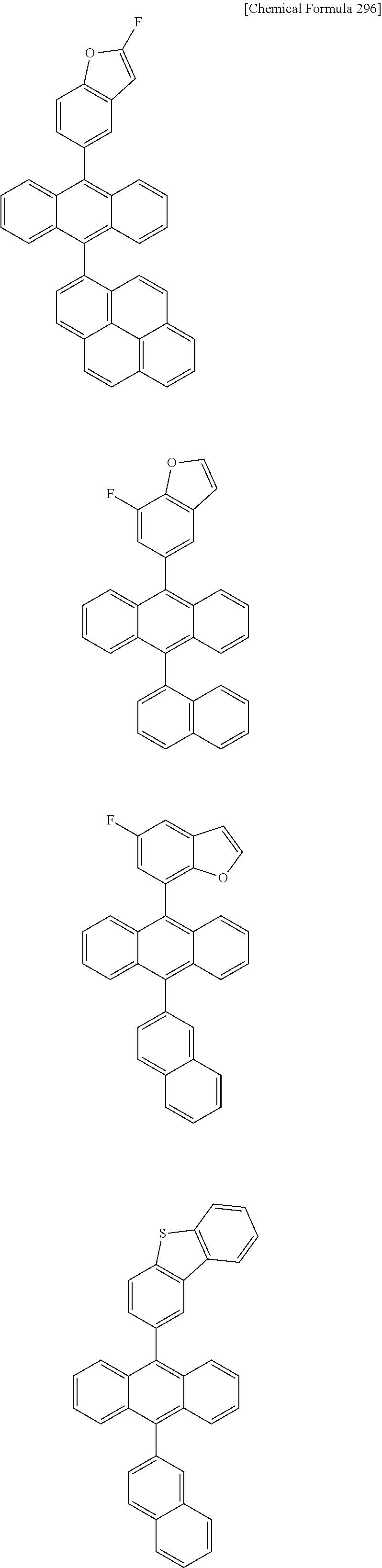

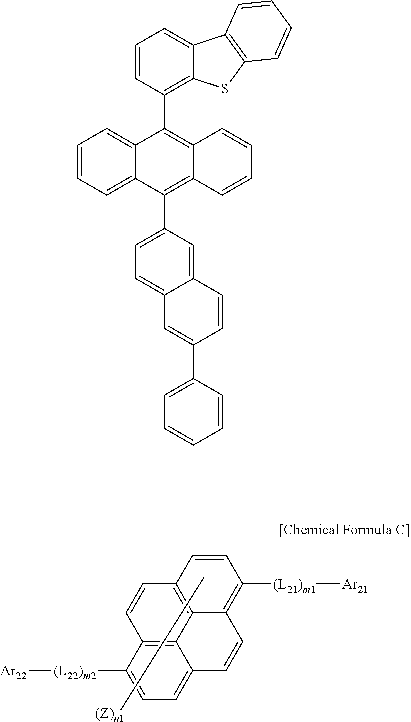

wherein,
linkers L₂₁ and L₂₂, which are same or different, may each be independently selected from among a single bond, a substituted or unsubstituted arylene of 6 to 30, and a substituted or unsubstituted heteroarylene of 2 to 30 carbon atoms,
m1 and m2, which are same or different, may each be independently an integer of 1 to 2, wherein when m1 and m2 are each 2, the corresponding L₂₁ may be same or different and the corresponding L₂₂ may be same or different;
Ar₂₁ and Ar₂₂, which are same or different, may each be independently at least one selected from among a substituted or unsubstituted aryl of 6 to 50 carbon atoms, a substituted or unsubstituted heteroaryl of 2 to 50 carbon atoms, a substituted or unsubstituted alkyl of 1 to 30 carbon atoms, a substituted or unsubstituted alkenyl of 2 to 30 carbon atoms, a substituted or unsubstituted cycloalkyl of 3 to 30 carbon atoms, a substituted or unsubstituted heterocycloalkyl of 2 to 30 carbon atoms, a substituted or unsubstituted aliphatic/aromatic composite ring of 3 to 50 carbon atoms, a substituted or unsubstituted amine of 0 to 30 carbon atoms, a substituted or unsubstituted silyl of 0 to 30 carbon atoms, a substituted or unsubstituted germanium of 0 to 30 carbon atoms;
Z is any one selected from among hydrogen atom, a deuterium atom, a substituted or unsubstituted alkyl of 1 to 30 carbon atoms, a substituted or unsubstituted alkenyl of 2 to 30 carbon atoms, a substituted or unsubstituted aryl of 6 to 50 carbon atoms, a substituted or unsubstituted cycloalkyl of 3 to 30 carbon atoms, a substituted or unsubstituted heterocycloalkyl of 2 to 30 carbon atoms, a substituted or unsubstituted heteroaryl of 2 to 50 carbon atoms, a substituted or unsubstituted aliphatic/aromatic composite ring of 3 to 50 carbon atoms, a substituted or unsubstituted amine of 0 to 30 carbon atoms, a substituted or unsubstituted silyl of 0 to 30 carbon atoms, a substituted or unsubstituted germanium of 0 to 30 carbon atoms, a cyano, a nitro, and a halogen; and
n1 is an integer of 0 to 8 wherein when n1 is 2 or greater, the corresponding Z's may be same or different, and
when Z, Ar₂₁-(L₂₁)m1- or Ar₂₁-(L₂₂)m2- is not bonded thereto, the pyrene ring moiety has a hydrogen atom or a deuterium atom on the carbon atom thereof.

In greater detail, examples of the host compound represented by Chemical Formula C include [Chemical Formula 301] to [Chemical Formula 372]:

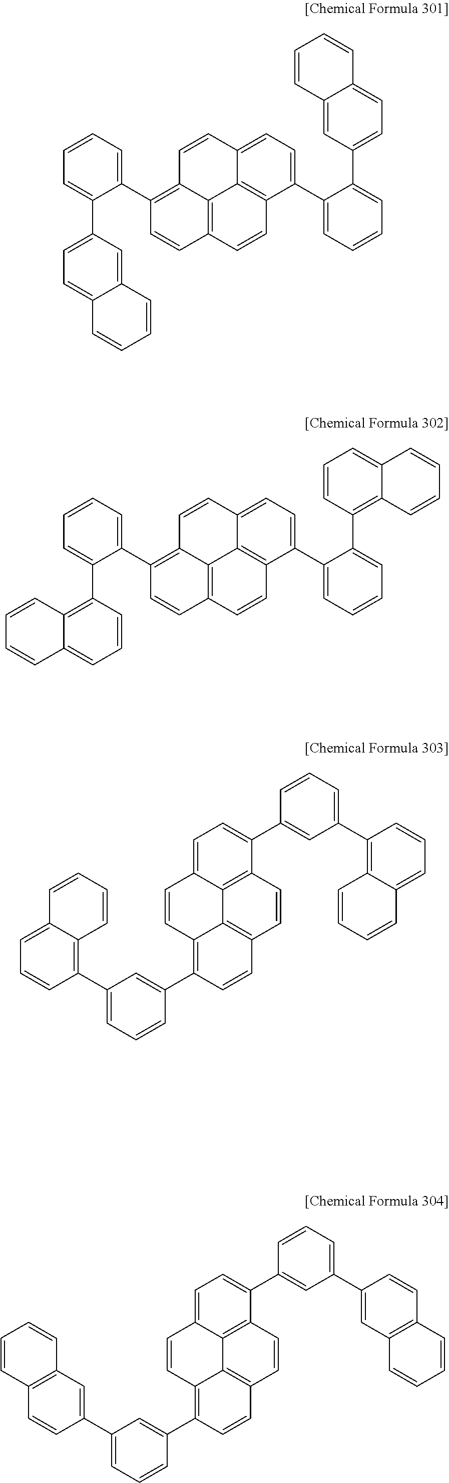

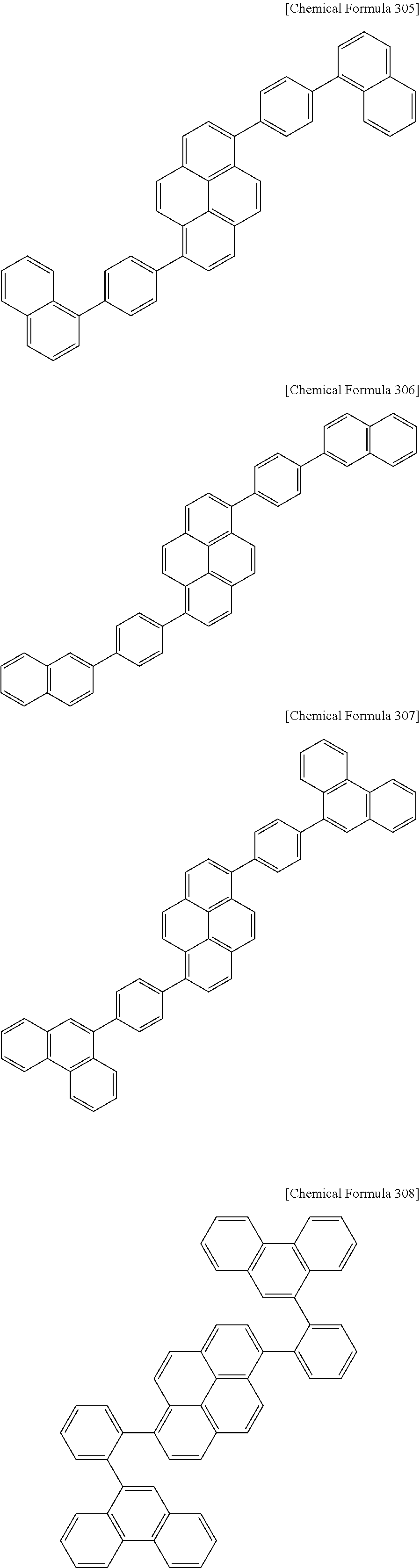

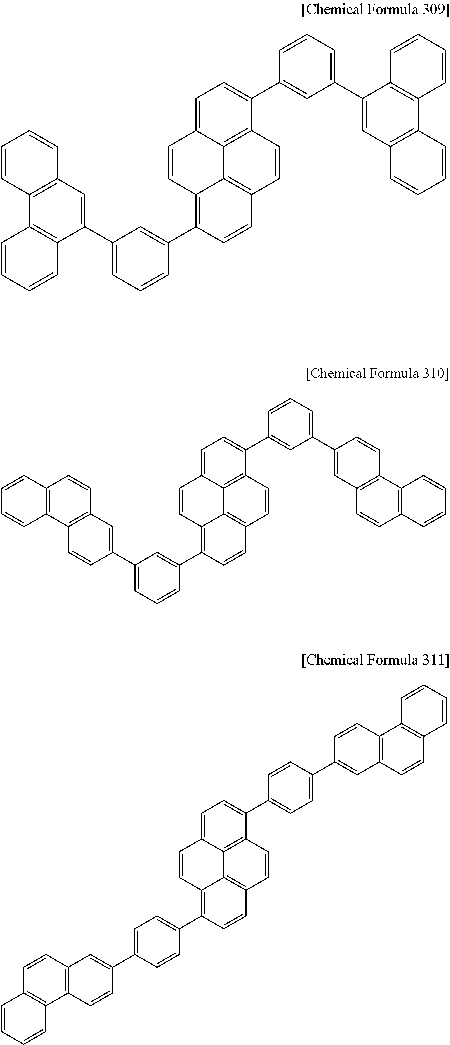

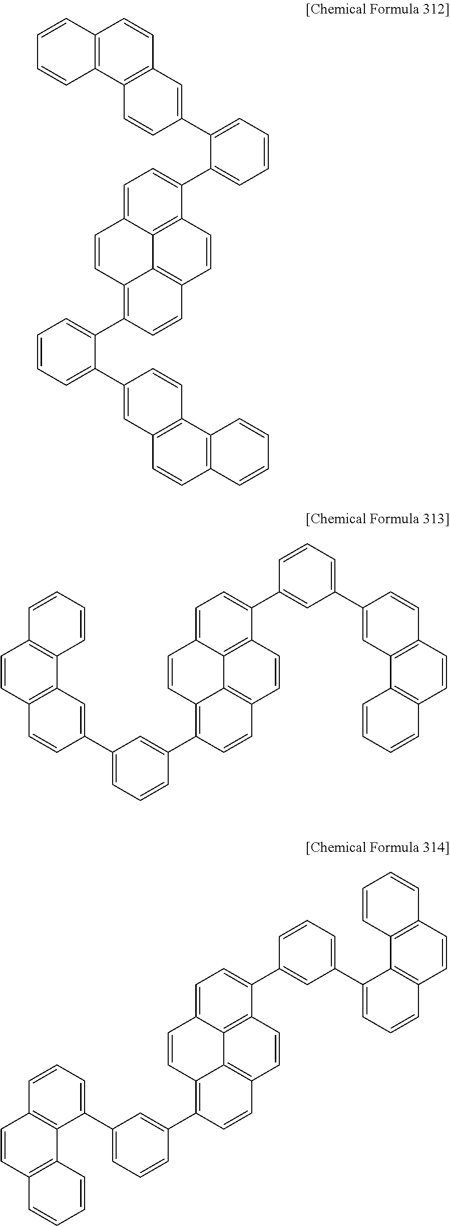

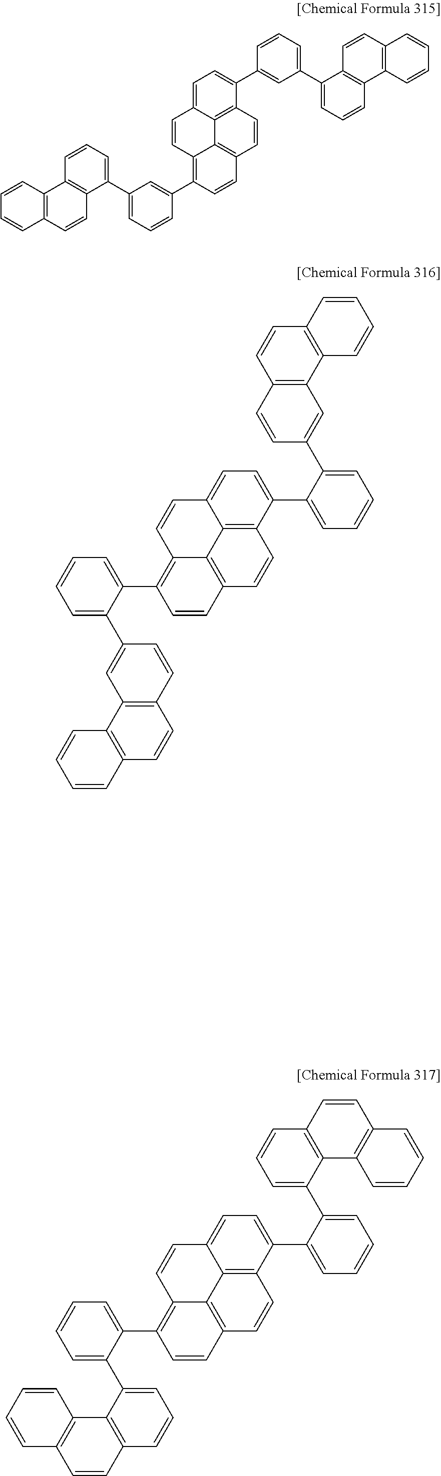

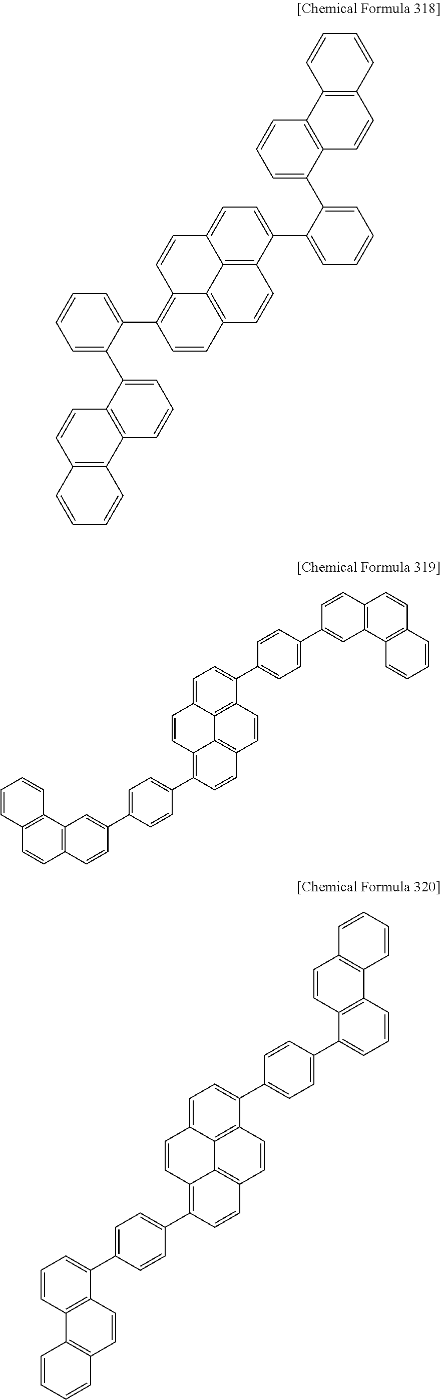

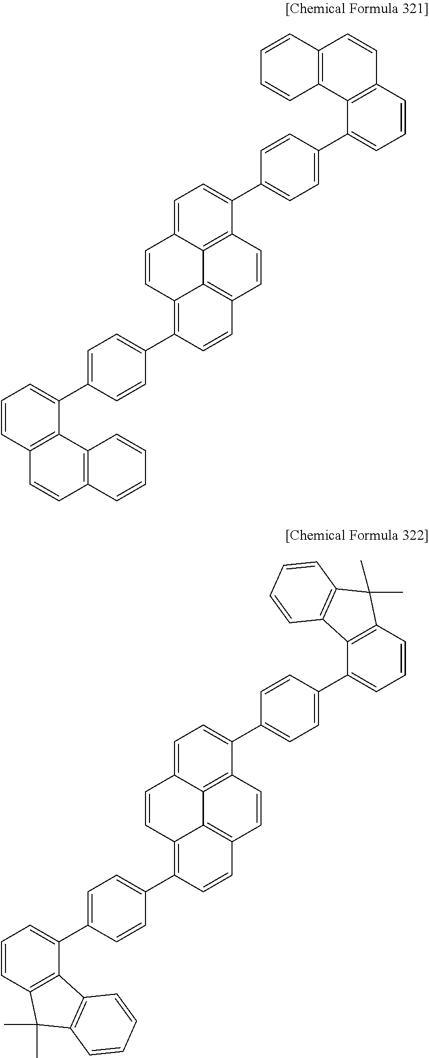

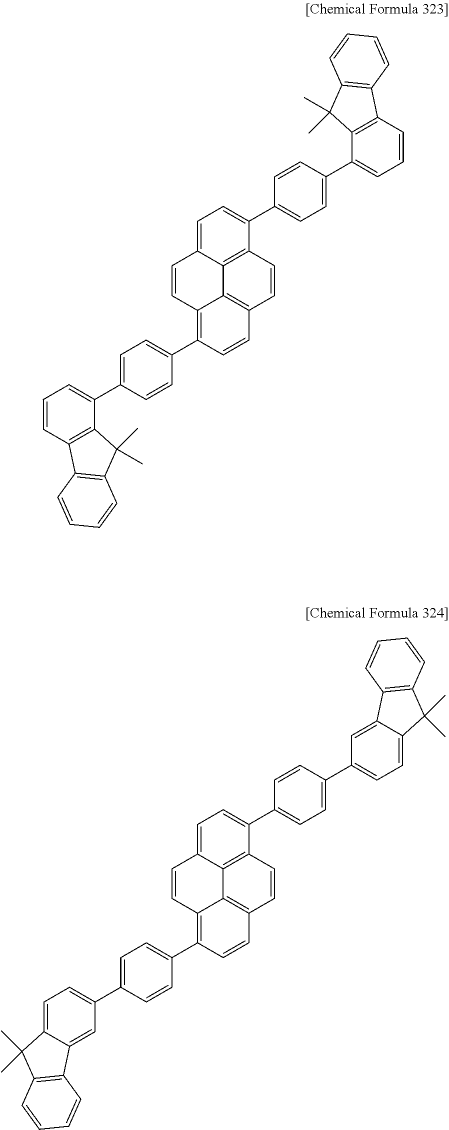

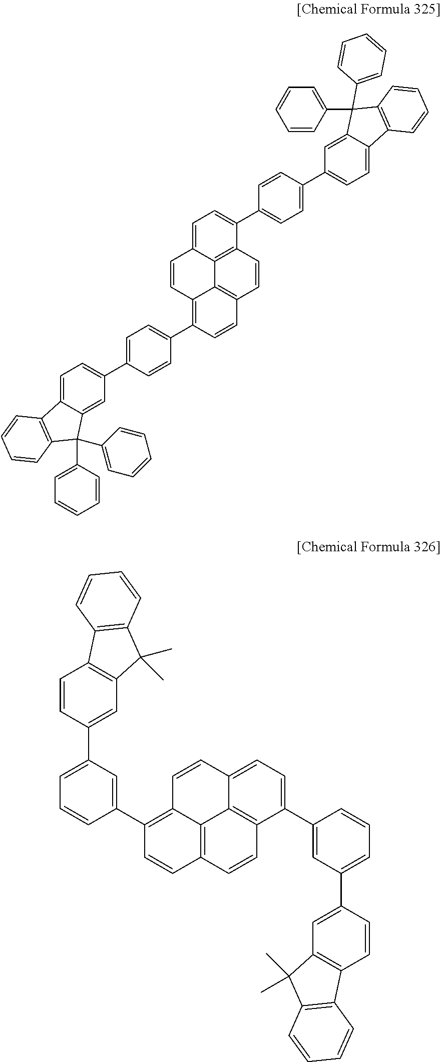

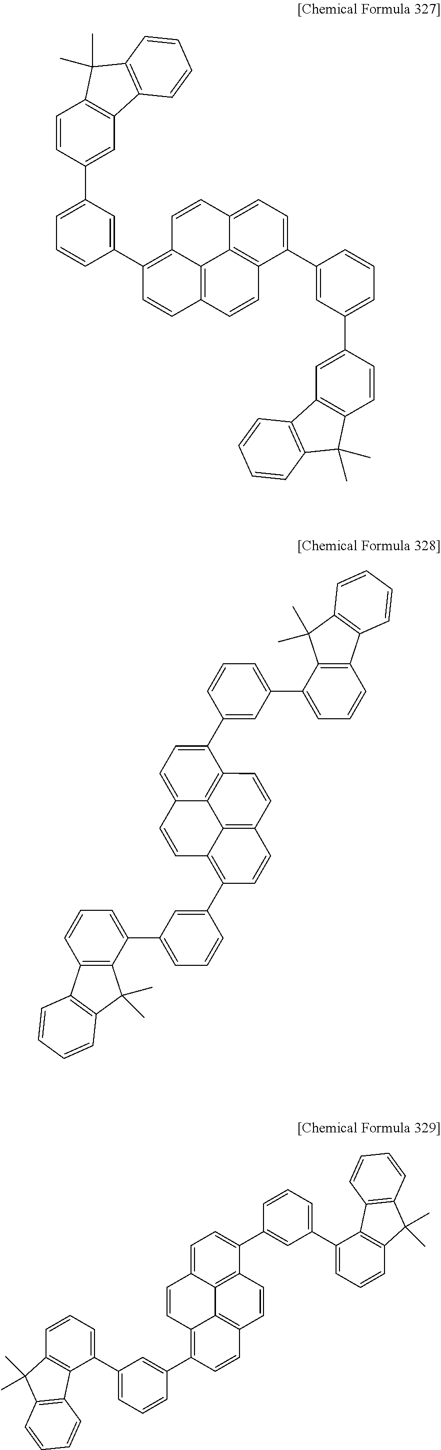

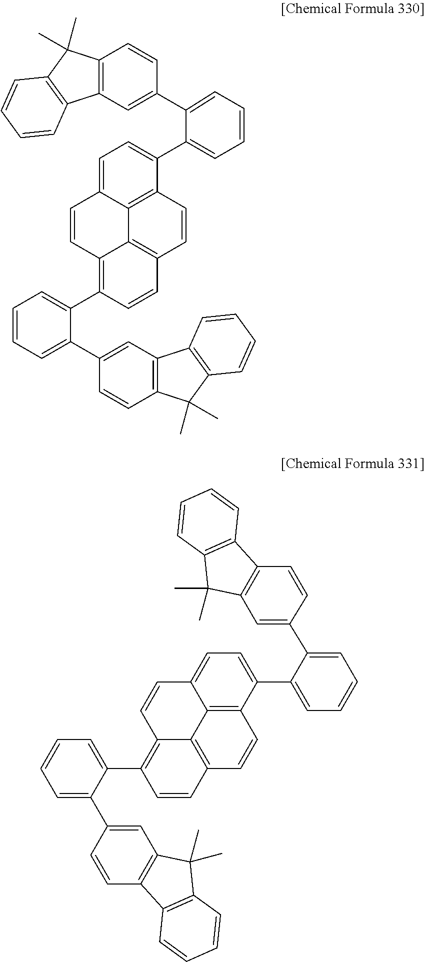

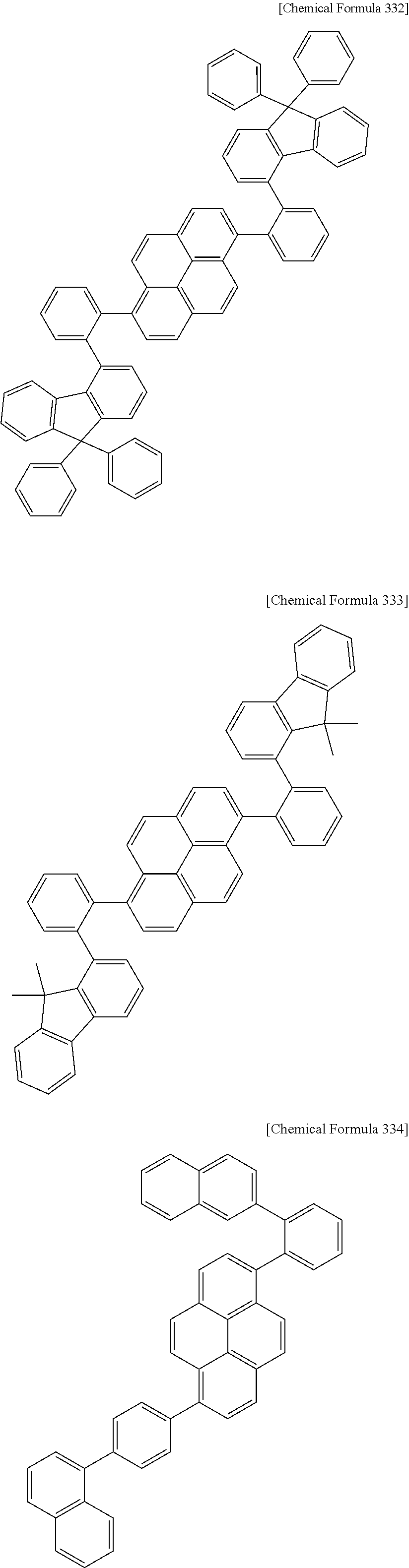

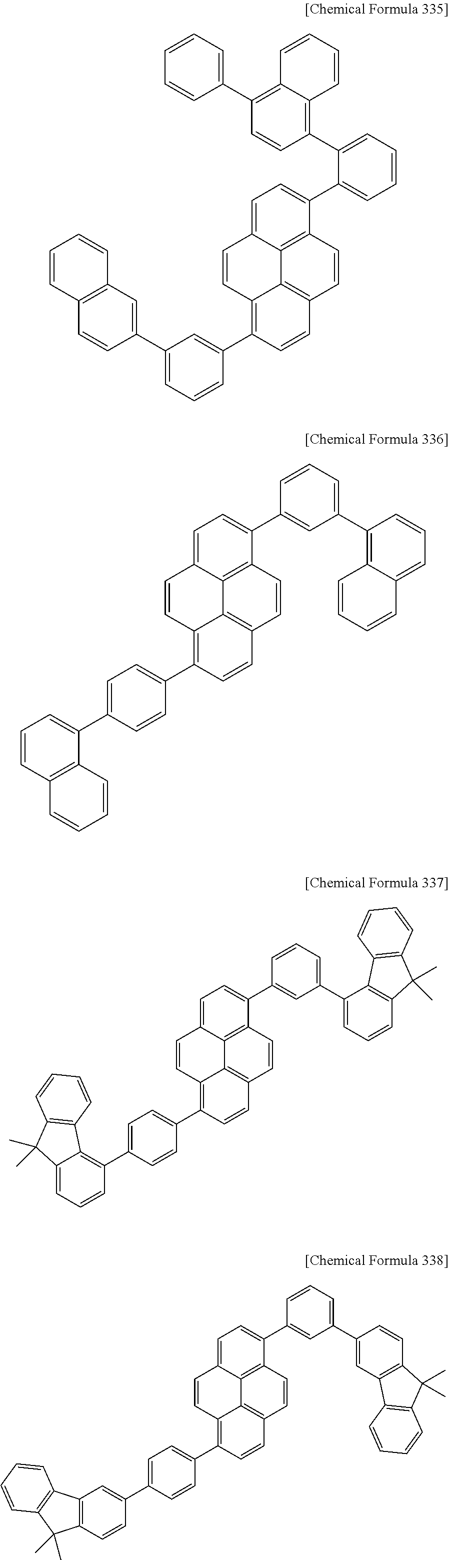

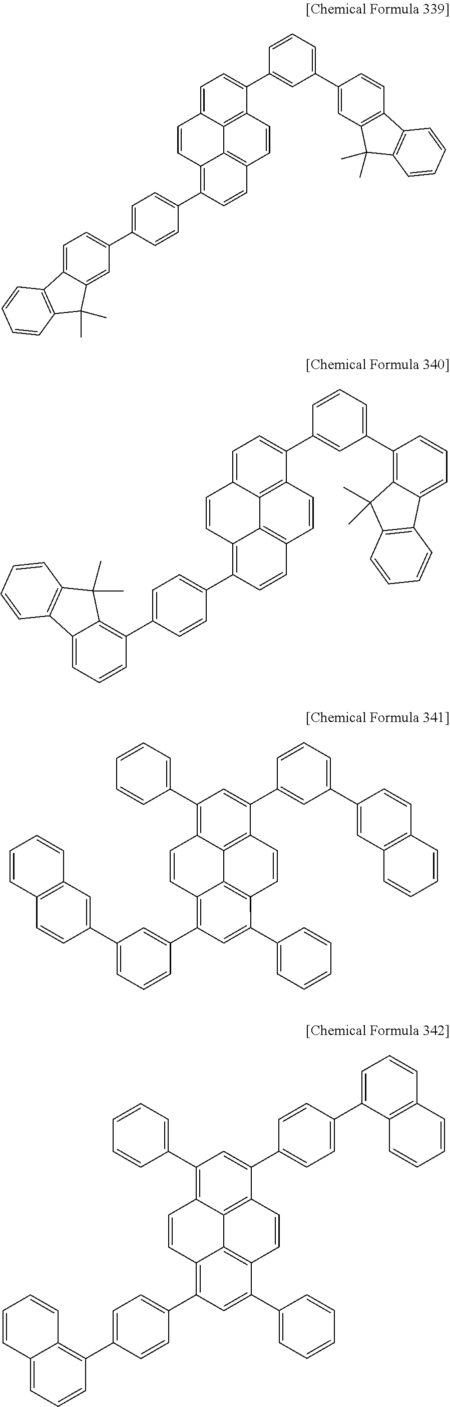

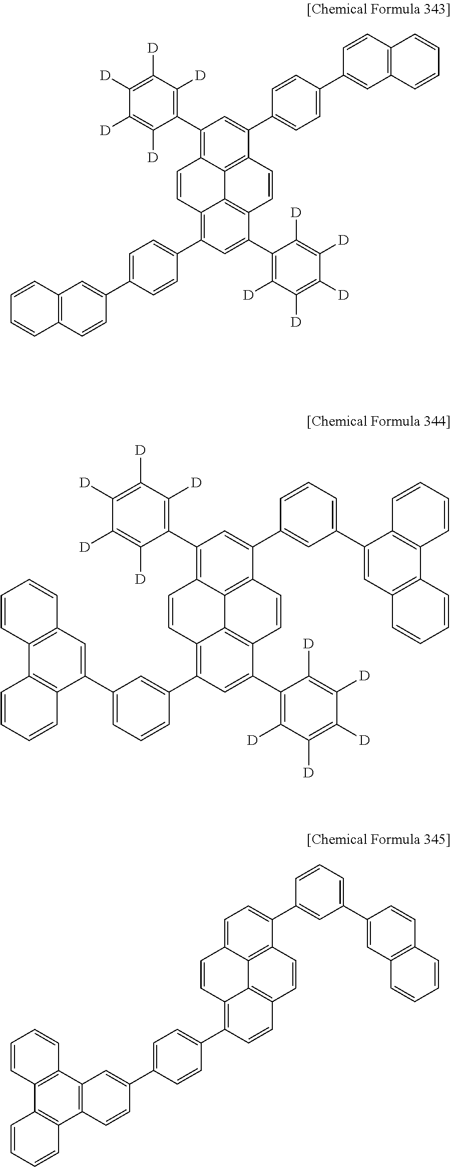

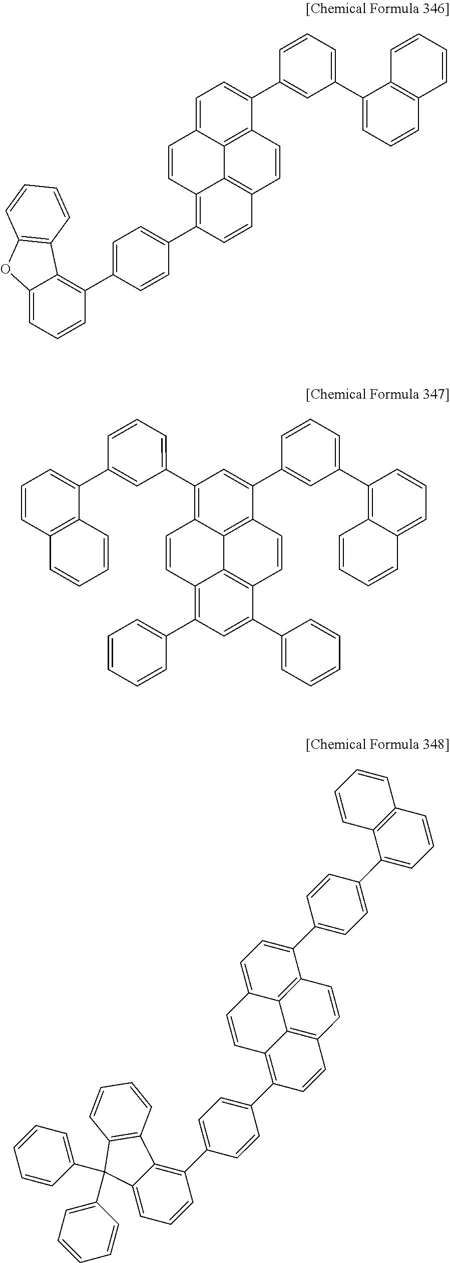

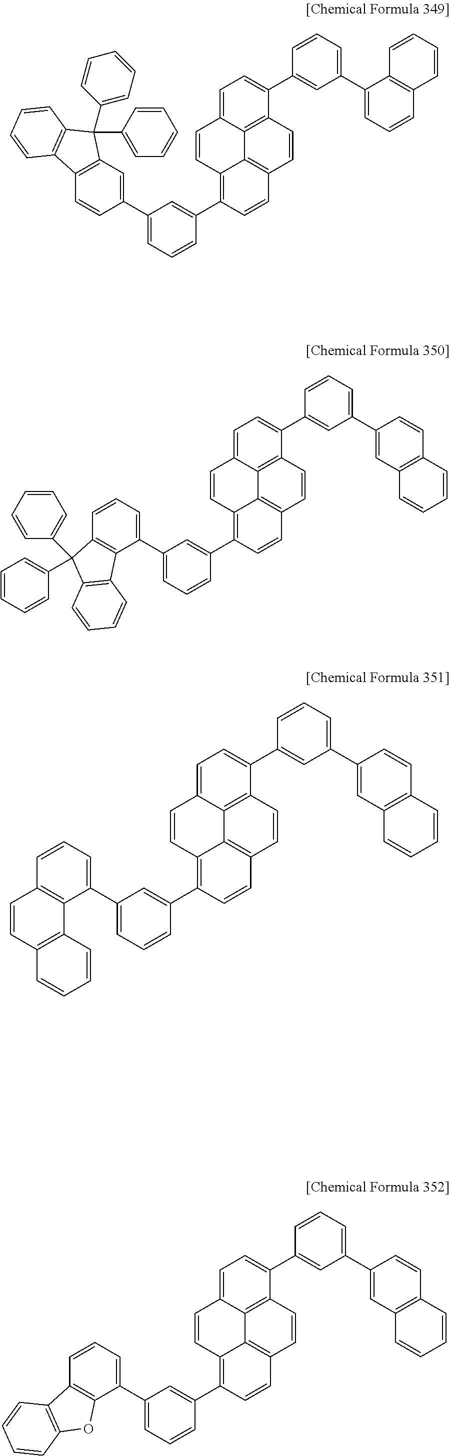

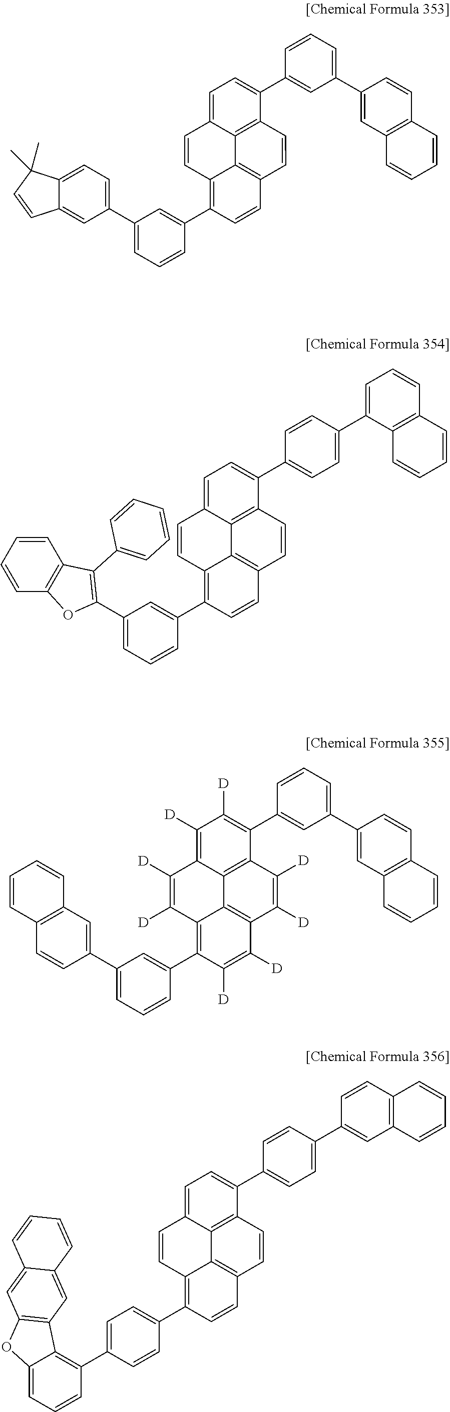

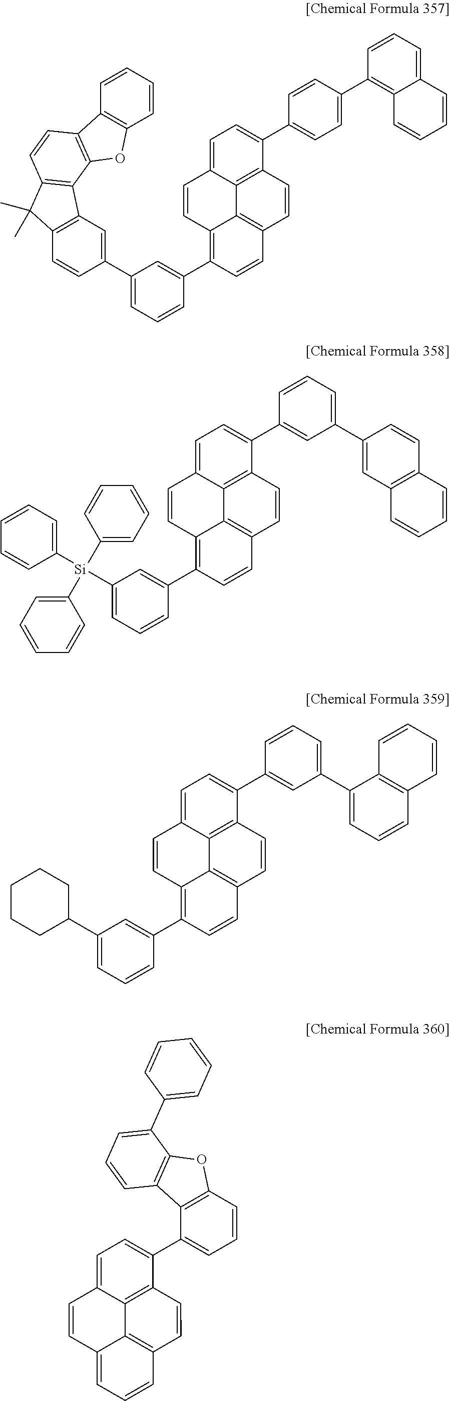

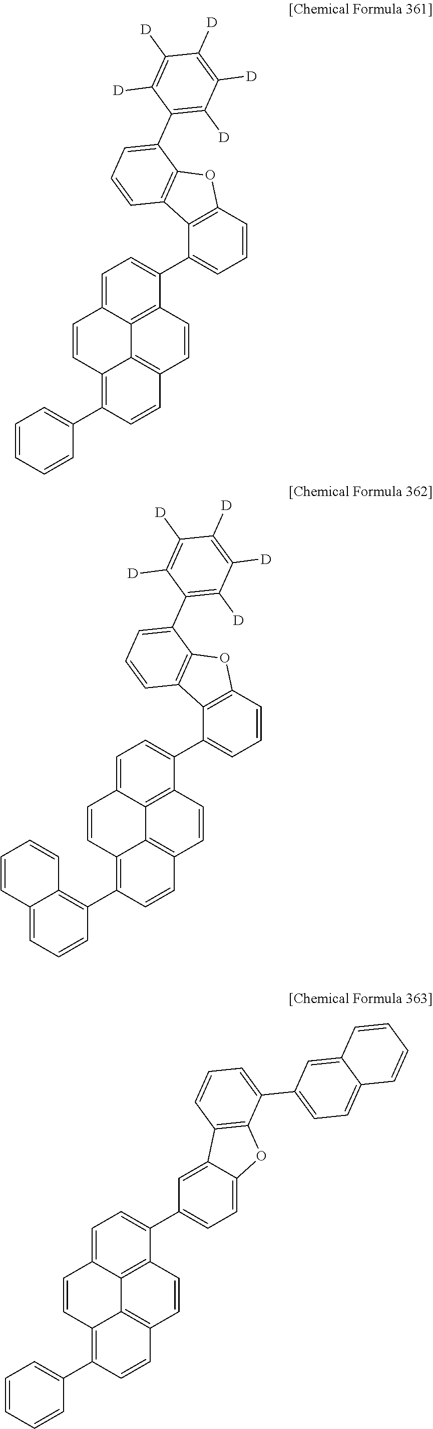 [SMILES: [2H]c1c([2H])c([2H])c(-c2cccc3c2oc2cccc(-c4ccc5ccc6c(-c7ccccc7)ccc7ccc4c5c76)c23)c([2H])c1[2H] ; [2H]c1c([2H])c([2H])c(-c2cccc3c2oc2cccc(-c4ccc5ccc6c(-c7cccc8ccccc78)ccc7ccc4c5c76)c23)c([2H])c1[2H] ; c1ccc(-c2ccc3ccc4c(-c5ccc6oc7c(-c8ccc9ccccc9c8)cccc7c6c5)ccc5ccc2c3c54)cc1]

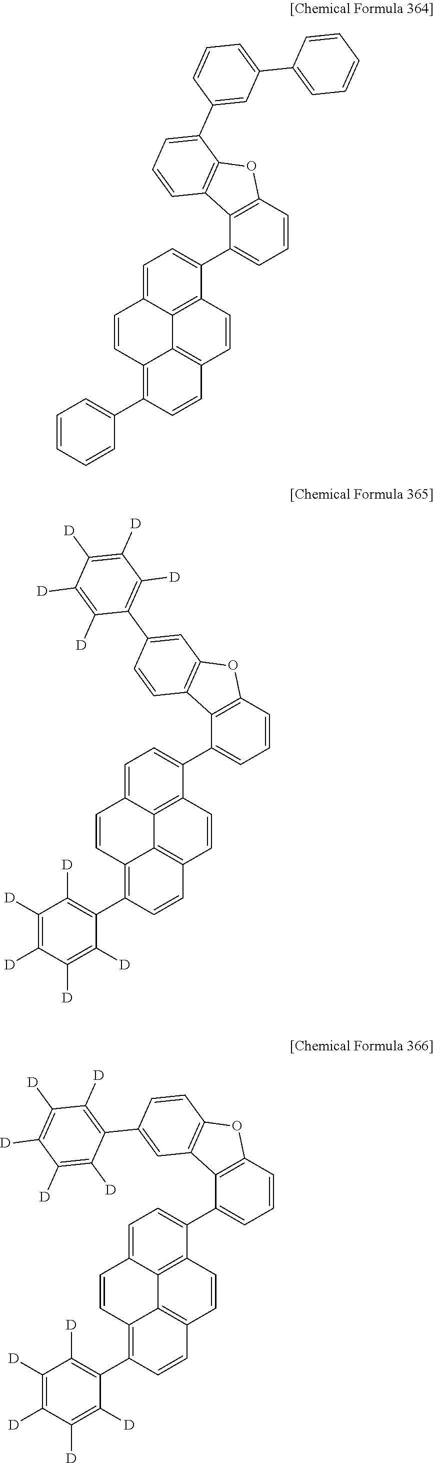 [SMILES: c1ccc(-c2cccc(-c3cccc4c3oc3cccc(-c5ccc6ccc7c(-c8ccccc8)ccc8ccc5c6c87)c34)c2)cc1 ; [2H]c1c([2H])c([2H])c(-c2ccc3c(c2)oc2cccc(-c4ccc5ccc6c(-c7c([2H])c([2H])c([2H])c([2H])c7[2H])ccc7ccc4c5c76)c23)c([2H])c1[2H] ; [2H]c1c([2H])c([2H])c(-c2ccc3oc4cccc(-c5ccc6ccc7c(-c8c([2H])c([2H])c([2H])c([2H])c8[2H])ccc8ccc5c6c87)c4c3c2)c([2H])c1[2H]]

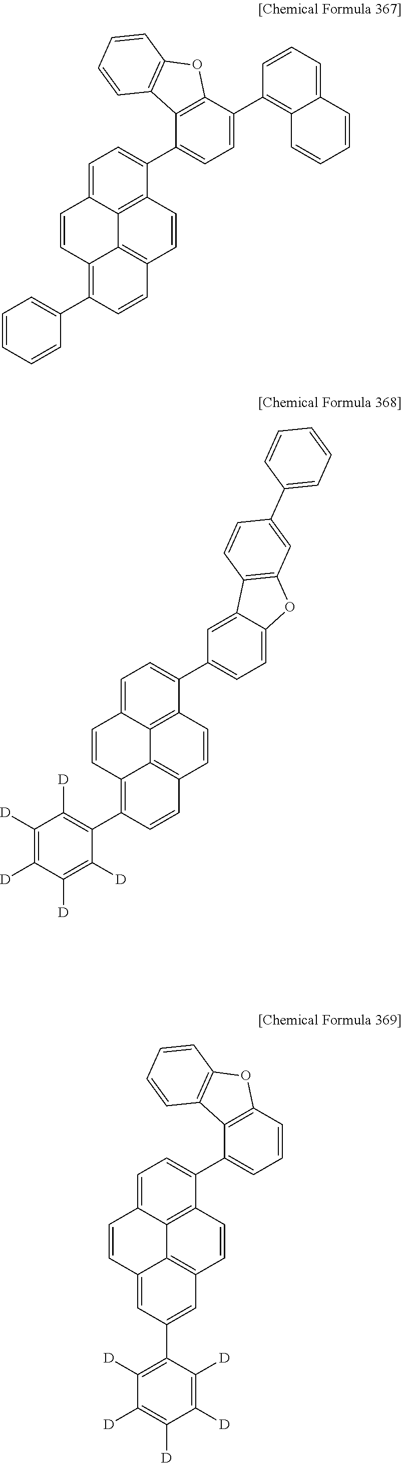 [SMILES: c1ccc(-c2ccc3ccc4c(-c5ccc(-c6cccc7ccccc67)c6oc7ccccc7c56)ccc5ccc2c3c54)cc1 ; [2H]c1c([2H])c([2H])c(-c2ccc3ccc4c(-c5ccc6oc7cc(-c8ccccc8)ccc7c6c5)ccc5ccc2c3c54)c([2H])c1[2H] ; [2H]c1c([2H])c([2H])c(-c2cc3ccc4ccc(-c5cccc6oc7ccccc7c56)c5ccc(c2)c3c45)c([2H])c1[2H]]

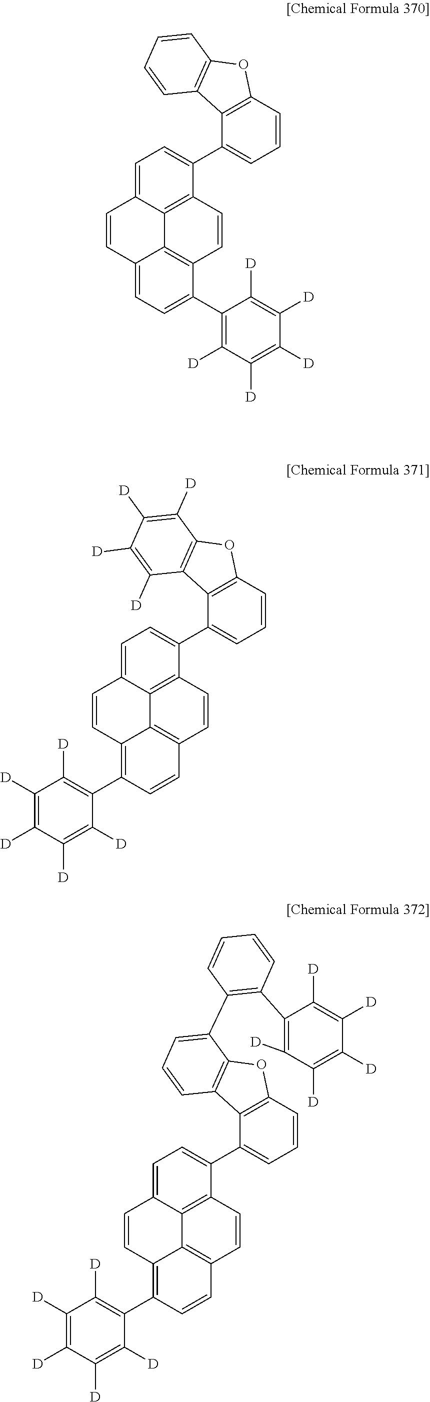 [SMILES: [2H]c1c([2H])c([2H])c(-c2ccc3ccc4ccc(-c5cccc6oc7ccccc7c56)c5ccc2c3c45)c([2H])c1[2H] ; [2H]c1c([2H])c([2H])c(-c2ccc3ccc4c(-c5cccc6oc7c([2H])c([2H])c([2H])c([2H])c7c56)ccc5ccc2c3c54)c([2H])c1[2H] ; [2H]c1c([2H])c([2H])c(-c2ccccc2-c2cccc3c2oc2cccc(-c4ccc5ccc6c(-c7c([2H])c([2H])c([2H])c([2H])c7[2H])ccc7ccc4c5c76)c23)c([2H])c1[2H]]

After being deposited on the light emission layer by deposition in a vacuum and spin coating, the electron transport layer 60 is covered with the electron injection layer 70. A cathode metal is deposited on the electron injection layer 70 by thermal vacuum deposition to form the cathode 80, thus obtaining an organic light-emitting diode.

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinorate)aluminum (Alq₃), Liq, TAZ, BAlq, beryllium bis(benzoquinolin-10-olate) (Bebq₂), Compound 201, Compound 202, BCP, and oxadiazole derivatives such as PBD, BMD, and BND, but are not limited thereto:

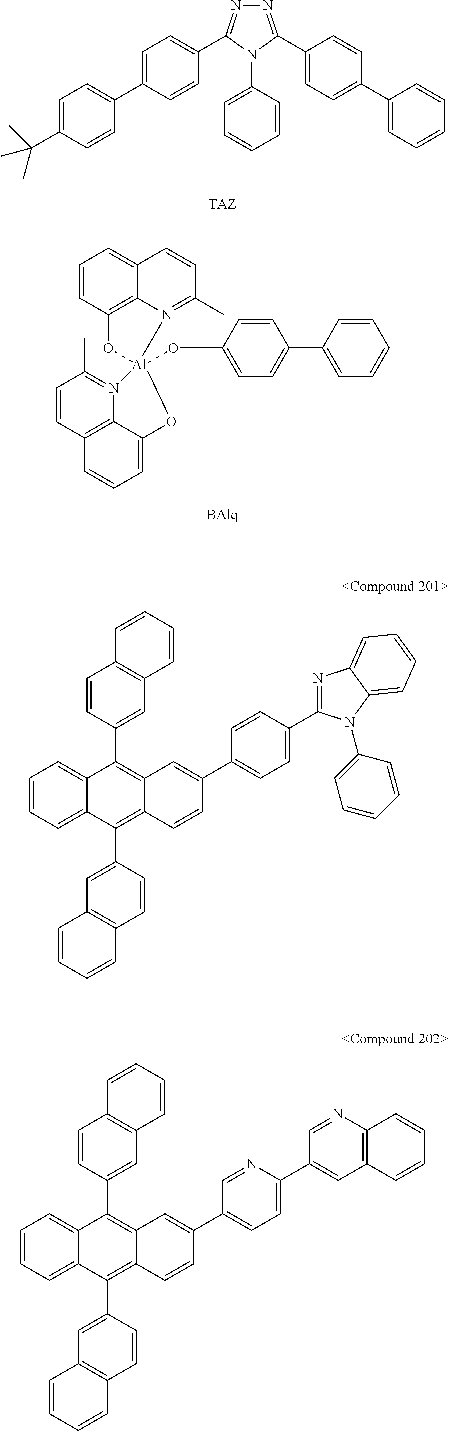

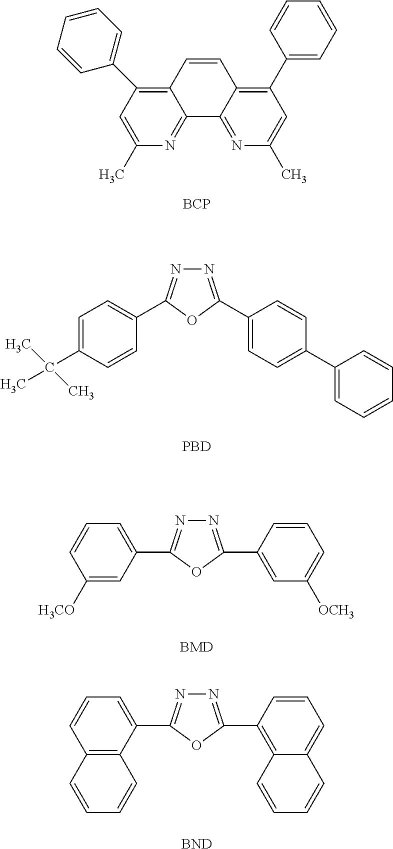

In the organic light emitting diode of the present disclosure, an electron injection layer (EIL) that functions to facilitate electron injection from the cathode may be deposited on the electron transport layer. The material for the EIL is not particularly limited.

So long as it is conventionally used in the art, any material can be available for the electron injection layer without particular limitations. Examples include CsF, NaF, LiF, Li₂O, and BaO. Deposition conditions for the electron injection layer may vary, depending on compounds used, but may be generally selected from condition scopes that are almost the same as for the formation of hole injection layers.

The electron injection layer may range in thickness from about 1 Å to about 100 Å, and particularly from about 3 Å to about 90 Å. Given the thickness range for the electron injection layer, the diode can exhibit satisfactory electron injection properties without actually elevating a driving voltage.

Here, the cathode may be made of lithium (Li), magnesium (Mg), aluminum (Al), aluminum-lithium (Al—Li), calcium (Ca), magnesium-indium (Mg—In), or magnesium-silver (Mg—Ag). For a top-emitting OLED, a transparent cathode made of ITO or IZO may be employed.

In another embodiment, the light-emitting diode of the present disclosure may further comprise a light-emitting layer, made of a blue light-emitting material, a green light-emitting material, or a red light-emitting material, which can emit light in a wavelength range of 380 nm to 800 nm. That is, the light-emitting layer in the organic light-emitting device of the present disclosure may have a multilayer structure in which the additional blue, green, and/or red light-emitting layer may be made of a fluorescent or phosphorescent material.

Moreover, one or more layers selected from among a hole injection layer, a hole transport layer, a light emission layer, an electron transport layer, and an electron injection layer may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, monochrome or grayscale flexible illumination devices; vehicle display devices; and virtual or augmented reality display devices.

A better understanding of the present disclosure may be obtained through the following examples which are set forth to illustrate, but are not to be construed as limiting the present disclosure.

### EXAMPLES

### Synthesis Example 1. Synthesis of [Compound 13]

### Synthesis Example 1-1: Synthesis of 1-a

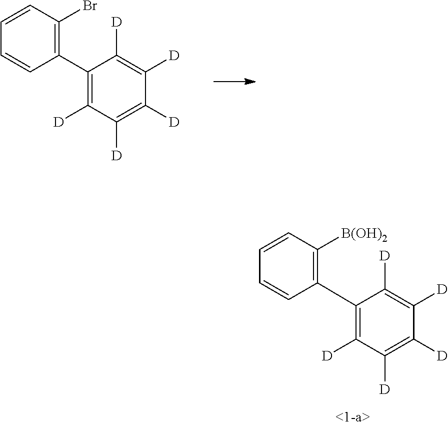 [SMILES: [2H]c1c([2H])c([2H])c(-c2ccccc2Br)c([2H])c1[2H] ; [2H]c1c([2H])c([2H])c(-c2ccccc2B(O)O)c([2H])c1[2H]]

In a 2-L reactor, a solution of 2-bromo-1,1′-biphenyl-2′,3′,4′,5′,6′-d5 (70 g) in tetrahydrofuran (700 mL) was cooled to −78° C. under a nitrogen atmosphere and n-butyl lithium (1.6 M, 213 mL) was dropwise added. The mixture was stirred for 1 hour, added with trimethyl borate (40 g), and stirred again at room temperature. After completion of the reaction, the reaction mixture was acidified with 2 N HCl. Extraction was conducted followed by subjecting the organic layer to separation and vacuum concentration. The concentrate was recrystallized in tetrahydrofuran to afford <1-a>. (45.2 g, 75%)

### Synthesis Example 1-2: Synthesis of 1-b

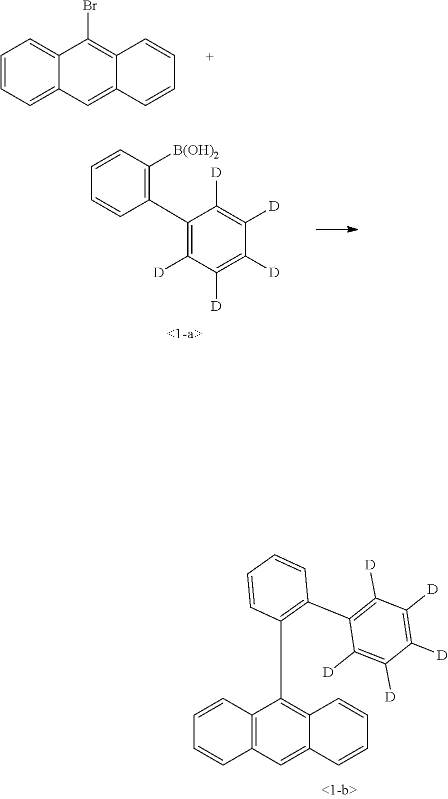 [SMILES: Brc1c2ccccc2cc2ccccc12 ; [2H]c1c([2H])c([2H])c(-c2ccccc2B(O)O)c([2H])c1[2H] ; [2H]c1c([2H])c([2H])c(-c2ccccc2-c2c3ccccc3cc3ccccc23)c([2H])c1[2H]]

In a 1 L reactor, 9-bromoanthracene (51 g), <1-a> (43 g), potassium carbonate (54.8 g), palladium (II) acetate (0.9 g), SPhos (3.3 g), toluene (210 mL), ethanol (150 mL), and distilled water (150 mL) were stirred overnight under reflux. The reaction mixture was cooled to room temperature and subjected to extraction with ethyl acetate/distilled. The organic layer was concentrated and isolated by column chromatography to afford <1-b>. (55 g, 80%)

### Synthesis Example 1-3: Synthesis of 1-c

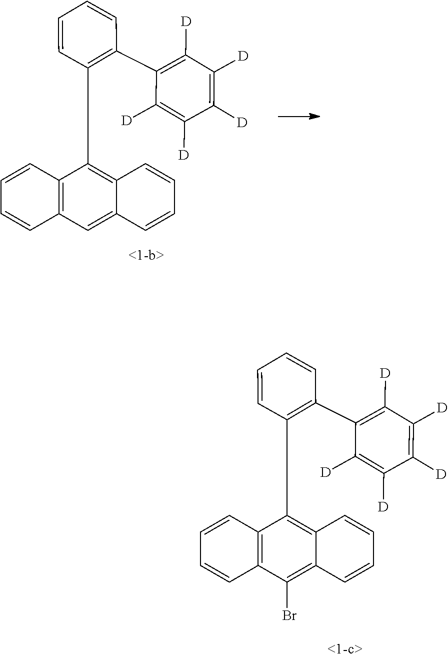 [SMILES: [2H]c1c([2H])c([2H])c(-c2ccccc2-c2c3ccccc3cc3ccccc23)c([2H])c1[2H] ; [2H]c1c([2H])c([2H])c(-c2ccccc2-c2c3ccccc3c(Br)c3ccccc23)c([2H])c1[2H]]

In a 2-L round-bottom flask, a solution of <1-b> (53 g) in N, N-dimethyl formamide (530 mL) was stirred at room temperature. A solution of N-bromosuccinimide (30.1 g) in N, N-dimethyl formamide (100 mL) was dropwise added to the reaction solution. After completion of the reaction was confirmed by thin layer chromatography, the reaction solution was added with distilled water (500 mL) and stirred. The solid thus formed was filtered. The filtrate was washed H₂O and methanol and then dissolved in toluene. Following filtration through silica gel pad, recrystallization in methanol afforded <1-c>. (52.0 g, 80%)

### Synthesis Example 1-4: Synthesis of [Compound 13]

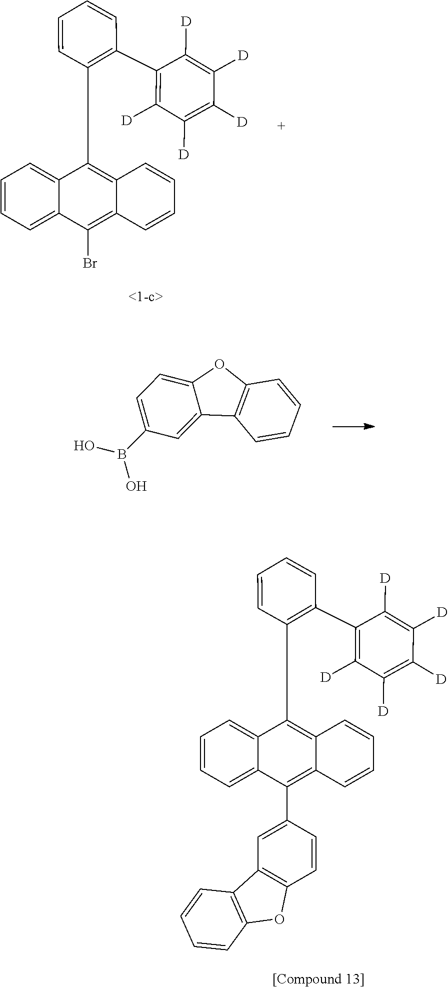 [SMILES: [2H]c1c([2H])c([2H])c(-c2ccccc2-c2c3ccccc3c(Br)c3ccccc23)c([2H])c1[2H] ; OB(O)c1ccc2oc3ccccc3c2c1 ; [2H]c1c([2H])c([2H])c(-c2ccccc2-c2c3ccccc3c(-c3ccc4oc5ccccc5c4c3)c3ccccc23)c([2H])c1[2H]]

In a 500-mL reactor, <1-c> (25 g), (dibenzofuran-2-yl)boronic acid (14.7 g), palladium(II) acetate (0.27 g), potassium carbonate (12.51 g), and SPhos (0.99 g) were stirred together for 3 hours in toluene (100 mL), ethanol (75 mL), and distilled water (75 mL). After completion of the reaction was confirmed by thin layer chromatography, the temperature was decreased to room temperature. The solid thus formed was filtered and then isolated and purified by column chromatography. Recrystallization in toluene and acetone afforded [Compound 13]. (16.65 g, 55%)

MS (MALDI-TOF): m/z 501.21 [M⁺]

### Synthesis Example 2. Synthesis of [Compound 4]

### Synthesis Example 2-1: Synthesis of 2-a

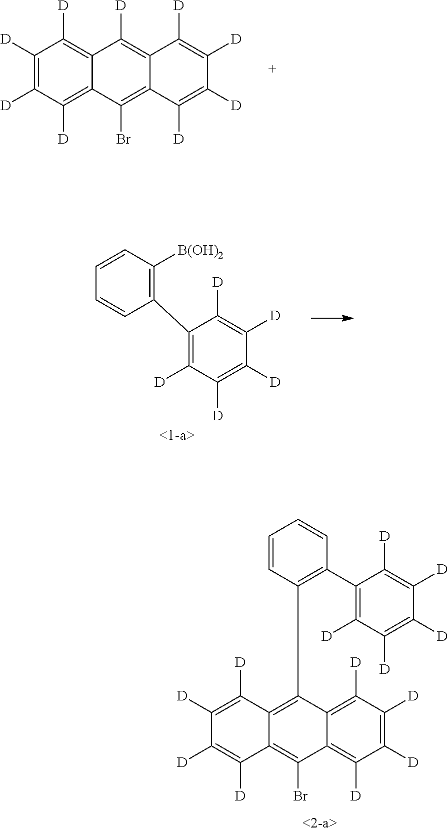 [SMILES: [2H]c1c([2H])c([2H])c2c(Br)c3c([2H])c([2H])c([2H])c([2H])c3c([2H])c2c1[2H] ; [2H]c1c([2H])c([2H])c(-c2ccccc2B(O)O)c([2H])c1[2H] ; [2H]c1c([2H])c([2H])c(-c2ccccc2-c2c3c([2H])c([2H])c([2H])c([2H])c3c(Br)c3c([2H])c([2H])c([2H])c([2H])c23)c([2H])c1[2H]]

The same procedure as in Synthesis Example 1-2 was carried out, with the exception of using 9-bromoanthracene-1,2,3,4,5,6,7,8,10-d instead of 9-bromoanthracene, to afford <2-a>. (yield 79%)

### Synthesis Example 2-2: Synthesis of 2-b

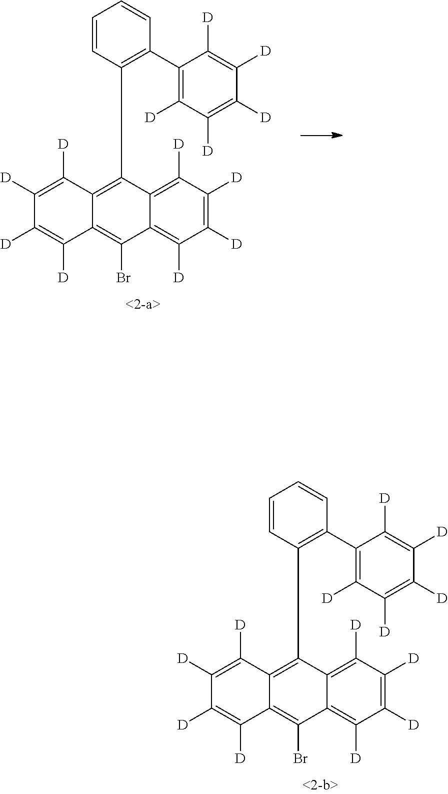 [SMILES: [2H]c1c([2H])c([2H])c(-c2ccccc2-c2c3c([2H])c([2H])c([2H])c([2H])c3c(Br)c3c([2H])c([2H])c([2H])c([2H])c23)c([2H])c1[2H] ; [2H]c1c([2H])c([2H])c(-c2ccccc2-c2c3c([2H])c([2H])c([2H])c([2H])c3c(Br)c3c([2H])c([2H])c([2H])c([2H])c23)c([2H])c1[2H]]

The same procedure as in Synthesis Example 1-3 was carried out, with the exception of using <2-a> instead of <1-b> to afford <2-b>. (yield 76.9%)

### Synthesis Example 2-3: Synthesis of [Compound 4]

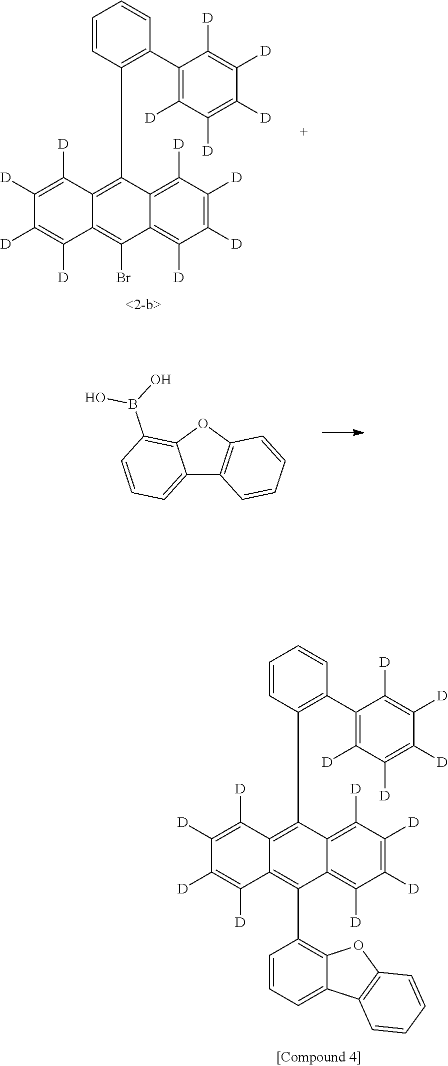 [SMILES: [2H]c1c([2H])c([2H])c(-c2ccccc2-c2c3c([2H])c([2H])c([2H])c([2H])c3c(Br)c3c([2H])c([2H])c([2H])c([2H])c23)c([2H])c1[2H] ; OB(O)c1cccc2c1oc1ccccc12 ; [2H]c1c([2H])c([2H])c(-c2ccccc2-c2c3c([2H])c([2H])c([2H])c([2H])c3c(-c3cccc4c3oc3ccccc34)c3c([2H])c([2H])c([2H])c([2H])c23)c([2H])c1[2H]]

The same procedure as in Synthesis Example 1-4 was carried out, with the exception of using <2-b> and dibenzofuran-4-yl boronic acid, instead of <1-c> and dibenzofuran-2-yl boronic acid, respectively, to afford [Compound 4]. (yield 50%)

MS (MALDI-TOF): m/z 509.26 [M⁺]

### Synthesis Example 3. Synthesis of [Compound 7]

### Synthesis Example 3-1: Synthesis of [Compound 7]

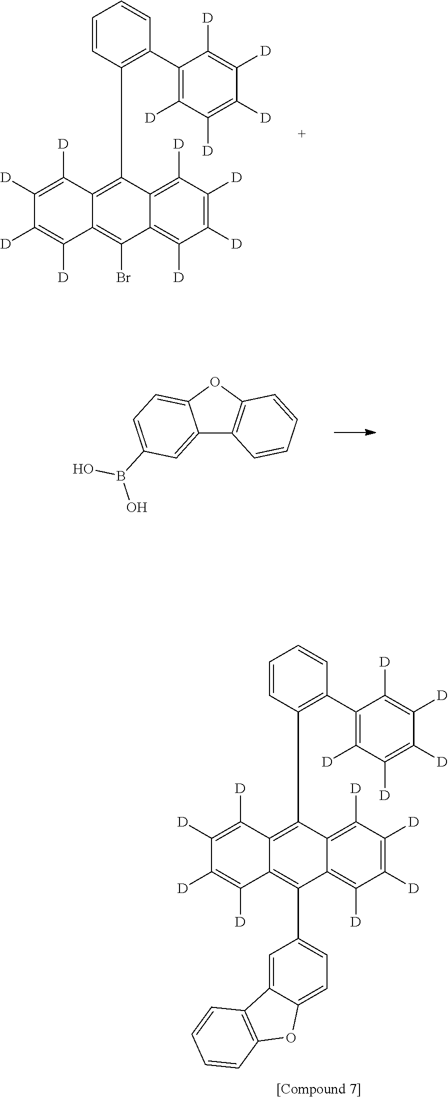 [SMILES: [2H]c1c([2H])c([2H])c(-c2ccccc2-c2c3c([2H])c([2H])c([2H])c([2H])c3c(Br)c3c([2H])c([2H])c([2H])c([2H])c23)c([2H])c1[2H] ; OB(O)c1ccc2oc3ccccc3c2c1 ; [2H]c1c([2H])c([2H])c(-c2ccccc2-c2c3c([2H])c([2H])c([2H])c([2H])c3c(-c3ccc4oc5ccccc5c4c3)c3c([2H])c([2H])c([2H])c([2H])c23)c([2H])c1[2H]]

The same procedure as in Synthesis Example 2-3 was carried out, with the exception of using dibenzofuran-2-yl boronic acid, instead of dibenzofuran-4-yl boronic acid, to afford [Compound 7]. (yield 52%)

MS (MALDI-TOF): m/z 509.26 [M⁺]

### Synthesis Example 4. Synthesis of [Compound 14]

### Synthesis Example 4-1: Synthesis of 4-a

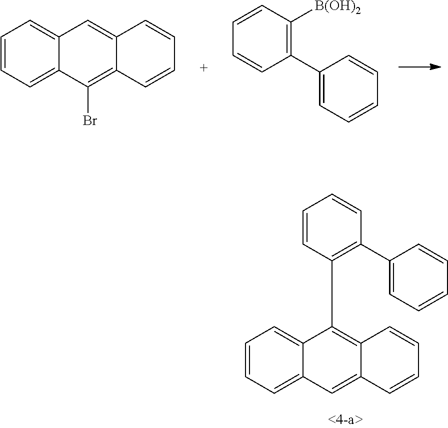

The same procedure as in Synthesis Example 1-2 was carried out, with the exception of using 2-biphenyl boronic acid, instead of <1-a>, to afford <4-a>. (yield 82%)

### Synthesis Example 4-2: Synthesis of 4-b

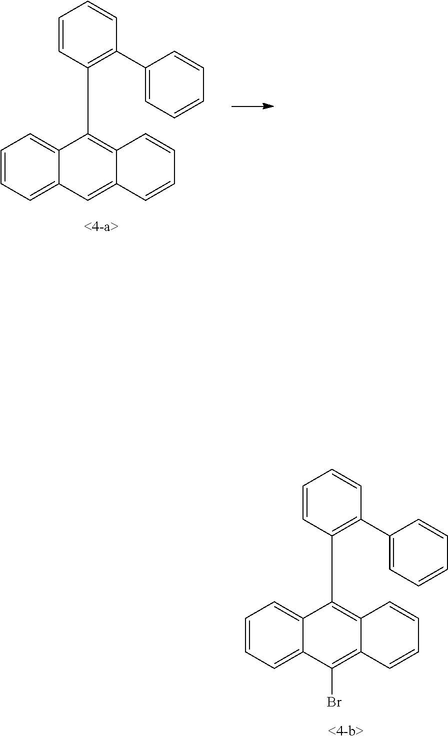

The same procedure as in Synthesis Example 1-3 was carried out, with the exception of using <4-a>, instead of <1-b>, to afford <4-b>. (yield 81.2%)

### Synthesis Example 4-3: Synthesis of 4-c

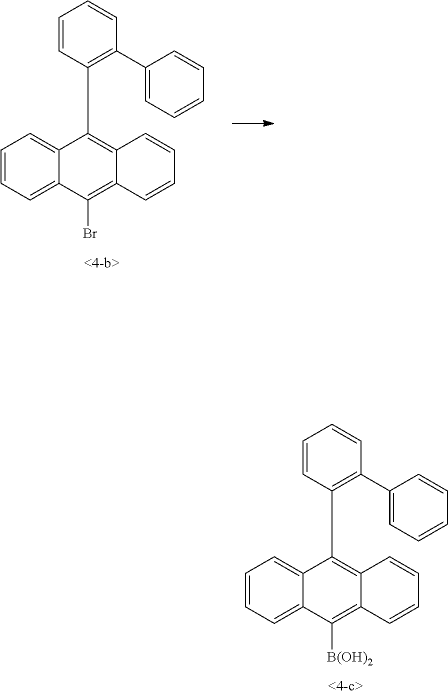 [SMILES: Brc1c2ccccc2c(-c2ccccc2-c2ccccc2)c2ccccc12 ; OB(O)c1c2ccccc2c(-c2ccccc2-c2ccccc2)c2ccccc12]

In a 1-L round-bottom flask, a solution of <4-b> (35 g) in tetrahydrofuran (350 mL) was cooled to −78° C. under a nitrogen atmosphere, and n-butyl lithium (1.6 M, 60 mL) was dropwise added. The mixture was stirred for 1 hour, added with trimethyl borate (10.8 g), and then stirred again at room temperature. After completion of the reaction, the reaction mixture was acidified with 2 N HCl and the organic layer was separated and concentrated. The concentrate was recrystallized in tetrahydrofuran to afford <4-c>. (25 g, 78%)

### Synthesis Example 4-4: Synthesis of 4-d

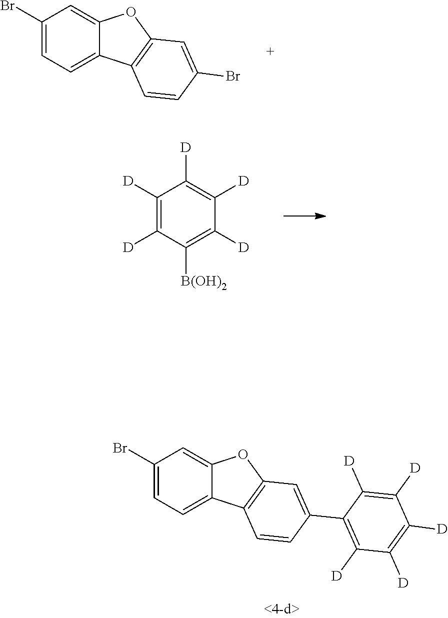 [SMILES: Brc1ccc2c(c1)oc1cc(Br)ccc12 ; [2H]c1c([2H])c([2H])c(B(O)O)c([2H])c1[2H] ; [2H]c1c([2H])c([2H])c(-c2ccc3c(c2)oc2cc(Br)ccc23)c([2H])c1[2H]]

In a 1-L round-bottom flask, 3,6-dibromodibenzofuran (30 g), phenyl-d5-boronic acid (13.4 g), potassium carbonate (60 g), tetrakis(triphenylphosphine)palladium (2.1 g), toluene (360 mL), tetrahydrofuran (180 mL), and distilled water (120 mL) were stirred together overnight at an elevated temperature under reflux. After completion of the reaction was confirmed by thin layer chromatography, the temperature was decreased to room temperature. Following extraction with ethyl acetate and distilled water, the organic layer was concentrated at a reduced pressure. The concentrate was isolated and purified by column chromatography, followed by recrystallization in dichloromethane and acetone to afford <4-d>. (19 g, 63%)

### Synthesis Example 4-5: Synthesis of [Compound 14]

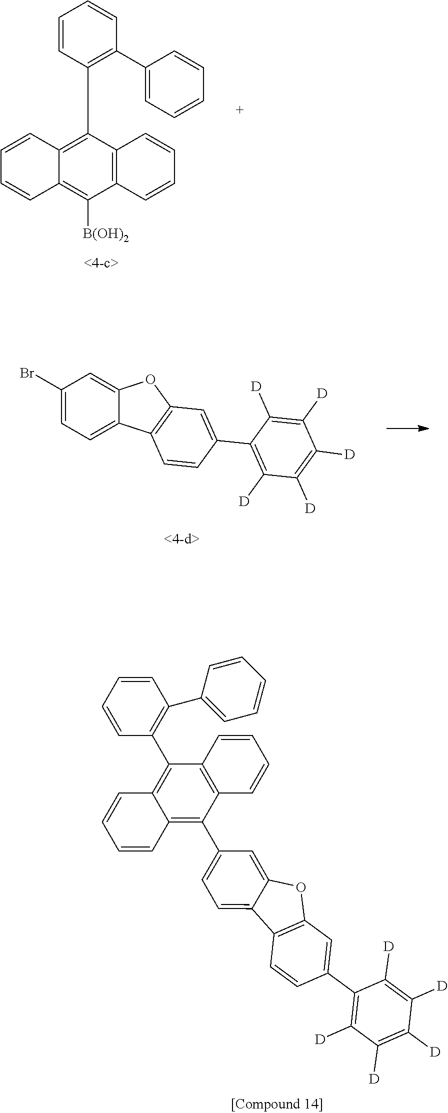 [SMILES: OB(O)c1c2ccccc2c(-c2ccccc2-c2ccccc2)c2ccccc12 ; [2H]c1c([2H])c([2H])c(-c2ccc3c(c2)oc2cc(Br)ccc23)c([2H])c1[2H] ; [2H]c1c([2H])c([2H])c(-c2ccc3c(c2)oc2cc(-c4c5ccccc5c(-c5ccccc5-c5ccccc5)c5ccccc45)ccc23)c([2H])c1[2H]]

The same procedure as in Synthesis Example 1-4 was carried out, with the exception of using <4-d> and <4-c>, instead of <1-c> and dibenzofuran-2-yl boronic acid, respectively, to afford [Compound 14]. (yield 48%)

MS (MALDI-TOF): m/z 577.25 [M⁺]

### Synthesis Example 5. Synthesis of [Compound 17]

### Synthesis Example 5-1: Synthesis of <5-a>

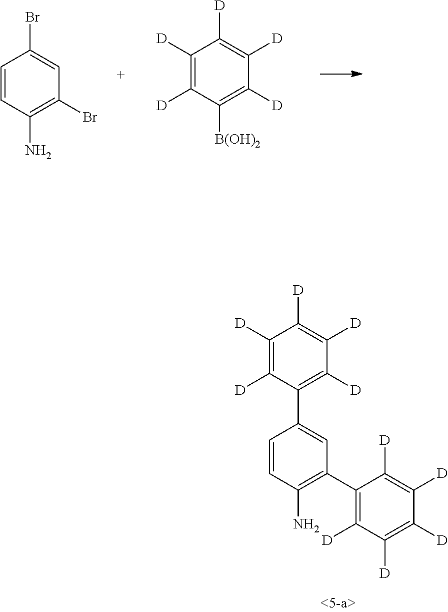 [SMILES: Nc1ccc(Br)cc1Br ; [2H]c1c([2H])c([2H])c(B(O)O)c([2H])c1[2H] ; [2H]c1c([2H])c([2H])c(-c2ccc(N)c(-c3c([2H])c([2H])c([2H])c([2H])c3[2H])c2)c([2H])c1[2H]]

In a 1-L round-bottom flask, 2,4-dibromoaniline (54 g), phenyl-d5-boronic acid (65.6 g), potassium carbonate (89.2 g), tetrakis (triphenylphosphine)palladium (9.9 g), toluene (216 mL), 1,4-dioxane (216 mL), and distilled water (86 mL) were stirred together overnight at an elevated temperature under reflux. After completion of the reaction was confirmed by thin layer chromatography, the temperature was decreased to room temperature. Extraction with ethyl acetate and distilled water was followed by concentrating the organic layer in a vacuum. The concentrate was isolated and purified by column chromatography to afford <5-a>. (26.5 g, 48.2%) Synthesis Example 5-2: Synthesis of <5-b>

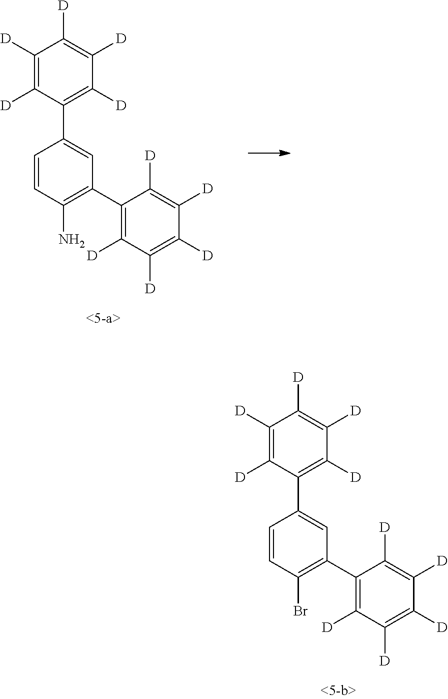 [SMILES: [2H]c1c([2H])c([2H])c(-c2ccc(N)c(-c3c([2H])c([2H])c([2H])c([2H])c3[2H])c2)c([2H])c1[2H] ; [2H]c1c([2H])c([2H])c(-c2ccc(Br)c(-c3c([2H])c([2H])c([2H])c([2H])c3[2H])c2)c([2H])c1[2H]]

In a 3-L round-bottom flask, a solution of <5-a> (26.5 g) and p-toluene sulfonate monohydrate (53.6 g) in acetonitrile (477 mL) was stirred at room temperature for 30 minutes. A solution of sodium nitrite (14.3 g) in distilled water (100 mL) were dropwise added to the reaction solution. After being stirred at room temperature for 2 hours, the mixture was added at once with copper (I) bromide (37.2 g) and stirred. After completion of the reaction was confirmed by thin layer chromatography, distilled water (200 mL) was added and stirred, followed by extraction with dichloromethane. The organic layer was separated and concentrated in a vacuum. Isolation and purification by column chromatography afforded <5-b>. (24 g, 72.4%)

### Synthesis Example 5-3: Synthesis of <5-c>

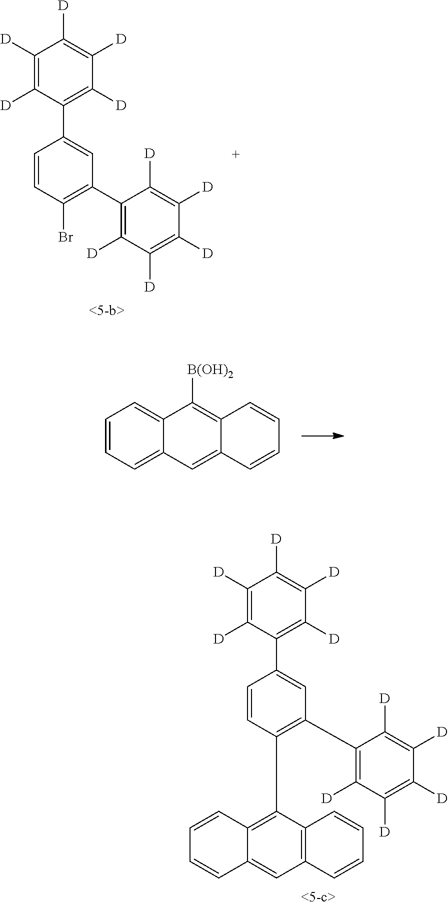 [SMILES: [2H]c1c([2H])c([2H])c(-c2ccc(Br)c(-c3c([2H])c([2H])c([2H])c([2H])c3[2H])c2)c([2H])c1[2H] ; OB(O)c1c2ccccc2cc2ccccc12 ; [2H]c1c([2H])c([2H])c(-c2ccc(-c3c4ccccc4cc4ccccc34)c(-c3c([2H])c([2H])c([2H])c([2H])c3[2H])c2)c([2H])c1[2H]]

The same procedure as in Synthesis Example 1-2 was carried out, with the exception of using <5-b> and 9-anthracene boronic acid, instead of 9-bromoanthracene and <1-a>, respectively, to afford <5-c>. (yield 78.2%)

### Synthesis Example 5-4<5-d>

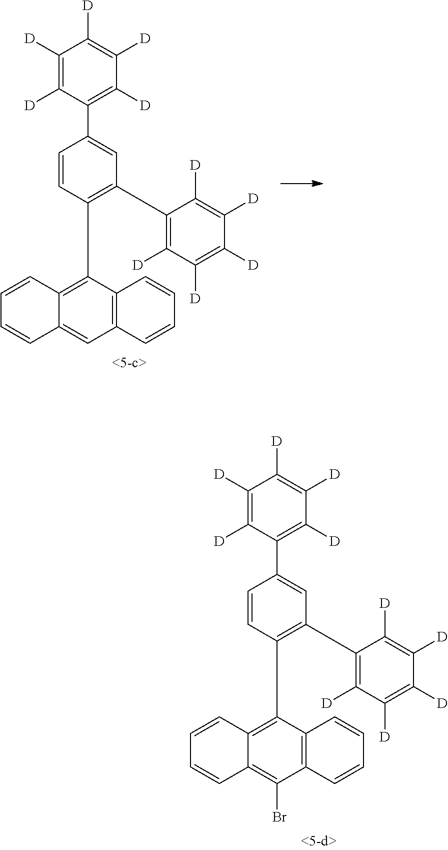 [SMILES: [2H]c1c([2H])c([2H])c(-c2ccc(-c3c4ccccc4cc4ccccc34)c(-c3c([2H])c([2H])c([2H])c([2H])c3[2H])c2)c([2H])c1[2H] ; [2H]c1c([2H])c([2H])c(-c2ccc(-c3c4ccccc4c(Br)c4ccccc34)c(-c3c([2H])c([2H])c([2H])c([2H])c3[2H])c2)c([2H])c1[2H]]

The same procedure as in Synthesis Example 1-3 was carried out, with the exception of using <5-c>, instead of <1-b>, to afford <5-d>. (yield 79.2%)

### Synthesis Example 5-5: Synthesis of [Compound 17]

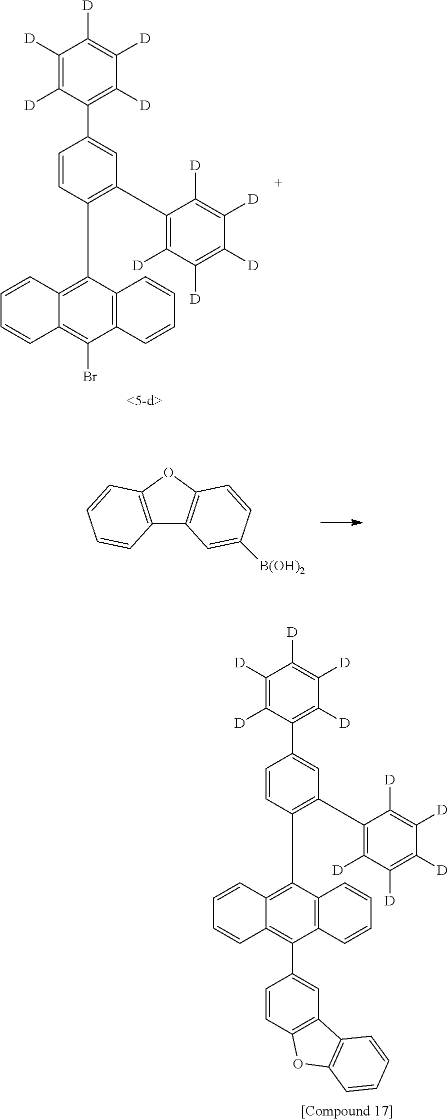 [SMILES: [2H]c1c([2H])c([2H])c(-c2ccc(-c3c4ccccc4c(Br)c4ccccc34)c(-c3c([2H])c([2H])c([2H])c([2H])c3[2H])c2)c([2H])c1[2H] ; OB(O)c1ccc2oc3ccccc3c2c1 ; [2H]c1c([2H])c([2H])c(-c2ccc(-c3c4ccccc4c(-c4ccc5oc6ccccc6c5c4)c4ccccc34)c(-c3c([2H])c([2H])c([2H])c([2H])c3[2H])c2)c([2H])c1[2H]]

The same procedure as in Synthesis Example 1-4 was carried out, with the exception of using <5-d>, instead of <1-c>, to afford [Compound 17]. (yield 55%)

MS (MALDI-TOF): m/z 582.28 [M⁺]

### Synthesis Example 6. Synthesis of [Compound 21]

### Synthesis Example 6-1: Synthesis of 6-a

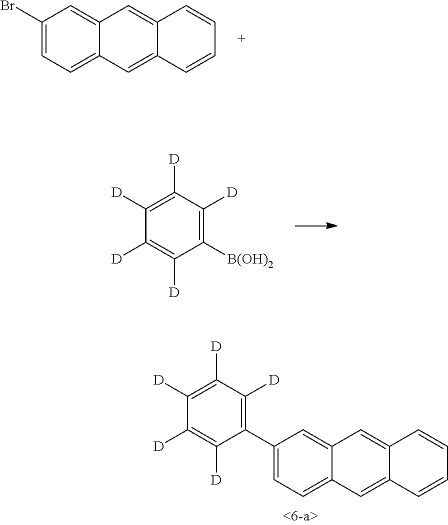 [SMILES: Brc1ccc2cc3ccccc3cc2c1 ; [2H]c1c([2H])c([2H])c(B(O)O)c([2H])c1[2H] ; [2H]c1c([2H])c([2H])c(-c2ccc3cc4ccccc4cc3c2)c([2H])c1[2H]]

The same procedure as in Synthesis Example 1-2 was carried out, with the exception of using 2-bromoanthracene and phenyl-2′,3′,4′,5′,6′-d5 boronic acid, instead of 9-bromoanthracene and <1-a>, respectively, to afford <6-a>. (yield 79%)

### Synthesis Example 6-2: Synthesis of 6-b

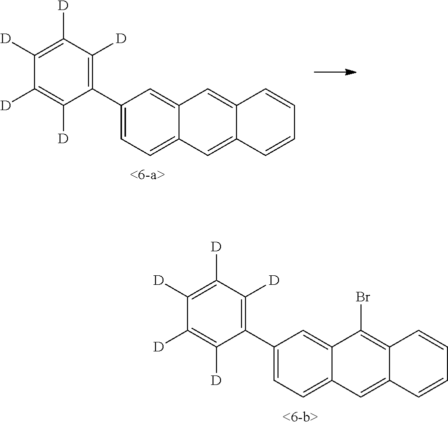 [SMILES: [2H]c1c([2H])c([2H])c(-c2ccc3cc4ccccc4cc3c2)c([2H])c1[2H] ; [2H]c1c([2H])c([2H])c(-c2ccc3cc4ccccc4c(Br)c3c2)c([2H])c1[2H]]

The same procedure as in Synthesis Example 1-3 was carried out, with the exception of using <6-a>, instead of <1-b>, to afford <6-b>. (yield 81.4%)

### Synthesis Example 6-3: Synthesis of 6-c

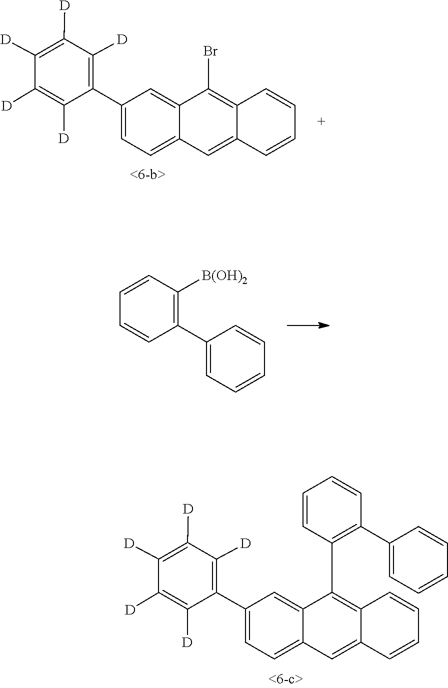 [SMILES: [2H]c1c([2H])c([2H])c(-c2ccc3cc4ccccc4c(Br)c3c2)c([2H])c1[2H] ; OB(O)c1ccccc1-c1ccccc1 ; [2H]c1c([2H])c([2H])c(-c2ccc3cc4ccccc4c(-c4ccccc4-c4ccccc4)c3c2)c([2H])c1[2H]]

The same procedure as in Synthesis Example 4-1 was carried out, with the exception of using <6-b>, instead of 9-bromoanthracene, to afford <6-c>. (yield 64%)

### Synthesis Example 6-4: Synthesis of 6-d

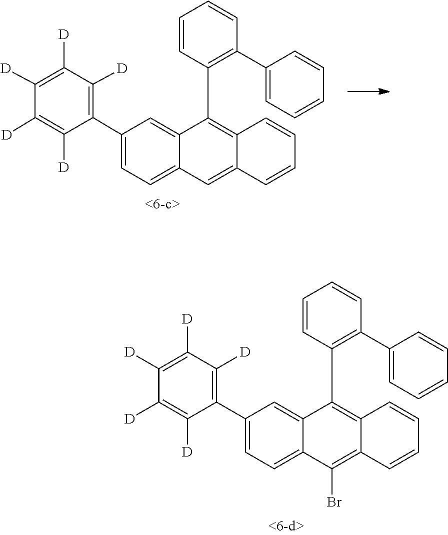 [SMILES: [2H]c1c([2H])c([2H])c(-c2ccc3cc4ccccc4c(-c4ccccc4-c4ccccc4)c3c2)c([2H])c1[2H] ; [2H]c1c([2H])c([2H])c(-c2ccc3c(Br)c4ccccc4c(-c4ccccc4-c4ccccc4)c3c2)c([2H])c1[2H]]

The same procedure as in Synthesis Example 1-3 was carried out, with the exception of using <6-c>, instead of <1-b>, to afford <6-d>. (yield 75.3%)

### Synthesis Example 6-5: Synthesis of [Compound 21]

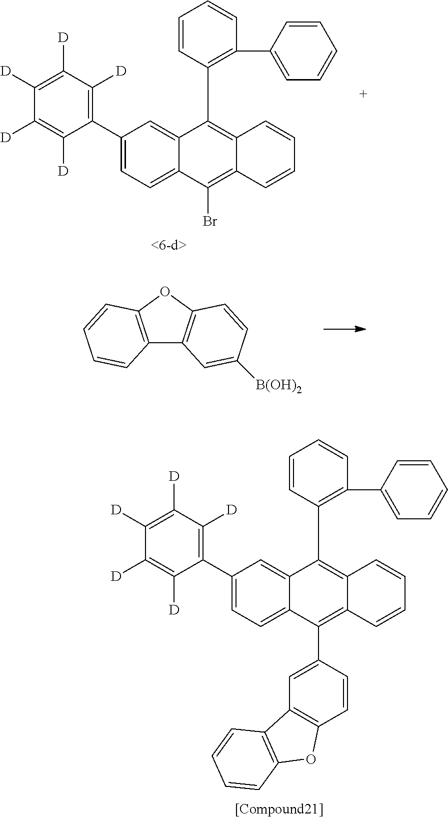 [SMILES: [2H]c1c([2H])c([2H])c(-c2ccc3c(Br)c4ccccc4c(-c4ccccc4-c4ccccc4)c3c2)c([2H])c1[2H] ; OB(O)c1ccc2oc3ccccc3c2c1 ; [2H]c1c([2H])c([2H])c(-c2ccc3c(-c4ccc5oc6ccccc6c5c4)c4ccccc4c(-c4ccccc4-c4ccccc4)c3c2)c([2H])c1[2H]]

The same procedure as in Synthesis Example 1-4 was carried out, with the exception of using <6-d>, instead of <1-c>, to afford [Compound 21]. (yield 61.2%)

MS (MALDI-TOF): m/z 577.25 [M⁺]

### Synthesis Example 7. Synthesis of [Compound 33]

### Synthesis Example 7-1: Synthesis of 7-a

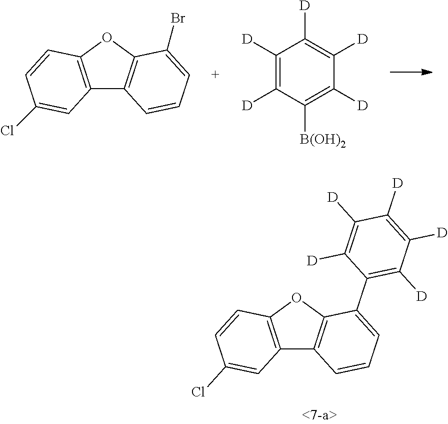 [SMILES: Clc1ccc2oc3c(Br)cccc3c2c1 ; [2H]c1c([2H])c([2H])c(B(O)O)c([2H])c1[2H] ; [2H]c1c([2H])c([2H])c(-c2cccc3c2oc2ccc(Cl)cc23)c([2H])c1[2H]]

The same procedure as in Synthesis Example 4-4 was carried out, with the exception of using 2-chloro-5-bromodibenzofuran, instead of 3,6-dibromodibenzofuran, to afford <7-a>. (yield 70.5%)

### Synthesis Example 7-2: Synthesis of 7-b

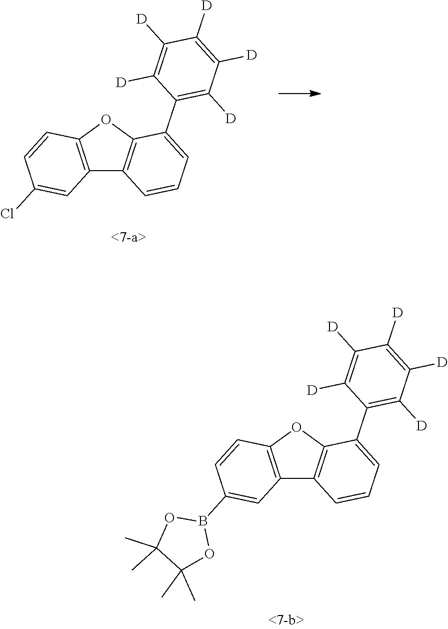 [SMILES: [2H]c1c([2H])c([2H])c(-c2cccc3c2oc2ccc(Cl)cc23)c([2H])c1[2H] ; [2H]c1c([2H])c([2H])c(-c2cccc3c2oc2ccc(B4OC(C)(C)C(C)(C)O4)cc23)c([2H])c1[2H]]

In a 500-mL round-bottom flask, <7-a> (23.1 g), bis(pinacolato)diboron (26.9 g), 1,1-bis(diphenylphosphino)ferrocene dichloropalladium (2 g), potassium acetate (24 g), diphenylphosphinoferrocene (0.5 g), and toluene (230 mL) were together stirred overnight under reflux. After completion of the reaction was confirmed by thin layer chromatography, the reaction mixture was filtered through a celite pad. The filtrate was isolated and purified by column chromatography and recrystallized in dichloromethane and heptane to afford <7-b>. (23.6 g, 77.3%)

### Synthesis Example 7-3: Synthesis of [Compound 33]

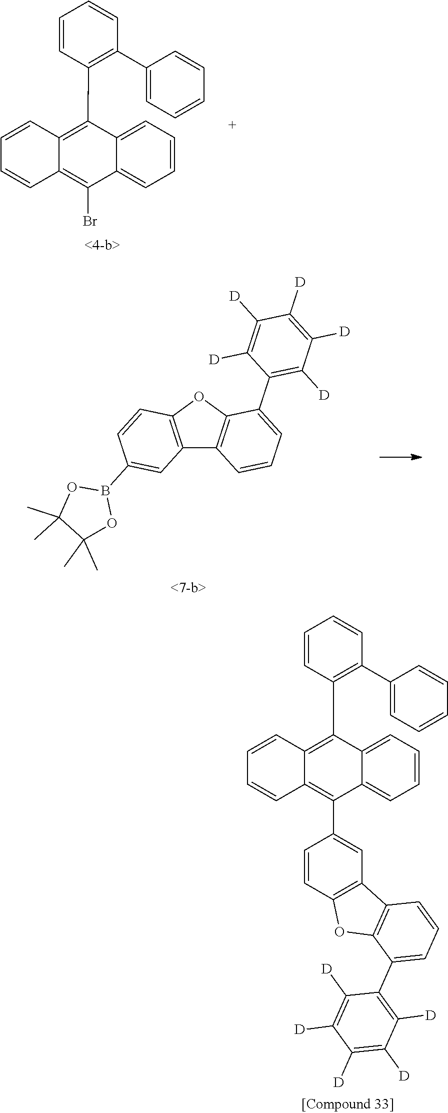 [SMILES: Brc1c2ccccc2c(-c2ccccc2-c2ccccc2)c2ccccc12 ; [2H]c1c([2H])c([2H])c(-c2cccc3c2oc2ccc(B4OC(C)(C)C(C)(C)O4)cc23)c([2H])c1[2H] ; [2H]c1c([2H])c([2H])c(-c2cccc3c2oc2ccc(-c4c5ccccc5c(-c5ccccc5-c5ccccc5)c5ccccc45)cc23)c([2H])c1[2H]]

The same procedure as in Synthesis Example 2-3 was carried out, with the exception of using <4-b> and <7-b>, instead of <2-b> and dibenzofuran-4-yl boronic acid, to afford [Compound 33]. (yield 51.2%)

MS (MALDI-TOF): m/z 577.25 [M⁺]

### Synthesis Example 8. Synthesis of [Compound 3]

### Synthesis Example 8-1: Synthesis of [Compound 3]

The same procedure as in Synthesis Example 1-4 was carried out, with the exception of using <4-b>, instead of <1-c>, to afford [Compound 3]. (yield 43%)

MS (MALDI-TOF): m/z 496.18 [M⁺]

### Example 1: Fabrication of Organic Light-Emitting Diode

An ITO glass substrate was patterned to have a translucent area of 2 mm×2 mm and cleansed. The ITO glass was mounted in a vacuum chamber that was then set to have a base pressure of 1×10⁻⁷ torr. On the ITO glass substrate, a film for a hole injection layer was formed of a mixture of [HT] and 5 wt % of [Acceptor-1](50 Å). Subsequently, a film for a hole transport layer was formed of [HT](600 Å). Then, a light-emitting layer (200 Å) was formed of a combination of the host compound according to the present disclosure and the dopant compound [BD](3 wt %), below. Then, a mixture of 1:1 of [Chemical Formula E-1] and [Chemical Formula E-2] was deposited to form an electron transport layer (250 Å) on which an electron injection layer of [Chemical Formula E-2](10 Å) was formed and then covered with an Al layer (1000 Å) for a cathode. The organic light-emitting diode thus fabricated was measured at 10 mA/cm² for luminescence properties.

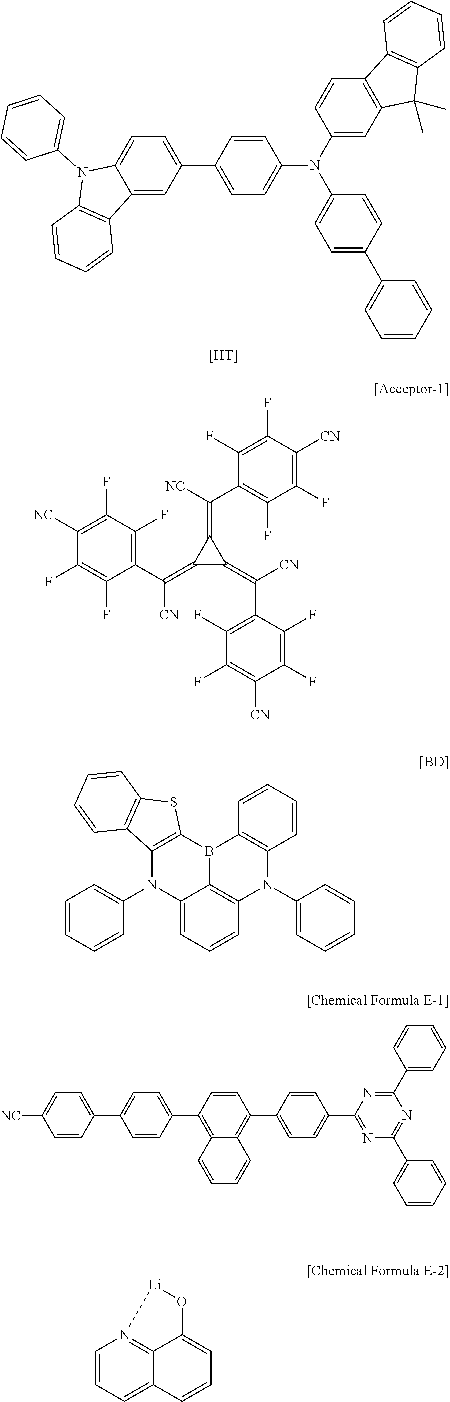

### Comparative Examples 1 AND 2: Fabrication of Organic Light-Emitting Diodes

Organic light emitting diodes were fabricated in the same manner as in Example 1, with the exception of using [BH 1] and [BH 2] compounds instead of the host compound used in Example 1. The luminescence characteristics of the organic light-emitting diodes thus obtained were measured at 10 mA/cm², and the measurements are summarized in Table 1, below.

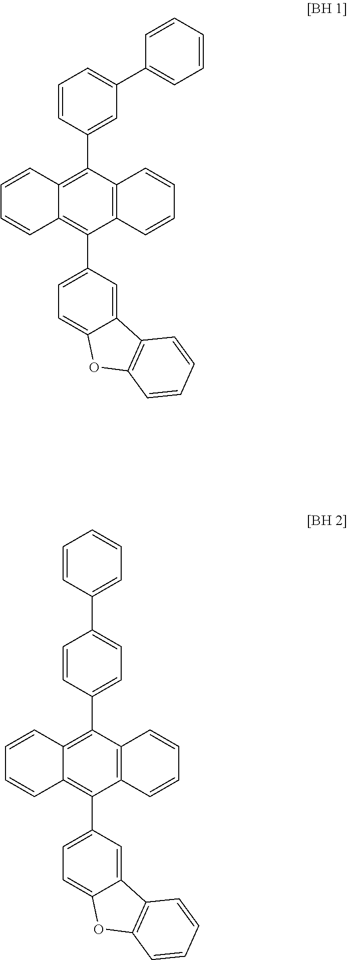 [SMILES: c1ccc(-c2cccc(-c3c4ccccc4c(-c4ccc5oc6ccccc6c5c4)c4ccccc34)c2)cc1 ; c1ccc(-c2ccc(-c3c4ccccc4c(-c4ccc5oc6ccccc6c5c4)c4ccccc34)cc2)cc1]

TABLE 1

| | Host | V | EQE | LT₉₇ |
|---|---|---|---|---|
| Example 1 | Compound 13 | 3.52 | 12.2 | 200 |
| Comparative | [BH 1] | 3.65 | 12.0 | 80 |
| Example 1 | | | | |
| Comparative | [BH 2] | 3.55 | 11.8 | 30 |
| Example 2 | | | | |

### Examples 2 TO 8: Fabrication of Organic Light-Emitting Diodes

An ITO glass substrate was patterned to have a translucent area of 2 mm×2 mm and cleansed. The ITO glass was mounted in a vacuum chamber that was then set to have a base pressure of 1×10⁻⁷ torr. On the ITO glass substrate, a film was formed of the electron acceptors [Acceptor-1] and [HT] at a deposition ratio of [Acceptor-1]:[HT]=2:98 (100 Å). A film was formed of [HT] for a hole transport layer (550 Å) and then of [Chemical Formula G] for an electron barrier layer (50 Å). A light-emitting layer (200 Å) was formed of a combination of the host compound according to the present disclosure and the dopant compound [BD 1](1 wt %), below, followed by depositing [Chemical Formula H] to form a film for a hole barrier layer (50 Å). Thereafter, films were formed of a combination of 1:1 of [Chemical Formula E-2] and [Chemical Formula E-3] for an electron transport layer (250 Å), of [Chemical Formula E-2] for an electron injection layer (10 Å), and of Al for a cathode (1000 Å) in that order to fabricate an organic light-emitting diode. The organic light-emitting diode thus obtained were measured at 10 mA/cm² for luminescence properties.

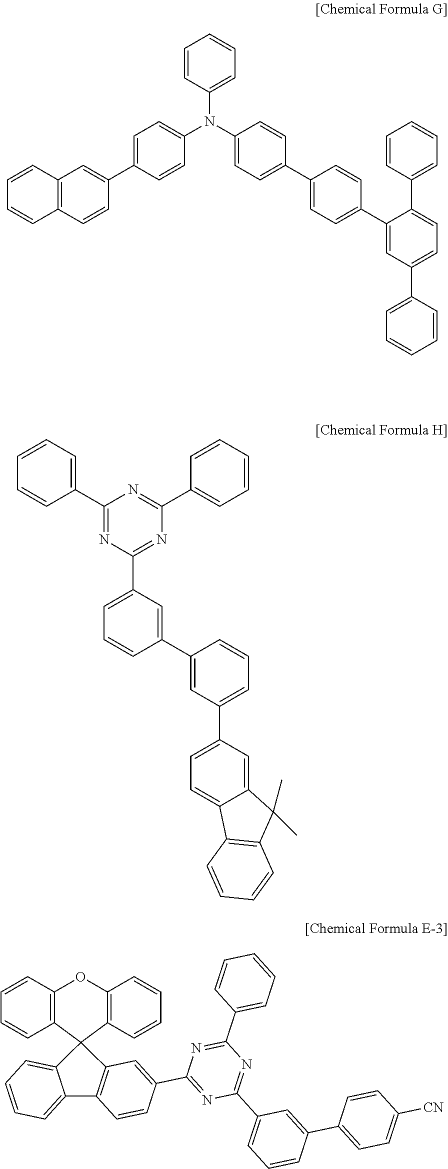 [SMILES: c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21 ; N#Cc1ccc(-c2cccc(-c3nc(-c4ccccc4)nc(-c4ccc5c(c4)C4(c6ccccc6Oc6ccccc64)c4ccccc4-5)n3)c2)cc1]

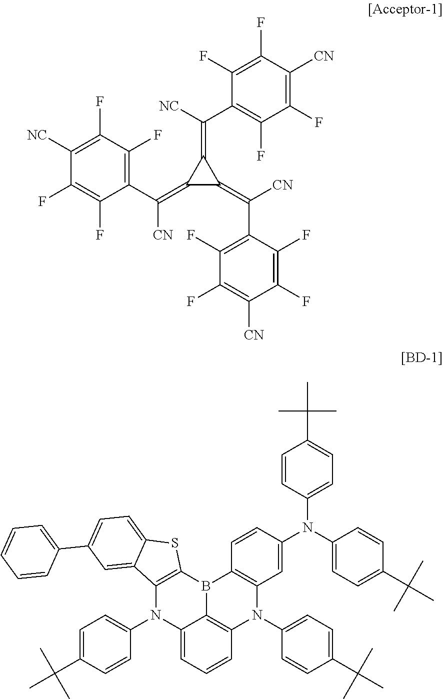 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; CC(C)(C)c1ccc(N(c2ccc(C(C)(C)C)cc2)c2ccc3c(c2)N(c2ccc(C(C)(C)C)cc2)c2cccc4c2B3c2sc3ccc(-c5ccccc5)cc3c2N4c2ccc(C(C)(C)C)cc2)cc1]

### Comparative Examples 3 TO 4: Fabrication of Organic Light-Emitting Diodes

Organic light emitting diodes were fabricated in the same manner as in Examples 2 to, with the exception of using [BH 1] and [BH 2] compounds instead of the host compound used in the Examples. The luminescence characteristics of the organic light-emitting diodes thus obtained were measured at 10 mA/cm².

TABLE 2

| | Host | LT₉₇ |
|---|---|---|
| Example 2 | Compound 4 | 120 |
| Example 3 | Compound 7 | 260 |
| Example 4 | Compound 13 | 230 |
| Example 5 | Compound 14 | 150 |
| Example 6 | Compound 17 | 180 |
| Example 7 | Compound 21 | 126 |
| Example 8 | Compound 33 | 137 |
| Comparative | [BH 1] | 100 |
| Example 3 | | |
| Comparative | [BH 2] | 60 |
| Example 4 | | |

As is understood from data of Tables 1 and 2, the compounds according to the present disclosure allowed longer lifespans, compared to anthracene compounds which are the same structure as Chemical Formula A, but do not bear deuterium atoms or the substituents, thereby finding high applicability to organic light-emitting diodes.

What is claimed is:

1. An organic light-emitting diode comprising: a first electrode; a second electrode facing the first electrode; and an organic layer between the first electrode and the second electrode, wherein the organic layer includes a light emission layer containing a host and a dopant, the host comprising at least one of anthracene compounds represented by Chemical Formula A and the dopant comprising at least one of compounds represented by Chemical Formula B-1 or Chemical Formula B-2: 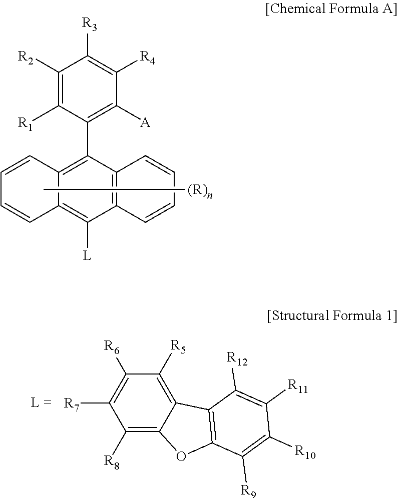
wherein,
A is any one selected from among a deuterium-substituted phenyl, a deuterium-substituted biphenyl, a deuterium-substituted terphenyl, a deuterium-substituted naphthyl, and a deuterium-substituted phenanthrenyl,
R₁ is a hydrogen atom or a deuterium atom,
R, and R₂ to R₁₂, which are same or different, are each independently any one selected from among a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted silyl of 0 to 30 carbon atoms, a substituted or unsubstituted aliphatic/aromatic composite ring of 3 to 50 carbon atoms, a cyano, a nitro, and a halogen, wherein a linkage can be made between adjacent two of the substituents R and R₂ to R₁₂ to form an additional mono- or polycyclic aliphatic or aromatic ring,
n is an integer of 1 to 8, wherein when n is 2 or greater, the R's are same or different,
one of R₅ to R₁₂ in Structural Formula 1 is a single bond to a carbon member of the anthracene moiety of Chemical Formula A, and 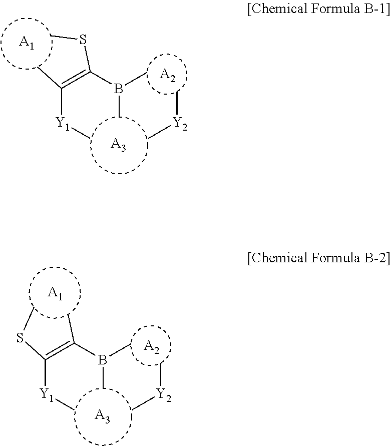
wherein,
A₁ to A₃, which are same or different, are each independently any one selected from among a substituted or unsubstituted aromatic hydrocarbon ring of 6 to 50 carbon atoms, a substituted or unsubstituted heteroaromatic ring of 2 to 50 carbon atoms, a substituted or unsubstituted aliphatic ring of 3 to 30 carbon atoms, and a substituted or unsubstituted aliphatic/aromatic composite ring of 3 to 30 carbon atoms, wherein a linkage can be formed between adjacent two of substituents on the rings A₁ to A₃ to form an additional mono- or polycyclic aliphatic or aromatic ring,
Y₁ and Y₂, which are same or different, are each independently any one selected from among NR₂₁, CR₂₂R₂₃, O, S and SiR₂₄R₂₅,
R₂₁ to R₂₅, which are same or different, are each independently any one selected from among a hydrogen atom, a deuterium atom, substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted silyl of 0 to 30 carbon atoms, a substituted or unsubstituted aliphatic/aromatic composite ring of 3 to 30 carbon atoms, a nitro, a cyano, and a halogen,
R₂₁ to R₂₅ can each be connected to at least one selected from among the rings A₁ to A₃ to form an additional mono- or polycyclic aliphatic or aromatic ring, and
a bond can be made between R₂₂ and R₂₃ and between R₂₄ and R₂₅ to form additional respective mono- or polycyclic aliphatic or aromatic rings,
wherein the anthracene compound represented by Chemical Formula A has a degree of deuteration of 20% or higher,
wherein the term “substituted” in the expression “substituted or unsubstituted” used for compounds of Chemical Formulas A, B-1, and B-2 means having at least one substituent selected from the group consisting of a deuterium atom, a cyano, a halogen, a nitro, an alkyl of 1 to 24 carbon atoms, an halogenated alkyl of 1 to 24 carbon atoms, a cycloalkyl of 3 to 30 carbon atoms, an aryl of 6 to 30 carbon atoms, an arylalkyl of 7 to 30 carbon atoms, an alkylaryl of 7 to 30 carbon atoms, a heteroaryl of 2 to 30 carbon atoms, a heteroarylalkyl of 2 to 30 carbon atoms, a silyl of 0 to 24 carbon atoms, and an aliphatic/aromatic composite ring of 3 to 30 carbon atoms.

2. The organic light emitting diode of claim 1, wherein at least one of the substituents R's in Chemical Formula A is a deuterium atom.

3. The organic light emitting diode of claim 1, wherein at least one of R₂ to R₄ in Chemical Formula A is selected from among a hydrogen atom, a deuterium atom, and a substituted or unsubstituted an aryl of 6 to 30 carbon atoms.

4. The organic light emitting diode of claim 1, wherein among the substituents R₅ to R₁₂ in Structural Formula 1 of Chemical Formula A, at least one of the substituents other than one that forms a single bond to the anthracene ring is an aryl group having 6 to 30 carbon atoms, the aryl group being optionally substituted with one or more deuterium atoms or unsubstituted.

5. The organic light emitting diode of claim 1, wherein the anthracene compound represented by Chemical Formula A has a degree of deuteration of 35% or higher.

6. The organic light emitting diode of claim 1, wherein the anthracene compound represented by Chemical Formula A is any one selected from among [Compound 1], [Compound 2], [Compound 4], [Compound 7], [Compound 9], [Compound 12], [Compound 13], [Compound 17], [Compound 18], [Compound 23], [Compound 24], [Compound 25], [Compound 30], [Compound 46], [Compound 47], [Compound 49], [Compound 51], [Compound 55], [Compound 56], [Compound 58] and [Compound 60]:

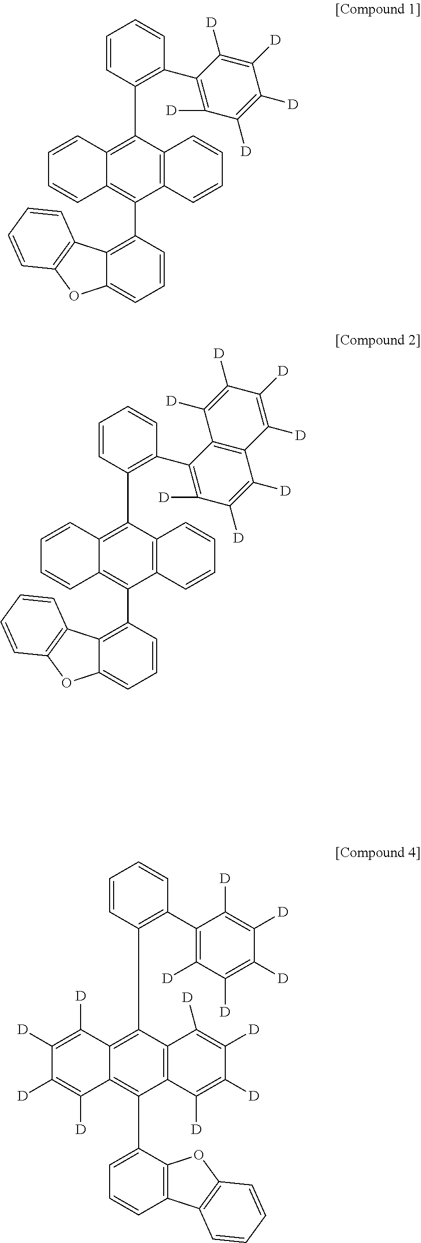 [SMILES: [2H]c1c([2H])c([2H])c(-c2ccccc2-c2c3ccccc3c(-c3cccc4oc5ccccc5c34)c3ccccc23)c([2H])c1[2H] ; [2H]c1c([2H])c([2H])c2c(-c3ccccc3-c3c4ccccc4c(-c4cccc5oc6ccccc6c45)c4ccccc34)c([2H])c([2H])c([2H])c2c1[2H] ; [2H]c1c([2H])c([2H])c(-c2ccccc2-c2c3c([2H])c([2H])c([2H])c([2H])c3c(-c3cccc4c3oc3ccccc34)c3c([2H])c([2H])c([2H])c([2H])c23)c([2H])c1[2H]]

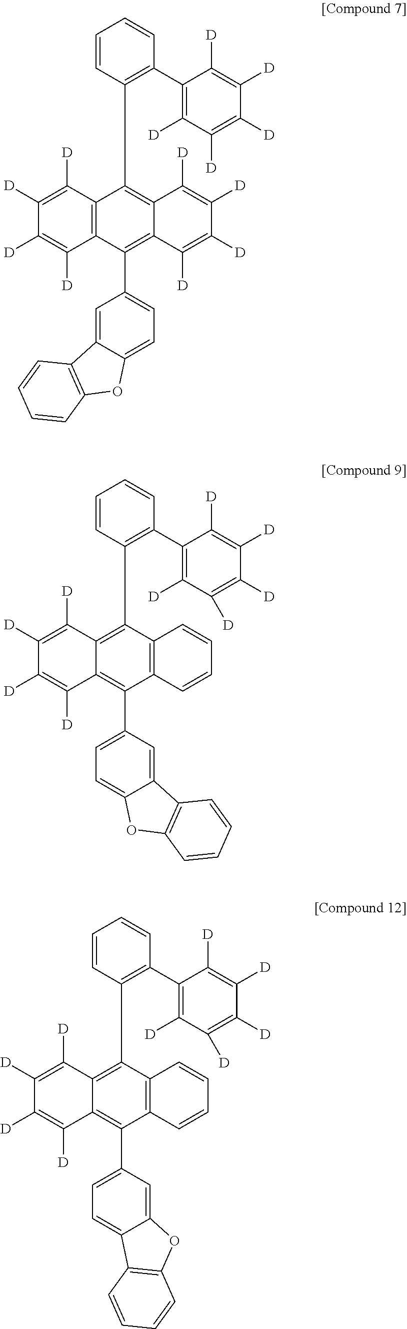 [SMILES: [2H]c1c([2H])c([2H])c(-c2ccccc2-c2c3c([2H])c([2H])c([2H])c([2H])c3c(-c3ccc4oc5ccccc5c4c3)c3c([2H])c([2H])c([2H])c([2H])c23)c([2H])c1[2H] ; [2H]c1c([2H])c([2H])c(-c2ccccc2-c2c3ccccc3c(-c3ccc4oc5ccccc5c4c3)c3c([2H])c([2H])c([2H])c([2H])c23)c([2H])c1[2H] ; [2H]c1c([2H])c([2H])c(-c2ccccc2-c2c3ccccc3c(-c3ccc4c(c3)oc3ccccc34)c3c([2H])c([2H])c([2H])c([2H])c23)c([2H])c1[2H]]

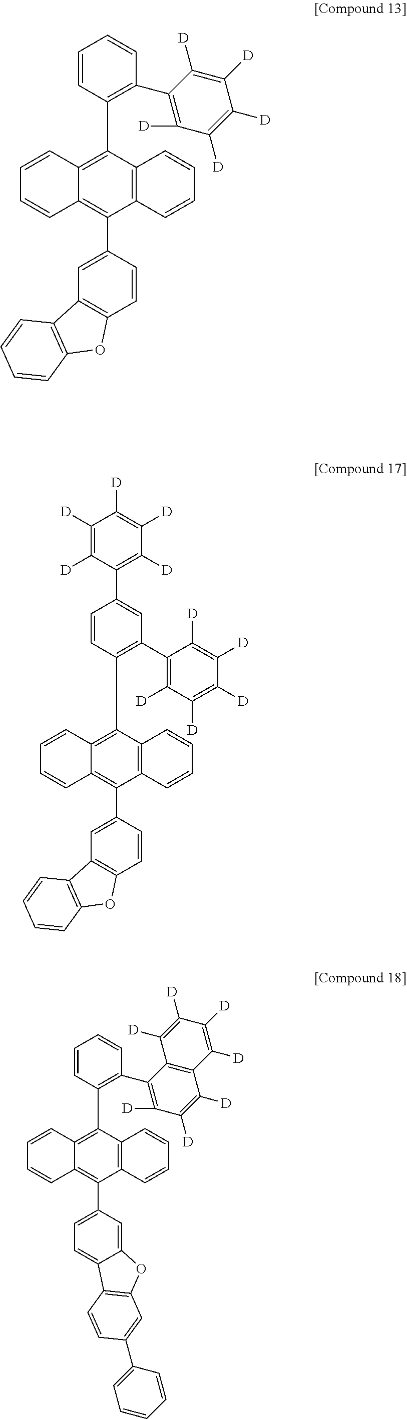 [SMILES: [2H]c1c([2H])c([2H])c(-c2ccccc2-c2c3ccccc3c(-c3ccc4oc5ccccc5c4c3)c3ccccc23)c([2H])c1[2H] ; [2H]c1c([2H])c([2H])c(-c2ccc(-c3c4ccccc4c(-c4ccc5oc6ccccc6c5c4)c4ccccc34)c(-c3c([2H])c([2H])c([2H])c([2H])c3[2H])c2)c([2H])c1[2H] ; [2H]c1c([2H])c([2H])c2c(-c3ccccc3-c3c4ccccc4c(-c4ccc5c(c4)oc4cc(-c6ccccc6)ccc45)c4ccccc34)c([2H])c([2H])c([2H])c2c1[2H]]

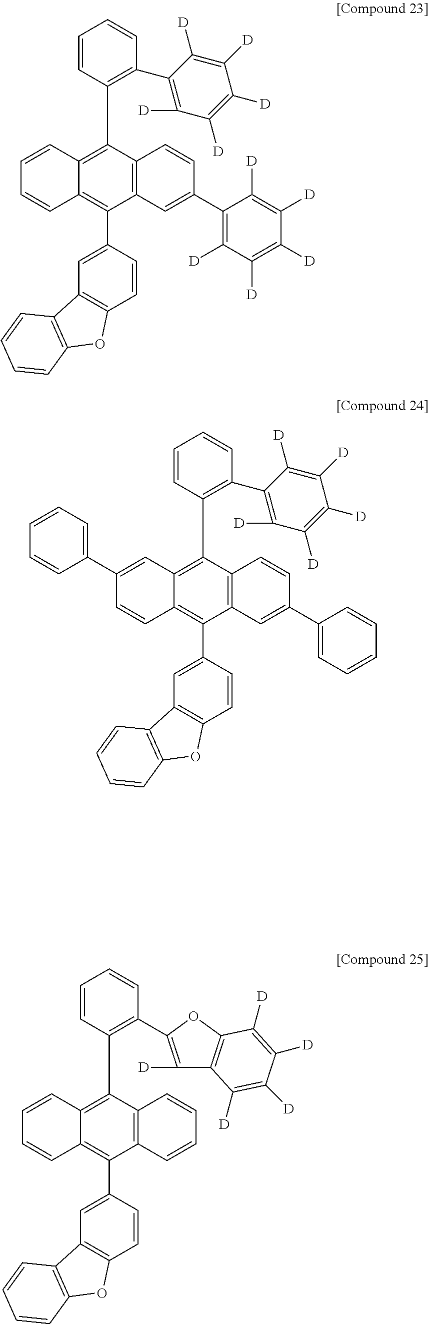 [SMILES: [2H]c1c([2H])c([2H])c(-c2ccc3c(-c4ccccc4-c4c([2H])c([2H])c([2H])c([2H])c4[2H])c4ccccc4c(-c4ccc5oc6ccccc6c5c4)c3c2)c([2H])c1[2H] ; [2H]c1c([2H])c([2H])c(-c2ccccc2-c2c3ccc(-c4ccccc4)cc3c(-c3ccc4oc5ccccc5c4c3)c3ccc(-c4ccccc4)cc23)c([2H])c1[2H] ; [2H]c1c([2H])c([2H])c2c([2H])c(-c3ccccc3-c3c4ccccc4c(-c4ccc5oc6ccccc6c5c4)c4ccccc34)oc2c1[2H]]

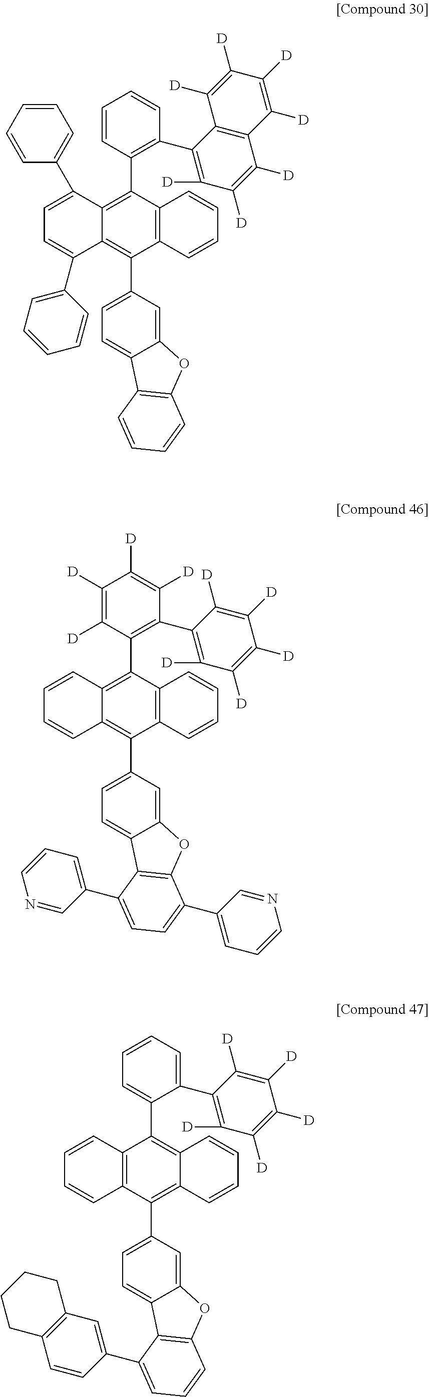 [SMILES: [2H]c1c([2H])c([2H])c2c(-c3ccccc3-c3c4ccccc4c(-c4ccc5c(c4)oc4ccccc45)c4c(-c5ccccc5)ccc(-c5ccccc5)c34)c([2H])c([2H])c([2H])c2c1[2H] ; [2H]c1c([2H])c([2H])c(-c2c([2H])c([2H])c([2H])c([2H])c2-c2c3ccccc3c(-c3ccc4c(c3)oc3c(-c5cccnc5)ccc(-c5cccnc5)c34)c3ccccc23)c([2H])c1[2H] ; [2H]c1c([2H])c([2H])c(-c2ccccc2-c2c3ccccc3c(-c3ccc4c(c3)oc3cccc(-c5ccc6c(c5)CCCC6)c34)c3ccccc23)c([2H])c1[2H]]

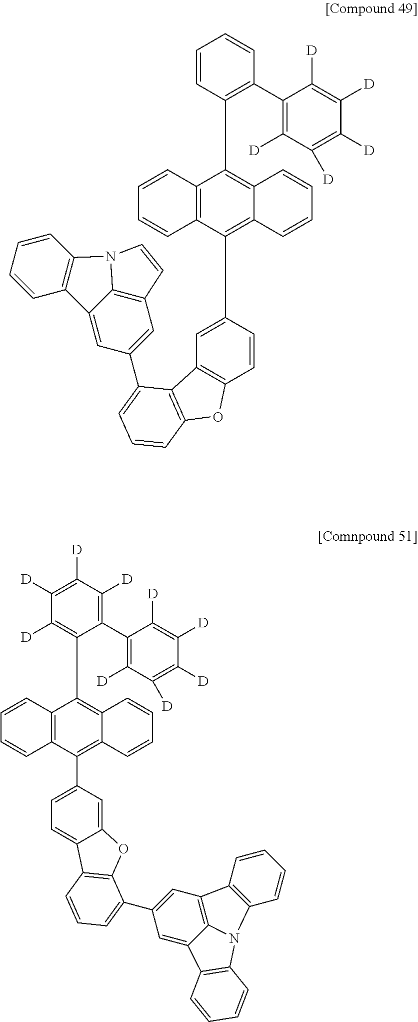 [SMILES: [2H]c1c([2H])c([2H])c(-c2ccccc2-c2c3ccccc3c(-c3ccc4oc5cccc(-c6cc7ccn8c9ccccc9c(c6)c78)c5c4c3)c3ccccc23)c([2H])c1[2H] ; [2H]c1c([2H])c([2H])c(-c2c([2H])c([2H])c([2H])c([2H])c2-c2c3ccccc3c(-c3ccc4c(c3)oc3c(-c5cc6c7ccccc7n7c8ccccc8c(c5)c67)cccc34)c3ccccc23)c([2H])c1[2H]]

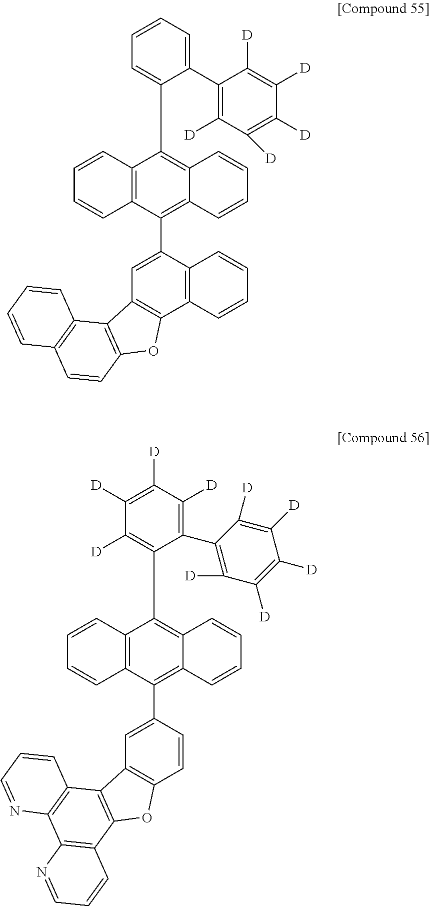 [SMILES: [2H]c1c([2H])c([2H])c(-c2ccccc2-c2c3ccccc3c(-c3cc4c(oc5ccc6ccccc6c54)c4ccccc34)c3ccccc23)c([2H])c1[2H] ; [2H]c1c([2H])c([2H])c(-c2c([2H])c([2H])c([2H])c([2H])c2-c2c3ccccc3c(-c3ccc4oc5c6cccnc6c6ncccc6c5c4c3)c3ccccc23)c([2H])c1[2H]]

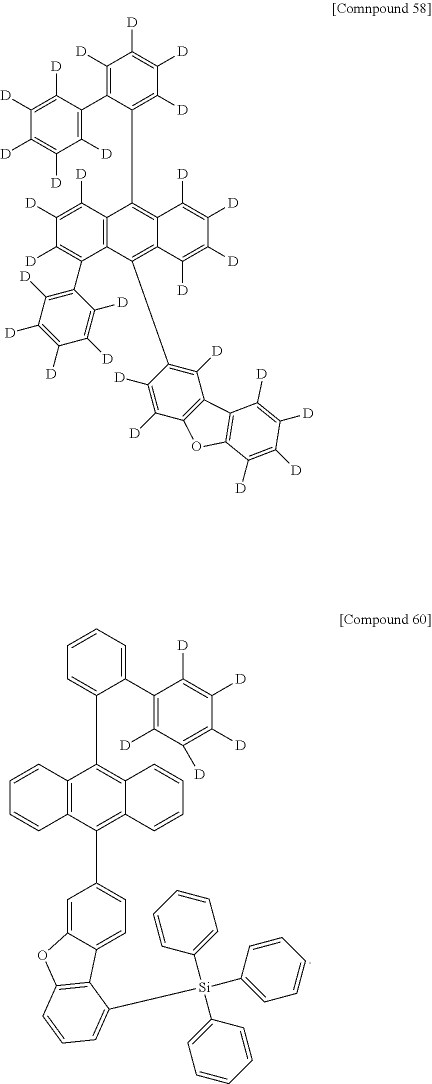 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c([2H])c([2H])c5c4c3[2H])c3c(-c4c([2H])c([2H])c([2H])c([2H])c4[2H])c([2H])c([2H])c([2H])c23)c([2H])c1[2H] ; [2H]c1c([2H])c([2H])c(-c2ccccc2-c2c3ccccc3c(-c3ccc4c(c3)oc3cccc([Si](c5ccccc5)(c5ccccc5)c5ccccc5)c34)c3ccccc23)c([2H])c1[2H]]

7. The organic light emitting diode of claim 1, wherein A₁ to A₃ in Chemical Formulas B-1 and B-2 are same or different and each independently a substituted or unsubstituted aromatic hydrocarbon ring of 6 to 30.

8. The organic light emitting diode of claim 1, wherein at least one of Y₁ and Y₂ in Chemical Formulas B-1 and B-2 is NR₂₁, wherein R₂₁ is as defined in claim 1.

9. The organic light emitting diode of claim 8, wherein R₂₁ in Chemical Formulas B-1 and B-2 is a substituted or unsubstituted an aryl of 6 to 30 carbon atoms.

10. The organic light emitting diode of claim 1, wherein the compound represented by Chemical Formula B-1 or B-2 is any one selected from among [Chemical Formula 1] to [Chemical Formula 84], below:

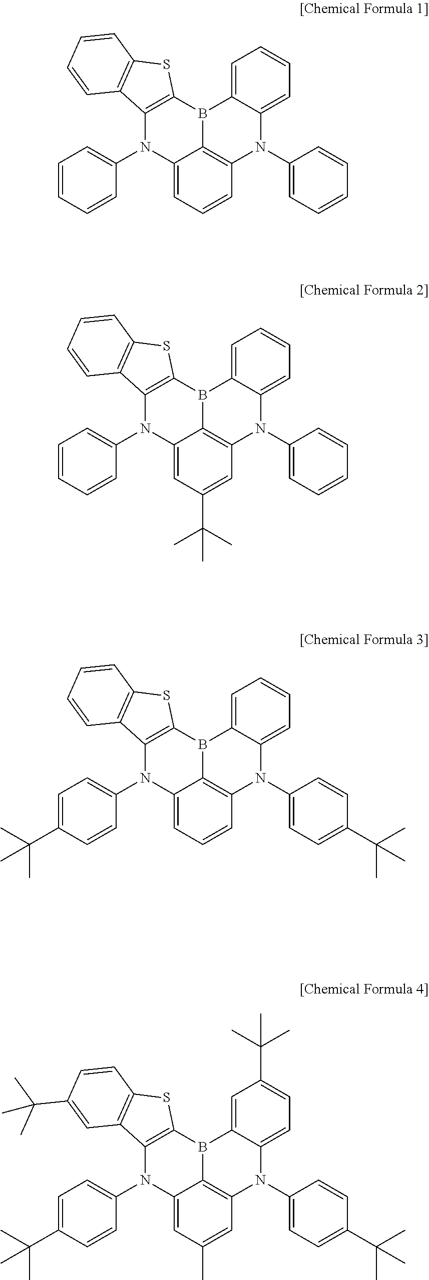

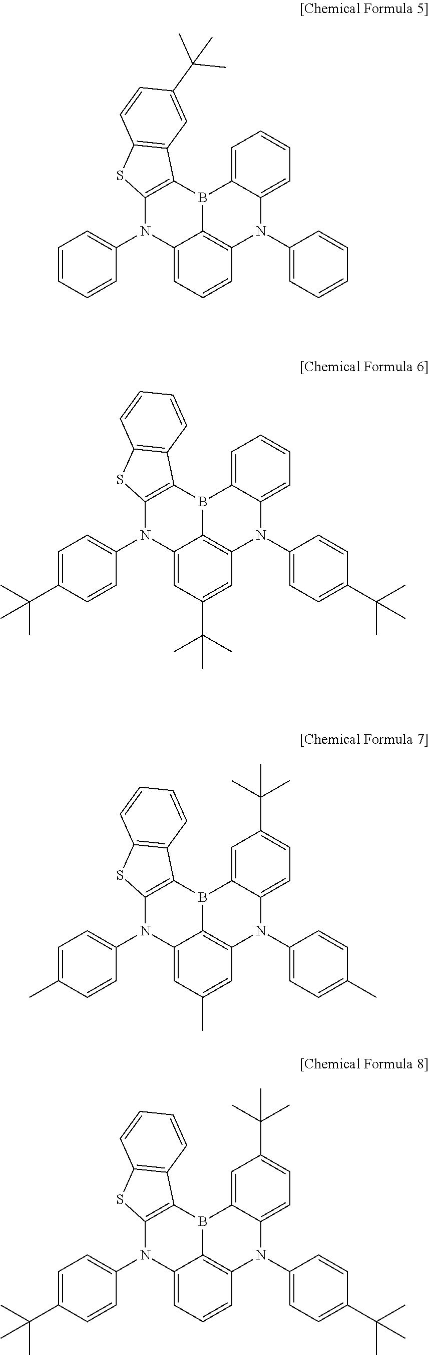

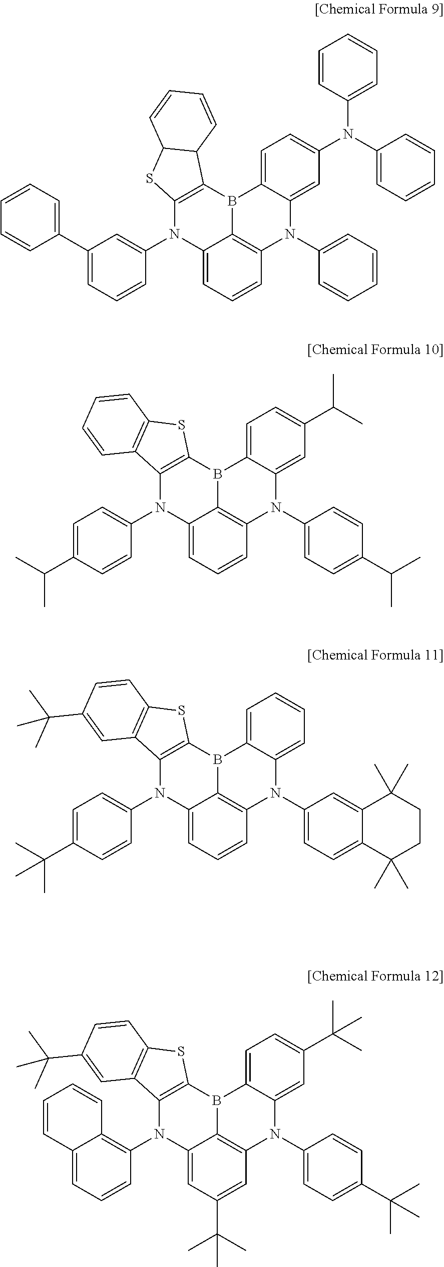

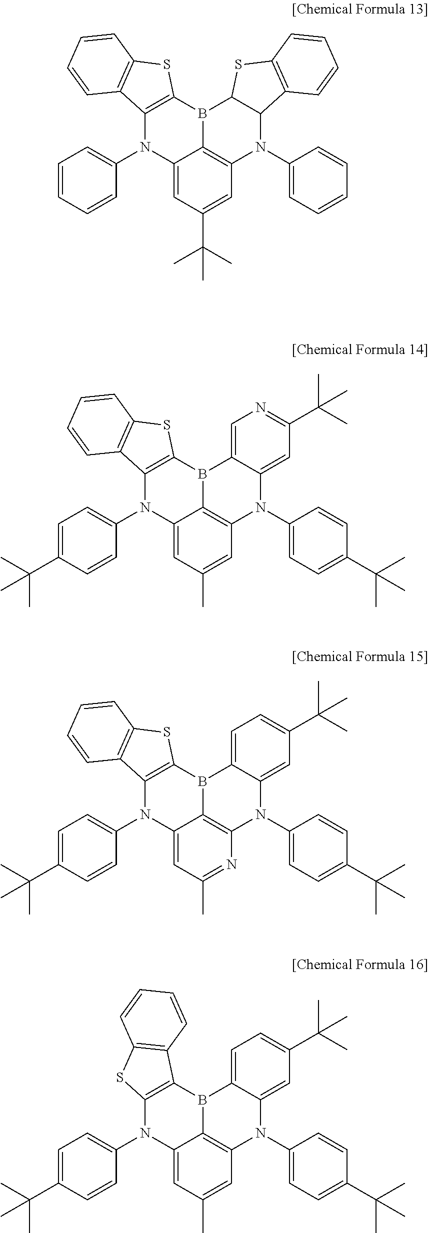

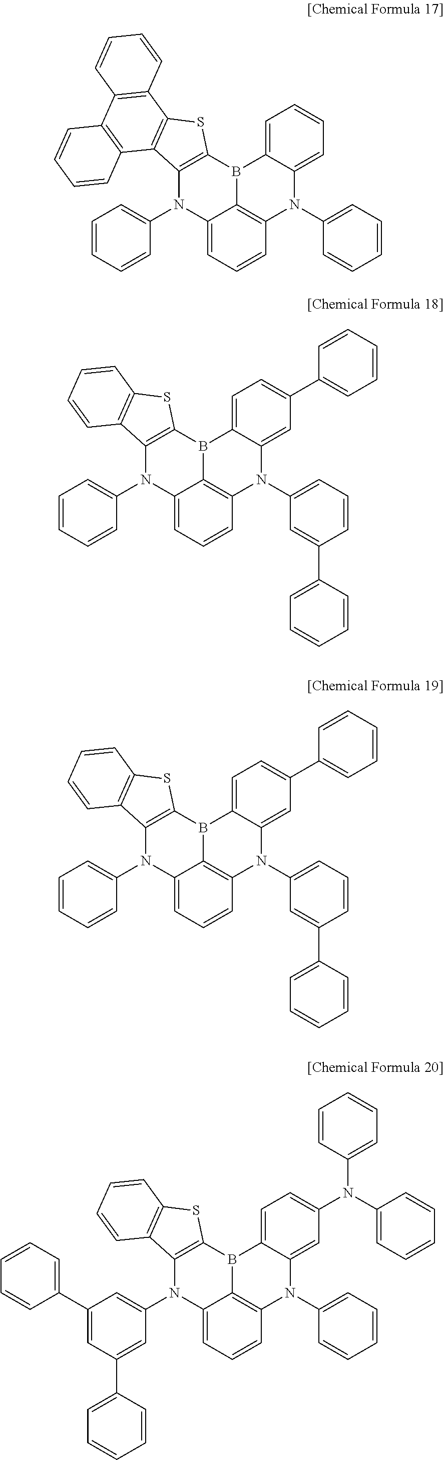 [SMILES: c1ccc(N2c3ccccc3B3c4sc5c6ccccc6c6ccccc6c5c4N(c4ccccc4)c4cccc2c43)cc1 ; c1ccc(-c2cccc(N3c4cc(-c5ccccc5)ccc4B4c5sc6ccccc6c5N(c5ccccc5)c5cccc3c54)c2)cc1 ; c1ccc(-c2cccc(N3c4cc(-c5ccccc5)ccc4B4c5sc6ccccc6c5N(c5ccccc5)c5cccc3c54)c2)cc1 ; c1ccc(-c2cc(-c3ccccc3)cc(N3c4cccc5c4B(c4ccc(N(c6ccccc6)c6ccccc6)cc4N5c4ccccc4)c4sc5ccccc5c43)c2)cc1]

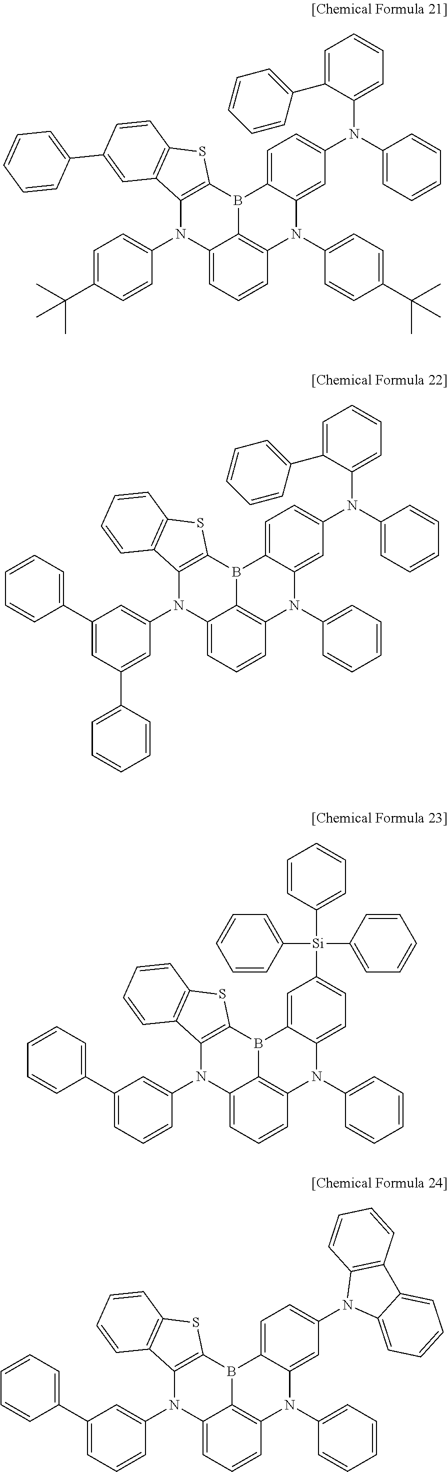 [SMILES: CC(C)(C)c1ccc(N2c3cc(N(c4ccccc4)c4ccccc4-c4ccccc4)ccc3B3c4sc5ccc(-c6ccccc6)cc5c4N(c4ccc(C(C)(C)C)cc4)c4cccc2c43)cc1 ; c1ccc(-c2cc(-c3ccccc3)cc(N3c4cccc5c4B(c4ccc(N(c6ccccc6)c6ccccc6-c6ccccc6)cc4N5c4ccccc4)c4sc5ccccc5c43)c2)cc1 ; c1ccc(-c2cccc(N3c4cccc5c4B(c4cc([Si](c6ccccc6)(c6ccccc6)c6ccccc6)ccc4N5c4ccccc4)c4sc5ccccc5c43)c2)cc1 ; c1ccc(-c2cccc(N3c4cccc5c4B(c4ccc(-n6c7ccccc7c7ccccc76)cc4N5c4ccccc4)c4sc5ccccc5c43)c2)cc1]

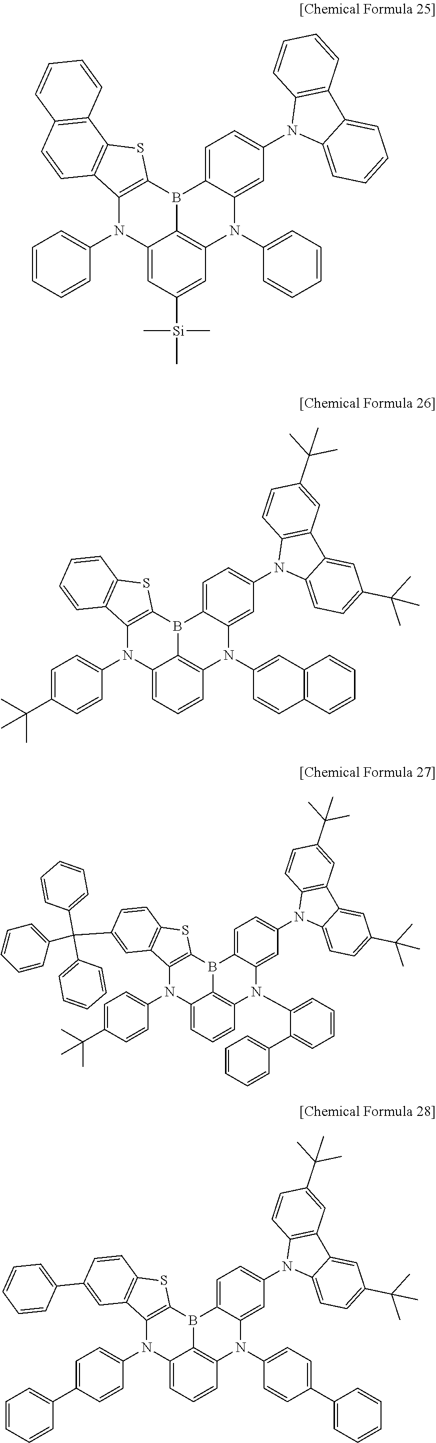 [SMILES: C[Si](C)(C)c1cc2c3c(c1)N(c1ccccc1)c1c(sc4c1ccc1ccccc14)B3c1ccc(-n3c4ccccc4c4ccccc43)cc1N2c1ccccc1 ; CC(C)(C)c1ccc(N2c3cccc4c3B(c3ccc(-n5c6ccc(C(C)(C)C)cc6c6cc(C(C)(C)C)ccc65)cc3N4c3ccc4ccccc4c3)c3sc4ccccc4c32)cc1 ; CC(C)(C)c1ccc(N2c3cccc4c3B(c3ccc(-n5c6ccc(C(C)(C)C)cc6c6cc(C(C)(C)C)ccc65)cc3N4c3ccccc3-c3ccccc3)c3sc4ccc(C(c5ccccc5)(c5ccccc5)c5ccccc5)cc4c32)cc1 ; CC(C)(C)c1ccc2c(c1)c1cc(C(C)(C)C)ccc1n2-c1ccc2c(c1)N(c1ccc(-c3ccccc3)cc1)c1cccc3c1B2c1sc2ccc(-c4ccccc4)cc2c1N3c1ccc(-c2ccccc2)cc1]

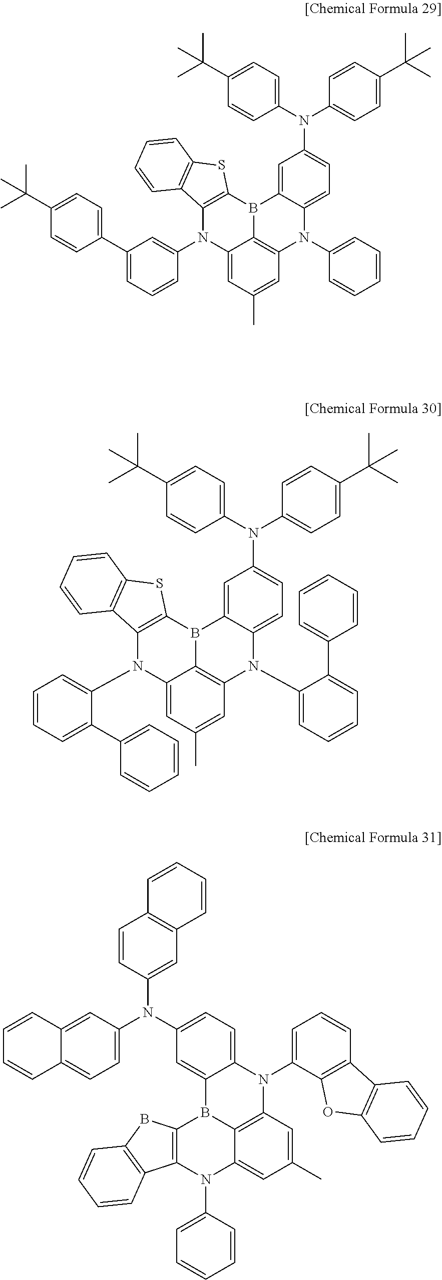

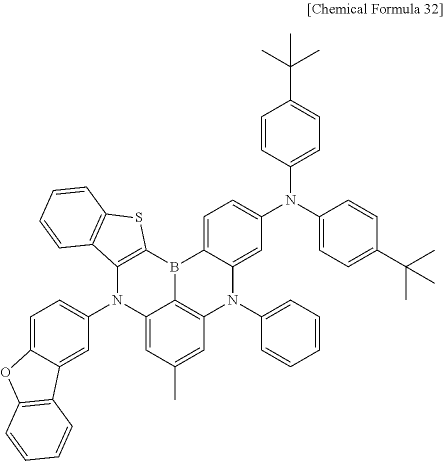 [SMILES: Cc1cc2c3c(c1)N(c1ccc4oc5ccccc5c4c1)c1c(sc4ccccc14)B3c1ccc(N(c3ccc(C(C)(C)C)cc3)c3ccc(C(C)(C)C)cc3)cc1N2c1ccccc1]

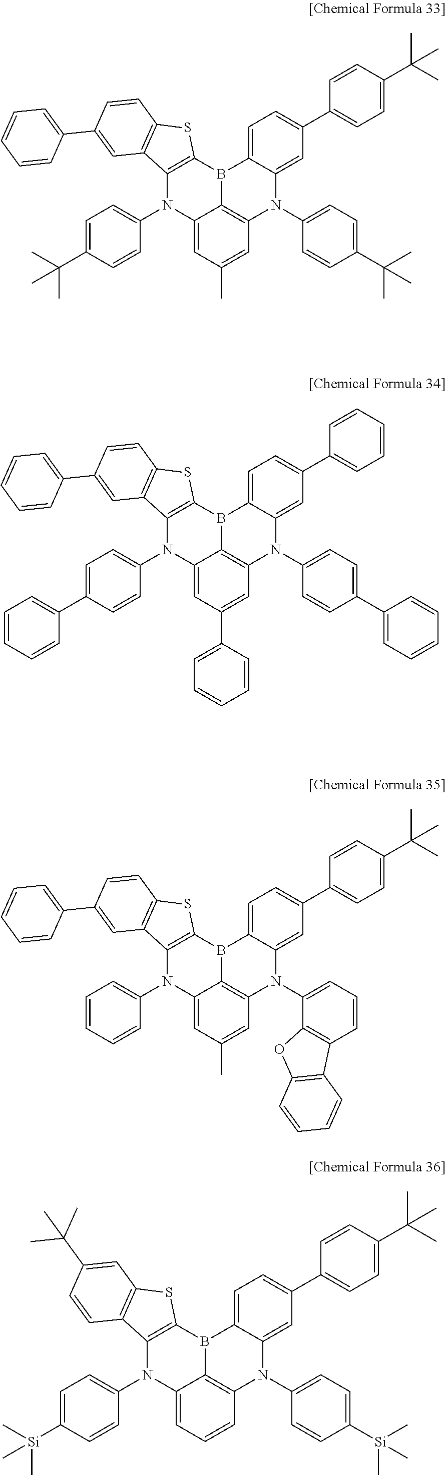

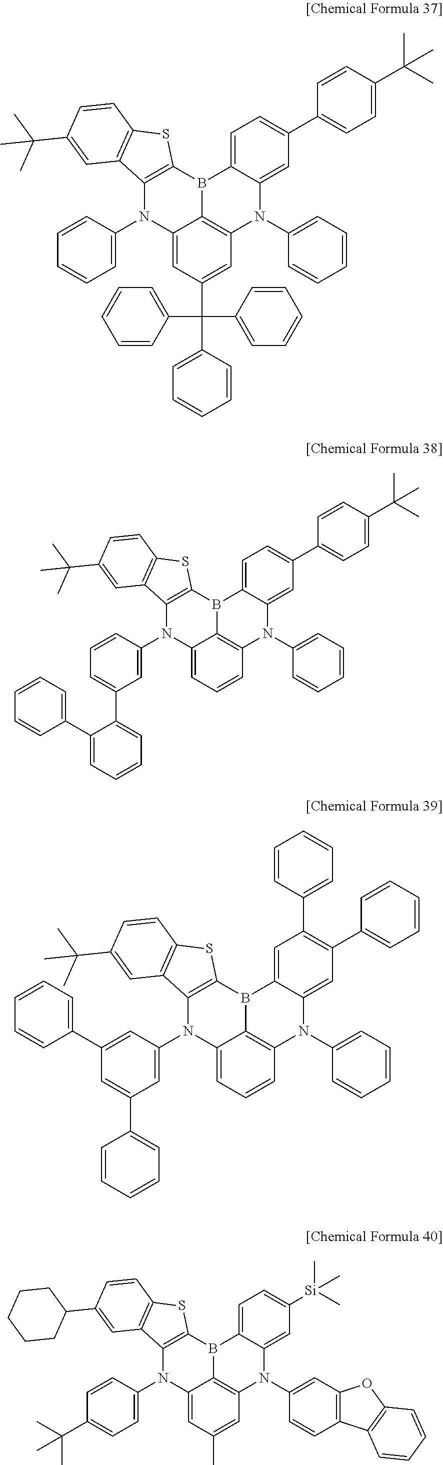 [SMILES: CC(C)(C)c1ccc(-c2ccc3c(c2)N(c2ccccc2)c2cc(C(c4ccccc4)(c4ccccc4)c4ccccc4)cc4c2B3c2sc3ccc(C(C)(C)C)cc3c2N4c2ccccc2)cc1 ; CC(C)(C)c1ccc(-c2ccc3c(c2)N(c2ccccc2)c2cccc4c2B3c2sc3ccc(C(C)(C)C)cc3c2N4c2cccc(-c3ccccc3-c3ccccc3)c2)cc1 ; CC(C)(C)c1ccc2sc3c(c2c1)N(c1cc(-c2ccccc2)cc(-c2ccccc2)c1)c1cccc2c1B3c1cc(-c3ccccc3)c(-c3ccccc3)cc1N2c1ccccc1 ; Cc1cc2c3c(c1)N(c1ccc(C(C)(C)C)cc1)c1c(sc4ccc(C5CCCCC5)cc14)B3c1ccc([Si](C)(C)C)cc1N2c1ccc2c(c1)oc1ccccc12]

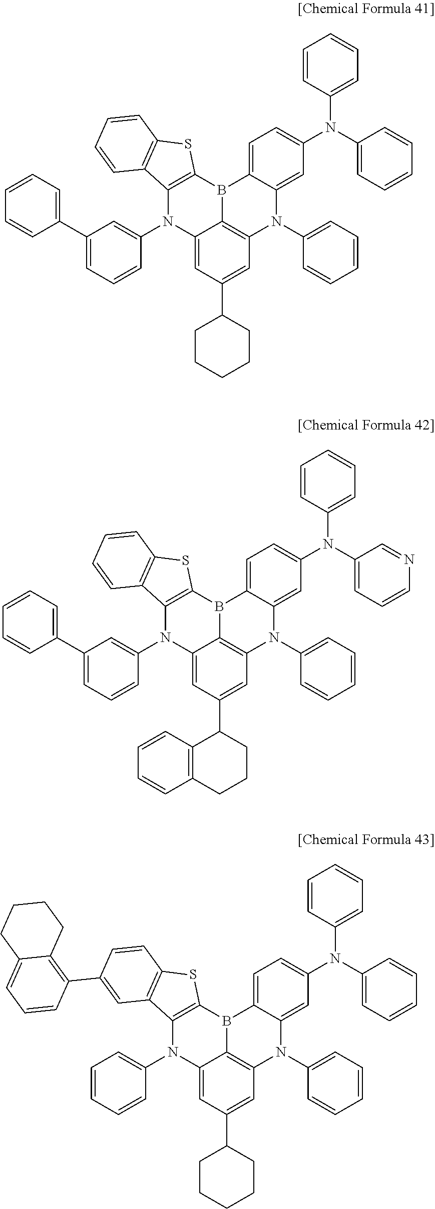 [SMILES: c1ccc(-c2cccc(N3c4cc(C5CCCCC5)cc5c4B(c4ccc(N(c6ccccc6)c6ccccc6)cc4N5c4ccccc4)c4sc5ccccc5c43)c2)cc1 ; c1ccc(-c2cccc(N3c4cc(C5CCCc6ccccc65)cc5c4B(c4ccc(N(c6ccccc6)c6cccnc6)cc4N5c4ccccc4)c4sc5ccccc5c43)c2)cc1 ; c1ccc(N(c2ccccc2)c2ccc3c(c2)N(c2ccccc2)c2cc(C4CCCCC4)cc4c2B3c2sc3ccc(-c5cccc6c5CCCC6)cc3c2N4c2ccccc2)cc1]

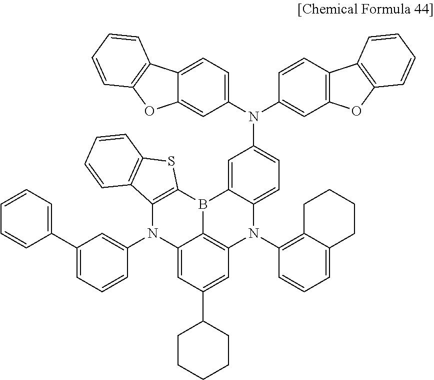 [SMILES: c1ccc(-c2cccc(N3c4cc(C5CCCCC5)cc5c4B(c4cc(N(c6ccc7c(c6)oc6ccccc67)c6ccc7c(c6)oc6ccccc67)ccc4N5c4cccc5c4CCCC5)c4sc5ccccc5c43)c2)cc1]

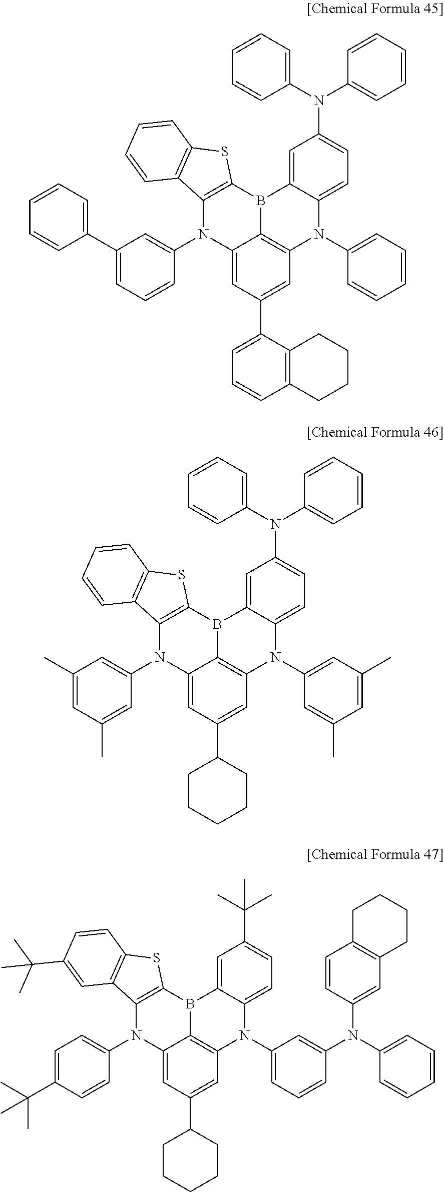

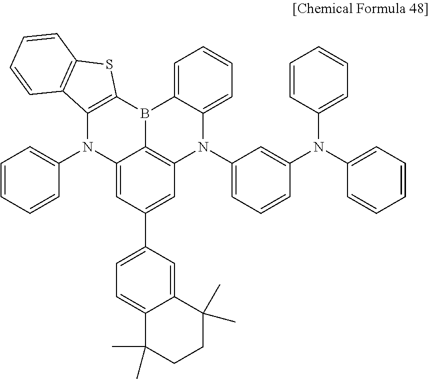 [SMILES: CC1(C)CCC(C)(C)c2cc(-c3cc4c5c(c3)N(c3ccccc3)c3c(sc6ccccc36)B5c3ccccc3N4c3cccc(N(c4ccccc4)c4ccccc4)c3)ccc21]

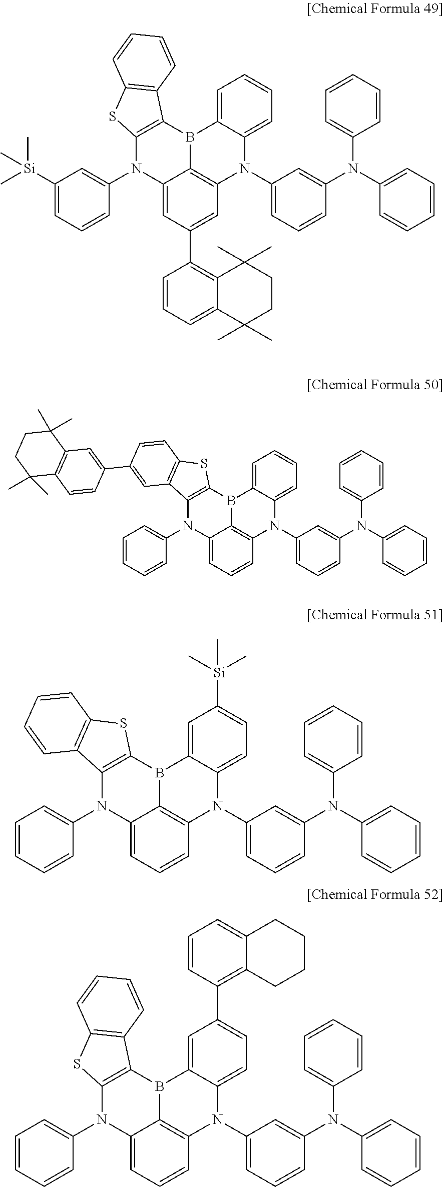 [SMILES: CC1(C)CCC(C)(C)c2c(-c3cc4c5c(c3)N(c3cccc([Si](C)(C)C)c3)c3sc6ccccc6c3B5c3ccccc3N4c3cccc(N(c4ccccc4)c4ccccc4)c3)cccc21 ; CC1(C)CCC(C)(C)c2cc(-c3ccc4sc5c(c4c3)N(c3ccccc3)c3cccc4c3B5c3ccccc3N4c3cccc(N(c4ccccc4)c4ccccc4)c3)ccc21 ; C[Si](C)(C)c1ccc2c(c1)B1c3sc4ccccc4c3N(c3ccccc3)c3cccc(c31)N2c1cccc(N(c2ccccc2)c2ccccc2)c1 ; c1ccc(N(c2ccccc2)c2cccc(N3c4ccc(-c5cccc6c5CCCC6)cc4B4c5c3cccc5N(c3ccccc3)c3sc5ccccc5c34)c2)cc1]

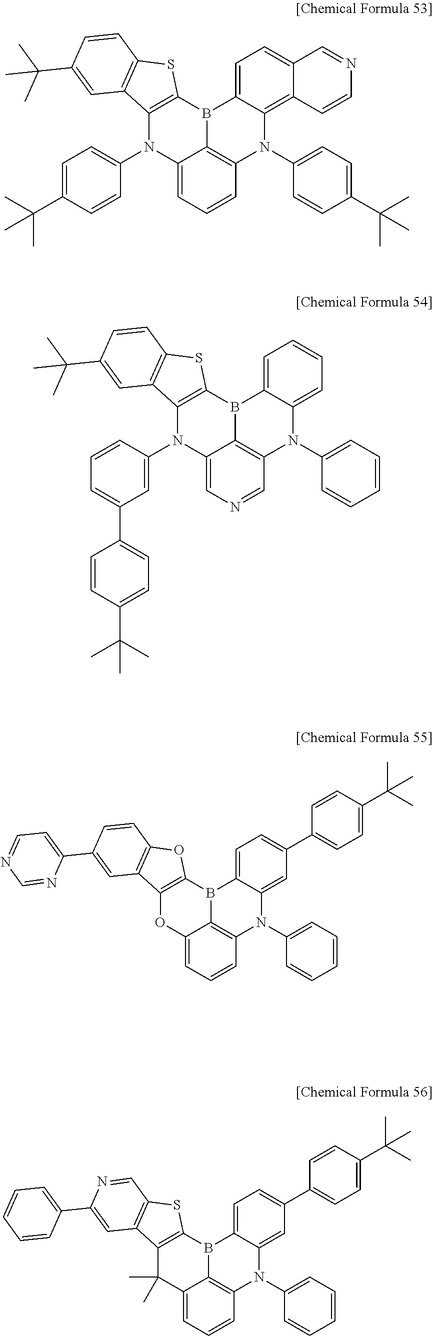

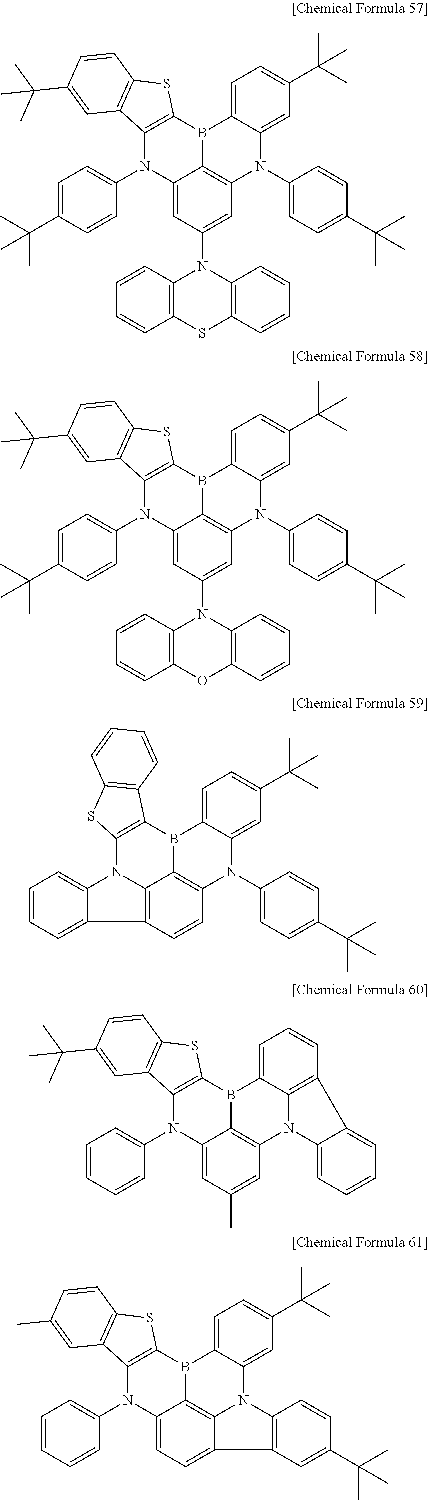

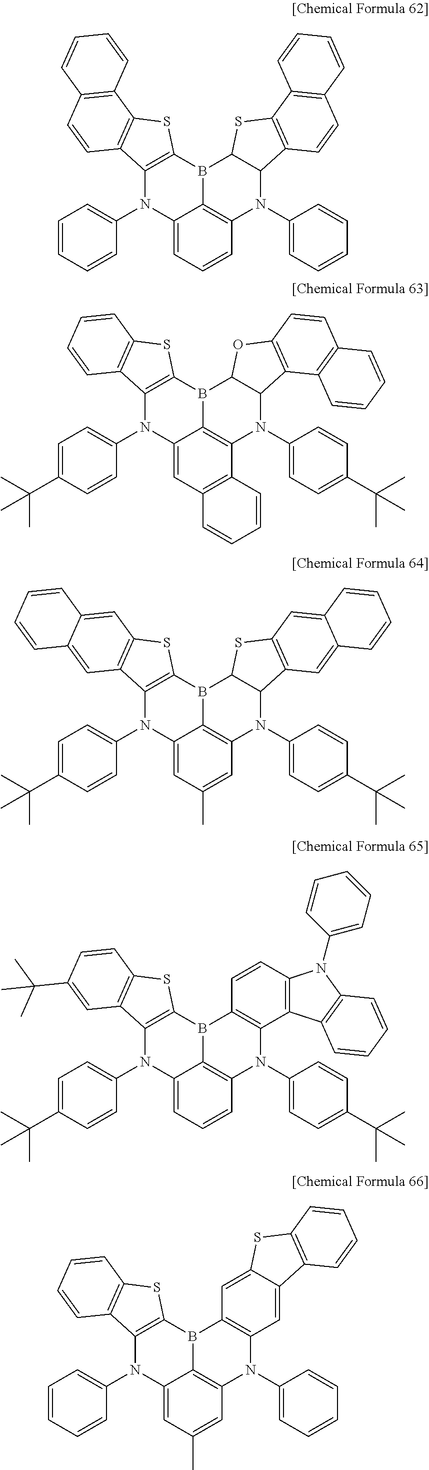

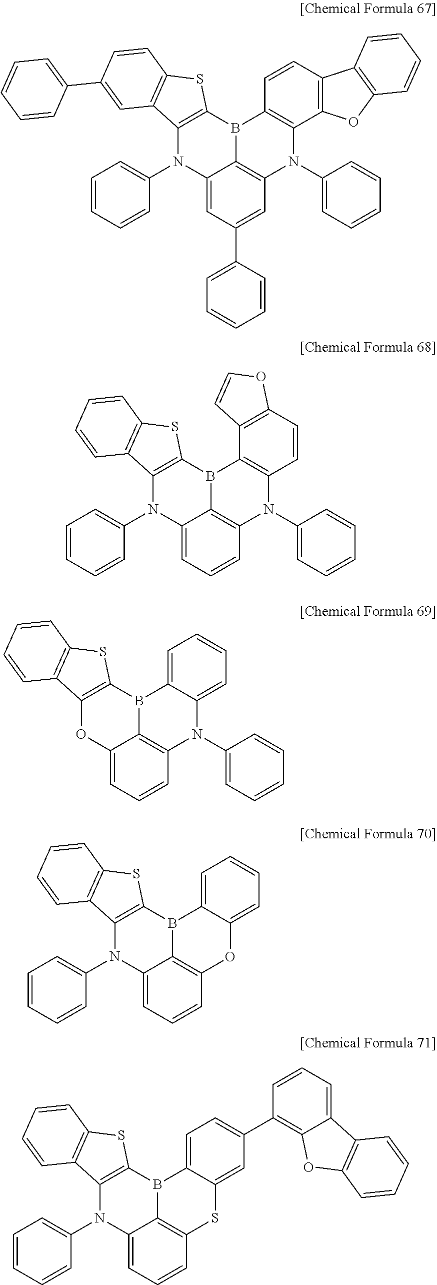

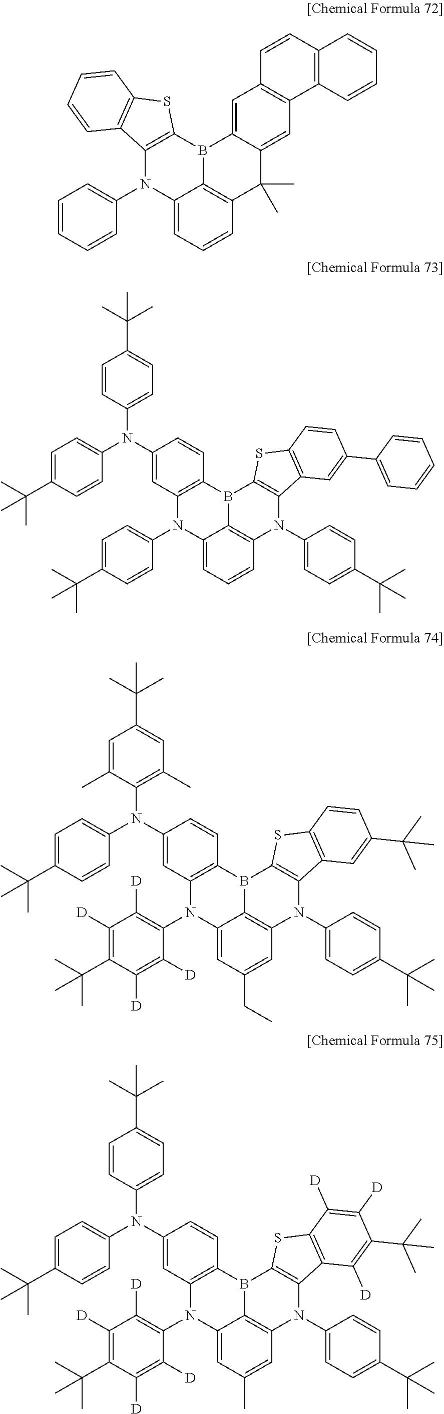

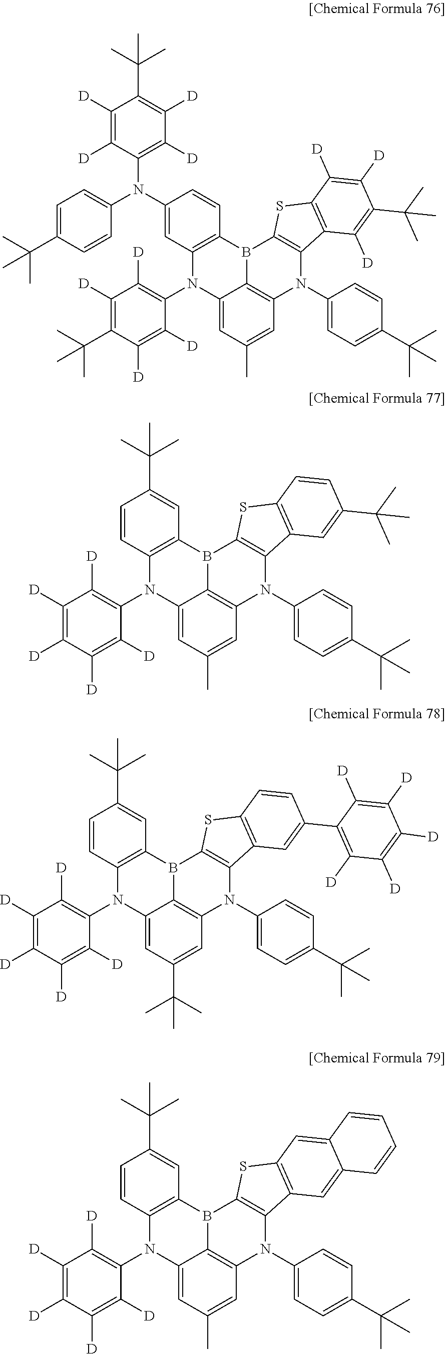

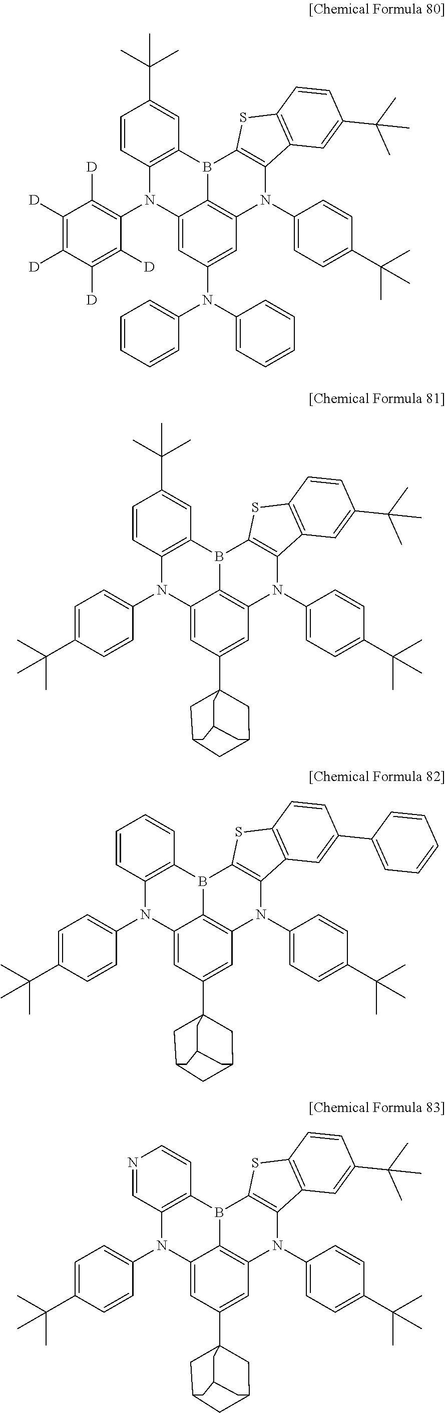

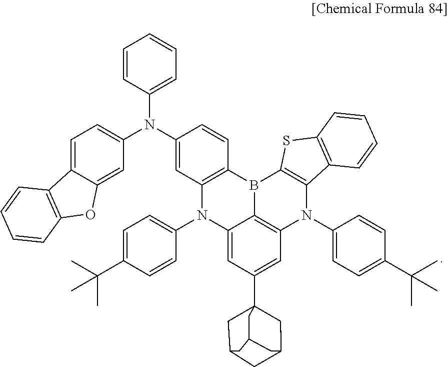 [SMILES: CC(C)(C)c1ccc(N2c3cc(N(c4ccccc4)c4ccc5c(c4)oc4ccccc45)ccc3B3c4sc5ccccc5c4N(c4ccc(C(C)(C)C)cc4)c4cc(C56CC7CC(CC(C7)C5)C6)cc2c43)cc1]

11. The organic light emitting diode of claim 1, wherein the organic layer comprises at least one of a hole injection layer, a hole transport layer, a functional layer capable of both hole injection and hole transport, an electron transport layer, and an electron injection layer, in addition to the light emission layer.

12. The organic light emitting diode of claim 1, wherein the host in the light emission layer is a mixture of the anthracene compound represented by Chemical Formula A and at least one host compound or is formed as the anthracene compound represented by Chemical Formula A and a different host compound are separately deposited.

13. The organic light emitting diode of claim 12, wherein at least one selected from among the layers is deposited using a single-molecule deposition process or a solution process.

14. The organic light emitting diode of claim 1, wherein the organic light emitting diode is used for a device selected from among a flat display device; a flexible display device; a monochrome or grayscale flat illumination; a monochrome or grayscale flexible illumination device; a vehicle display device; and a virtual or augmented reality display device.
